(19) United States
(12) Patent Application Publication
(10) Pub. No.: US 2009/0117707 A1
(43) Pub. Date: May 7, 2009

(54) METHOD FOR MANUFACTURING SOI SUBSTRATE AND SEMICONDUCTOR DEVICE

(75) Inventors: Akihisa Shimomura, Isehara (JP); Junpei Momo, Sagamihara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/260,712

(22) Filed: Oct. 29, 2008

(30) Foreign Application Priority Data
Nov. 1, 2007 (JP) 2007-285180

(51) Int. Cl. H01L 21/762

(52) U.S. Cl. 438/458; 257/E21.568

(57) ABSTRACT

An object is to provide a method for manufacturing an SOI substrate provided with a single crystal semiconductor layer which can be used practically even when a substrate having a low heat resistant temperature, such as a glass substrate or the like, is used. Another object is to manufacture a highly reliable semiconductor device using such an SOI substrate. An SOI substrate having a single crystal semiconductor layer which is transferred from a single crystal semiconductor substrate to a supporting substrate, and an entire region of which is melted by laser light irradiation to cause re-single-crystallization is used. Accordingly, the single crystal semiconductor layer has reduced crystal defects, high crystallinity and high planarity.

### BACKGROUND OF THE INVENTION

1. Field of the Invention

The present invention relates to a method for manufacturing a semiconductor substrate provided with a single crystal semiconductor layer over an insulating surface and a method for manufacturing a semiconductor device.

2. Description of the Related Art

As an alternative to an integrated circuit using a silicon wafer which is manufactured by thinly slicing an ingot of a single crystal semiconductor, an integrated circuit using a semiconductor substrate which is referred to as a silicon-on-insulator (hereinafter also referred to as “SOI”) substrate, in which a thin single crystal semiconductor layer is provided on an insulating surface has been developed. The integrated circuit using an SOI substrate has attracted attention as an integrated circuit which reduces parasitic capacitance between a drain of a transistor and the substrate and improves the performance of a semiconductor integrated circuit.

As a method for manufacturing SOI substrates, a hydrogen ion addition separation method is known (e.g., see Reference 1: Japanese Published Patent Application No. 2000-124092). The hydrogen ion addition separation method is a method in which hydrogen ions are added into a silicon wafer to form a microbubble layer at a predetermined depth from the surface, and a thin silicon layer is bonded to another silicon wafer by using the microbubble layer as a cleavage plane. In addition to the heat treatment for separation of the silicon layer, it is necessary to perform heat treatment in an oxidizing atmosphere to form an oxide film over the silicon layer, remove the oxide film, and perform heat treatment at 1000° C. to 1300° C. to increase bonding strength.

On the other hand, a semiconductor device in which an insulating substrate such as high heat resistant glass is provided with a silicon layer is disclosed (e.g., see Reference 2: Japanese Published Patent Application No. H11-163363). This semiconductor device has a structure in which the entire surface of crystallized glass having a strain point of greater than or equal to 750° C. is protected by an insulating silicon film and a silicon layer obtained by a hydrogen ion addition separation method is firmly fixed to the insulating silicon film.

### SUMMARY OF THE INVENTION

In addition, in an ion addition step to form the microbubble layer, a silicon layer is damaged by added ions. In heat treatment to increase the bonding strength between the silicon layer and a supporting substrate, damage to the silicon layer by an ion addition step is repaired as well.

However, when a substrate having a low heat resistant temperature, such as a glass substrate or the like, is used for the supporting substrate, heat treatment at a temperature of greater than or equal to 1000° C. cannot be performed and the damage to the silicon layer by the above ion addition step cannot be sufficiently repaired.

In view of the foregoing problems, an object of the present invention is to provide a method for manufacturing an SOI substrate (hereinafter also referred to as a semiconductor substrate) provided with a single crystal semiconductor layer which can be used practically even when a substrate having a low heat resistant temperature, such as a glass substrate or the like, is used. In addition, another object of the present invention is to manufacture a semiconductor device with high reliability which uses such a semiconductor substrate.

The gist of the present invention is that in manufacturing a semiconductor substrate, irradiation with laser light of pulsed oscillation (hereinafter also referred to as pulsed laser light) is performed in order to recover crystallinity of a single crystal semiconductor layer which is separated from a single crystal semiconductor substrate and bonded to a supporting substrate having an insulating surface. By irradiation with the pulsed laser light, a region of the single crystal semiconductor layer, which is irradiated with the pulsed laser light, is entirely melted and re-single-crystallization is caused using single crystal regions which are adjacent to the region irradiated with the pulsed laser light as nuclei of crystal growth in a later cooling step.

The region of the single crystal semiconductor layer, which is irradiated with the pulsed laser light, is entirely melted in a depth direction as well by irradiation with the pulsed laser light and re-single-crystallization is caused, so that crystal defects in the single crystal semiconductor layer are reduced. Since irradiation treatment with the pulsed laser light is used, the temperature rise of the supporting substrate is suppressed; therefore, a substrate with a low heat resistant temperature such as a glass substrate can be used as the supporting substrate. Accordingly, damage to the single crystal semiconductor layer by an ion addition step can be sufficiently repaired.

Further, the single crystal semiconductor layer is melted and re-single-crystallization is caused, whereby the surface thereof can be planarized. In this manner, re-single-crystallization of the single crystal semiconductor layer is caused by irradiation with the pulsed laser light, so that a semiconductor substrate having the single crystal semiconductor layer with reduced crystal defects and high planarity can be manufactured.

Any laser light may be used for re-single-crystallization of the single crystal semiconductor layer as long as it provides high energy to the single crystal semiconductor layer, and typically a pulsed laser light can be used. The wavelength of the laser light may be 190 nm to 600 nm.

In the present invention, the region of the single crystal semiconductor layer, which is irradiated with the laser light, is entirely melted in a depth direction as well. Accordingly, in the present invention, the entire region (in a plane direction and a depth direction) of the single crystal semiconductor layer, which is irradiated with the laser light, becomes a melted region. In this specification, “the entire region in the region of the single crystal semiconductor layer, which is irradiated with the laser light” refers to an entire region in a region of a single crystal semiconductor layer, which is irradiated with laser light, in a plane direction and a depth direction. Since the entire region of the laser light irradiation region in the single crystal semiconductor layer is melted completely at least in a depth direction, the melting can also be referred to as “complete melting.”

Accordingly, the crystal nuclei (seed crystals) for re-single-crystallization are the peripheral non-melted regions which are not irradiated with the laser light. Crystal growth occurs toward the center of the melted region in a parallel direction to the surface of the single crystal semiconductor layer (or the supporting substrate) using the non-melted regions as the crystal nuclei. Crystal growth occurs at end portions of the melted region from the interfaces between the melted region and the non-melted regions toward the inside (center) of the melted region and the regions in which re-single-crystallization is caused by the crystal growth are in contact with each other. In this manner, re-single-crystallization is caused in the entire region of the laser light irradiation region in the single crystal semiconductor layer.

In the present invention, since crystal growth which occurs by irradiation with the laser light occurs in a parallel direction to the surface of the single crystal semiconductor layer (or the supporting substrate), the crystal growth is also referred to as crystal growth of lateral growth (growth in a lateral direction) when a depth direction (a film thickness direction) to the surface of the single crystal semiconductor layer (or the supporting substrate) is a longitudinal direction.

The crystal growth in the melted region occurs in a supercooled state which is a state where the region of the single crystal semiconductor layer, which is irradiated with the laser light, remains in a melting state without being solidified even when the region is cooled down to a temperature of less than or equal to the melting point after the region is heated to a temperature of greater than or equal to the melting point to be melted by irradiation with the laser light. How long the supercooled state lasts depends on the thickness of the single crystal semiconductor layer, conditions for irradiation with the laser light (energy density, irradiation time (a pulse width), or the like), or the like. When the supercooled state lasts longer, a region in which re-single-crystallization is caused by crystal growth is widened; therefore, a region irradiated with laser light at once can be widened. Accordingly, treatment efficiency is increased and throughput is improved. Further, heating the supporting substrate is effective in extension of time of the supercooled state.

Accordingly, in the present invention, the region irradiated with the laser light (the melted region) is set to have an area in which the end portions (end portions of crystal growth) of the single crystal regions are in contact with each other by the re-single-crystallization. For example, the shape of a laser light profile (also referred to as a beam profile) in the minor-axis direction of the region of the single crystal semiconductor layer, which is irradiated with the pulsed laser light, is rectangular and the width thereof is less than or equal to 20 μm. The shape of a laser light profile in the minor-axis direction of the region of the single crystal semiconductor layer, which is irradiated with the pulsed laser light, is Gaussian and the width thereof is less than or equal to 100 μm. When the pulse width of the laser light is made long, the width of the laser light profile can be made long. When the laser light profile is set as described above, the entire melted region can be changed into the re-single-crystallization region by crystal growth within the time of the supercooled state. Further, the shape of the region of the single crystal semiconductor layer, which is irradiated with pulsed laser light, can be rectangular (a long rectangular shape by linear laser light may also be used). Alternatively, irradiation with a plurality of rectangular shapes of laser light may be performed with the use of a mask.

Here, the “single crystal” means a crystal in which, when a certain crystal axis is focused, the direction of the crystal axis is oriented in the same direction in any portion of a sample and which has no crystal grain boundary between crystals. Note that, in this specification, the “single crystal” includes a crystal in which crystal axis directions are uniform as described above and which has no grain boundary even when including a crystal defect or a dangling bond. In addition, re-single-crystallization of a single crystal semiconductor layer means that a semiconductor layer having a single crystal structure returns to a single crystal structure after being in a different state from the single crystal structure (e.g., a liquid-phase state). In addition, it can be said that re-single-crystallization of a single crystal semiconductor layer means that a single crystal semiconductor layer is recrystallized to form a single crystal semiconductor layer.

In this specification, separating a single crystal semiconductor layer from a single crystal semiconductor substrate and providing the single crystal semiconductor layer for a supporting substrate by bonding is referred to as transferring (transposing) the single crystal semiconductor layer from the single crystal semiconductor substrate to the supporting substrate. Accordingly, in the present invention, the transistor includes a single crystal semiconductor layer transferred to the supporting substrate from the single crystal semiconductor substrate.

One aspect of a method for manufacturing a semiconductor substrate of the present invention is to add ions from a surface of a single crystal semiconductor substrate to form an embrittlement layer at a predetermined depth from the surface of the single crystal semiconductor substrate. An insulating layer is formed either on one surface of the single crystal semiconductor substrate or on a supporting substrate. Heat treatment is performed to generate a crack is generated in the embrittlement layer in a state where the single crystal semiconductor substrate and the supporting substrate are bonded to each other with the insulating layer interposed therebetween and the single crystal semiconductor substrate is separated at the embrittlement layer. Accordingly, a single crystal semiconductor layer, which is separated from the single crystal semiconductor substrate, is formed over the supporting substrate. The entire region in the region of the single crystal semiconductor layer, which is irradiated with pulsed laser light, is melted in a depth direction as well by irradiation with the pulsed laser light and re-single-crystallization is caused.

Another aspect of a method for manufacturing a semiconductor substrate of the present invention is to add ions from a surface of a single crystal semiconductor substrate to form an embrittlement layer at a predetermined depth from the surface of the single crystal semiconductor substrate. An insulating layer is formed either on the surface of the single crystal semiconductor substrate or on a supporting substrate. Heat treatment is performed to generate a crack is generated in the embrittlement layer in a state where the single crystal semiconductor substrate and the supporting substrate are bonded to each other with the insulating layer interposed therebetween and the single crystal semiconductor substrate is separated at the embrittlement layer. Accordingly, a single crystal semiconductor layer, which is separated from the single crystal semiconductor substrate, is formed over the supporting substrate. The entire region in the region of the single crystal semiconductor layer, which is irradiated with pulsed laser light, is melted in a depth direction as well by irradiation with the pulsed laser light, and crystal growth occurs from end portions of the melted region of the single crystal semiconductor layer toward the center of the melted region in a parallel direction to the surface of the supporting substrate, so that re-single-crystallization is caused.

By using a single crystal semiconductor layer the entire region of which is melted by irradiation with laser light and in which re-single-crystallization is caused, even when a substrate having low heat resistance such as a glass substrate is used, a semiconductor substrate having a single crystal semiconductor layer with reduced crystal defects, high crystallinity and high planarity which can be used practically can be manufactured.

With the use of a single crystal semiconductor layer included in such a semiconductor substrate, a semiconductor device that includes various semiconductor elements, memory elements, integrated circuits, or the like which have high performance and high reliability can be manufactured with high yield.

### BRIEF DESCRIPTION OF THE DRAWINGS

In the accompanying drawings:

FIGS. 1A to 1H are views illustrating a method for manufacturing a semiconductor substrate of the present invention;

FIGS. 2A to 2F are views illustrating a method for manufacturing a semiconductor substrate of the present invention;

FIGS. 3A to 3D are views illustrating a method for manufacturing a semiconductor substrate of the present invention;

FIGS. 4A to 4C are views illustrating a method for manufacturing a semiconductor substrate of the present invention;

FIGS. 5A to 5E are views illustrating a method for manufacturing a semiconductor substrate of the present invention;

FIGS. 6A to 6E are views illustrating a method for manufacturing a semiconductor substrate of the present invention;

FIGS. 7A to 7E are views illustrating a method for manufacturing a semiconductor device of the present invention;

FIGS. 8A to 8D are views illustrating a method for manufacturing a semiconductor device of the present invention;

FIGS. 9A and 9B are views illustrating a semiconductor device of the present invention;

FIGS. 10A and 10B are views illustrating a semiconductor device of the present invention;

FIGS. 11A and 11B are views illustrating a semiconductor device of the present invention;

FIGS. 12A to 12F are views illustrating structures of a light-emitting element which can be applied to the present invention;

FIGS. 13A to 13D are views illustrating structures of a light-emitting element which can be applied to the present invention;

FIGS. 14A and 14B illustrate an electronic appliance to which the present invention is applied;

FIG. 15 illustrates an electronic appliance to which the present invention is applied;

FIG. 16 is a block diagram illustrating a main structure of an electronic appliance to which the present invention is applied;

FIG. 17 is a block diagram illustrating a structure of a microprocessor manufactured using a semiconductor substrate;

FIG. 18 is a block diagram illustrating a structure of an RFCPU manufactured using a semiconductor substrate;

FIGS. 19A to 19E each illustrate an electronic appliance to which the present invention is applied;

FIGS. 20A and 20B each illustrate an electronic appliance to which the present invention is applied;

FIGS. 21A to 21E are views illustrating a method for manufacturing a semiconductor device of the present invention;

FIGS. 22A to 22E are views illustrating a method for manufacturing a semiconductor device of the present invention;

FIGS. 23A and 23B are views illustrating a method for manufacturing a semiconductor substrate of the present invention;

FIGS. 24A to 24C illustrate an electronic appliance to which the present invention is applied;

FIG. 25 is an energy diagram of hydrogen ion species;

FIG. 26 is a diagram illustrating the results of ion mass spectrometry;

FIG. 27 is a diagram illustrating the results of Raman spectroscopy of a single crystal silicon layer;

FIGS. 28A and 28B are diagrams illustrating the results obtained from the measurement data of the EBSP of the surface of the single crystal silicon layer;

FIG. 29 is an SEM image of the single crystal silicon layer;

FIG. 30 is a diagram illustrating the results of ion mass spectrometry;

FIG. 31 is a diagram illustrating the profile (measured values and calculated values) of hydrogen in the depth direction when the accelerating voltage is 80 kV;

FIG. 32 is a diagram illustrating the profile (measured values, calculated values, and fitting function) of hydrogen in the depth direction when the accelerating voltage is 80 kV;

FIG. 33 is a diagram illustrating the profile (measured values, calculated values, and fitting function) of hydrogen in the depth direction when the accelerating voltage is 60 kV;

FIG. 34 is a diagram illustrating the profile (measured values, calculated values, and fitting function) of hydrogen in the depth direction when the accelerating voltage is 40 kV; and

FIG. 35 is a list of ratios of fitting parameters (hydrogen atom ratios and hydrogen ion species ratios).

### DETAILED DESCRIPTION OF THE INVENTION

Embodiment Modes of the present invention will be hereinafter described with reference to the accompanying drawings. However, the present invention is not limited to the descriptions below, and it is easily understood by those skilled in the art that modes and details thereof can be modified in various ways without departing from the purpose and the scope of the present invention. Therefore, the present invention should not be construed as being limited to the description of the embodiment modes to be given below. Note that, in the structures of the present invention described below, like portions or portions having similar functions are denoted by common reference numerals in different drawings, and repetitive description thereof is omitted.

### Embodiment Mode 1

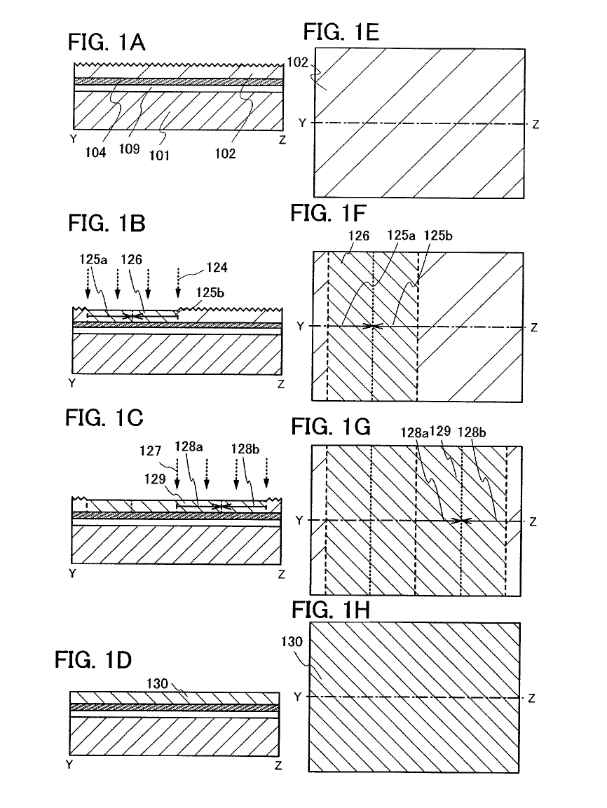

A method for manufacturing a semiconductor device of the present invention will be described with reference to FIGS. 1A to 1H, FIGS. 2A to 2F, FIGS. 3A to 3D and FIGS. 4A to 4C.

In this embodiment mode, in manufacturing a semiconductor substrate, pulsed laser light irradiation is performed for re-single-crystallization of a single crystal semiconductor layer which is separated from a single crystal semiconductor substrate and bonded to a supporting substrate having an insulating surface.

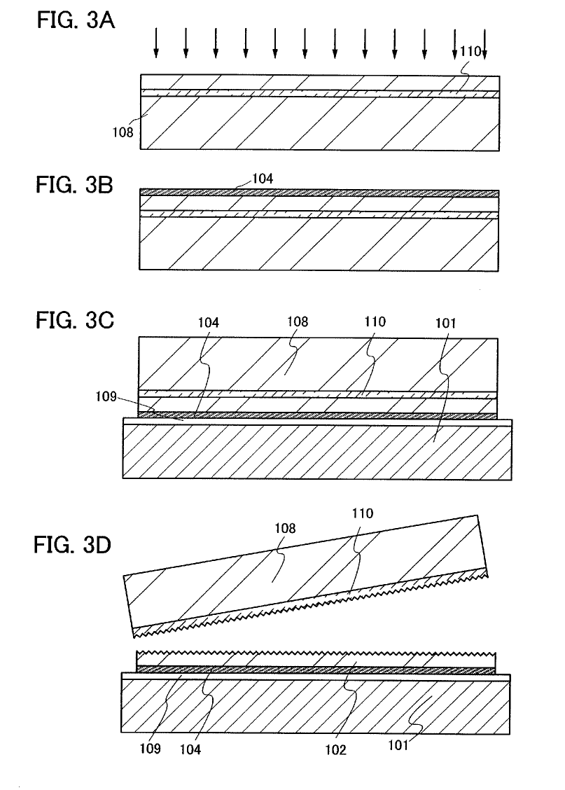

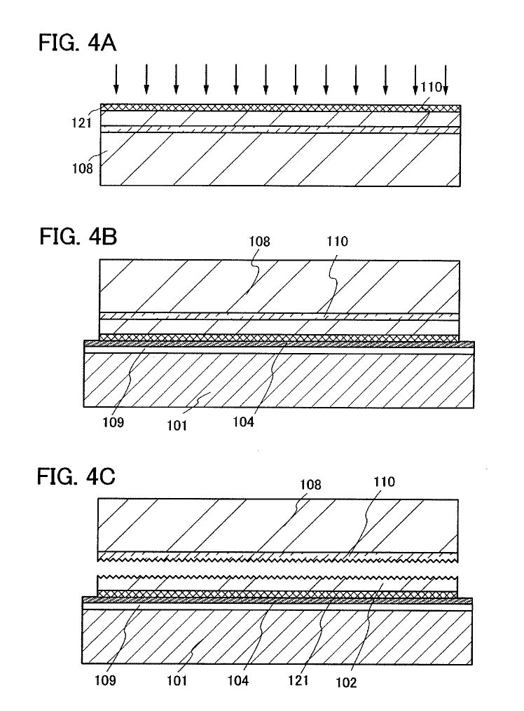

First, a method for providing a single crystal semiconductor layer from a single crystal semiconductor substrate over a supporting substrate having an insulating surface, will be described with reference to FIGS. 3A to 3D and FIGS. 4A to 4C.

A single crystal semiconductor substrate 108 illustrated in FIG. 3A is cleaned, and ions accelerated by an electric field are added to reach a predetermined depth from the surface to form an embrittlement layer 110. The ions are added in consideration of the thickness of a single crystal semiconductor layer to be transferred to a supporting substrate. An accelerating voltage in adding the ions is set in consideration of such a thickness, so that the ions are added to the single crystal semiconductor substrate 108. In the present invention, a region which is embrittled by adding ions to a single crystal semiconductor substrate so that the region can include microvoids is referred to as an embrittlement layer.

As the single crystal semiconductor substrate 108, a commercial single crystal semiconductor substrate can be used; for example, a single crystal semiconductor substrate that is formed of a group IV element, such as a single crystal silicon substrate, a single crystal germanium substrate, a single crystal silicon germanium substrate, or the like can be used. In addition, a compound semiconductor substrate of gallium arsenide, indium phosphide, or the like can be used. Needless to say, the single crystal semiconductor substrate is not limited to a circular wafer, and various shapes of single crystal semiconductor substrates can be used. For example, a polygonal substrate such as a rectangular substrate, a pentagonal substrate, a hexagonal substrate, or the like can be used. Needless to say, a commercial circular single crystal semiconductor wafer can be used as the single crystal semiconductor substrate. As a circular single crystal semiconductor wafer, a semiconductor wafer of silicon, germanium, or the like; a compound semiconductor wafer of gallium arsenide, indium phosphide, or the like; or the like can be used. A typical example of the single crystal semiconductor wafer is a single crystal silicon wafer, and a circular wafer having a diameter of 5 inches (125 mm), a circular wafer having a diameter of 6 inches (150 mm), a circular wafer having a diameter of 8 inches (200 mm), a circular wafer having a diameter of 12 inches (300 mm), a circular wafer having a diameter of 400 mm, or a circular wafer having a diameter of 450 mm can be used. In addition, a rectangular single crystal semiconductor substrate can be formed by cutting a commercial circular single crystal semiconductor wafer. The substrate can be cut with a cutting apparatus such as a dicer or a wiresaw, a laser, plasma, an electronic beam, or any other cutting means. In addition, a rectangular single crystal semiconductor substrate can be formed in such a way that an ingot for manufacturing a semiconductor substrate before being sliced into a substrate is processed into a rectangular solid so as to have a rectangular section and this rectangular solid ingot is sliced. In addition, although there is no particular limitation on the thickness of the single crystal semiconductor substrate, a thick single crystal semiconductor substrate is preferable because many single crystal semiconductor layers can be formed from one piece of thick material wafer, in consideration of reuse of the single crystal semiconductor substrate. The thickness of single crystal silicon wafers circulating in the market conforms to SEMI standards, which specify that, for example, a wafer with a diameter of 6 inches has a thickness of 625 μm, a wafer with a diameter of 8 inches has a thickness of 725 μm, and a wafer with a diameter of 12 inches has a thickness of 775 μm. Note that the thickness of a wafer conforming to SEMI standards has a tolerance of ±25 μm. Needless to say, the thickness of the single crystal semiconductor substrate which is a material is not limited to SEMI standards, and the thickness of the single crystal semiconductor substrate can be adjusted as appropriate when an ingot is sliced. Needless to say, when a reused single crystal semiconductor substrate 108 is used, the thickness thereof is thinner than that of SEMI standards. A single crystal semiconductor layer obtained over a supporting substrate can be determined by selecting a semiconductor substrate to serve as a base.

Further, the crystal plane orientation of the single crystal semiconductor substrate 108 may be selected depending on a semiconductor element to be manufactured (a field effect transistor in this embodiment mode). For example, a single crystal semiconductor substrate having a crystal plane {100}, a crystal plane {110}, or the like can be used.

In this embodiment mode, an ion addition separation method in which hydrogen, helium, or fluorine ions are added to reach a predetermined depth of the single crystal semiconductor substrate, heat treatment is then conducted, and a single crystal semiconductor layer, which is an outer layer, is separated is used. Alternatively, a method in which single crystal silicon is epitaxially grown on porous silicon and the porous silicon layer is separated by cleavage with water jetting may also be employed.

For example, a single crystal silicon substrate is used as the single crystal semiconductor substrate 108, the surface thereof is processed with dilute hydrofluoric acid, a film which is naturally oxidized is removed and a contaminant such as dust or the like which is attached to the surface is also removed, and the surface of the single crystal semiconductor substrate 108 is cleaned.

The embrittlement layer 110 may be formed by adding (introducing) ions by an ion doping method (abbreviated as an ID method) or an ion implantation method (abbreviated as an II method). The embrittlement layer 110 is formed by adding ions of hydrogen, helium, or a halogen typified by fluorine. When fluorine ions are added as a halogen element, BF₃ may be used as a source gas. Note that ion implantation is a method in which ionized gas is mass-separated and added to a semiconductor.

For example, ionized hydrogen gas is mass-separated by an ion implantation method and only H⁺ ions (or only H₂⁺ ions) can be accelerated selectively and added.

In an ion doping method, without mass separation of an ionized gas, plural kinds of ion species are generated in plasma and accelerated, and then a single crystal semiconductor substrate is doped with the accelerated ion species. In the case where the single crystal semiconductor substrate is doped with hydrogen ions including H⁺ ions, H₂⁺ ions, and H₃⁺ ions, the proportion of H₃⁺ ions is greater than or equal to 50%, for example, in general, the proportion of H₃⁺ ions is 80% and the proportion of other ions (H⁺ ions and H₂⁺ ions) is 20%. Here, an ion doping also includes addition of only ion species of H₃⁺ ions.

In addition, a single kind of ions or plural kinds of ions of the same atom which have different masses may be added. For example, when hydrogen ions are added, it is preferable to contain H⁺ ions, H₂⁺ ions, and H₃⁺ ions and to have a high proportion of H₃⁺ ions. In the case of adding hydrogen ions, when H⁺ ions, H₂⁺ ions, and H₃⁺ ions are contained and the proportion of H₃⁺ ions is high, addition efficiency can be increased and addition time can be shortened. With such a structure, separation can be performed easily.

Hereinafter, an ion doping method and an ion implantation method will be described in detail. With the use of an ion doping apparatus (also referred to as an ID apparatus) used in an ion doping method, since the plasma space is large, a large amount of ions can be added to the single crystal semiconductor substrate. On the other hand, an ion implantation apparatus (also referred to as an II apparatus) used in an ion implantation method has a characteristic that ions extracted from plasma are mass analyzed and only specific ion species can be implanted into a semiconductor substrate. In the ion implantation method, basically, processing is performed by scanning with a point beam.

Both of the apparatuses generate a plasma state by thermoelectrons which are generated by heating of a filament. However, an ion doping method and an ion implantation method differ greatly in the proportion of the hydrogen ion species in adding (introducing) hydrogen ions (H⁺, H₂⁺, H₃⁺), which are generated, to the semiconductor substrate.

An ion irradiation method, which is one aspect of the present invention, is considered below.

In the present invention, a single crystal semiconductor substrate is irradiated with ions that are derived from hydrogen (H) (hereafter referred to as “hydrogen ion species”). More specifically, a hydrogen gas or a gas which contains hydrogen in its composition is used as a source material; a hydrogen plasma is generated; and a single crystal semiconductor substrate is irradiated with the hydrogen ion species in the hydrogen plasma.

(Ions in Hydrogen Plasma)

In such a hydrogen plasma as described above, hydrogen ion species such as H⁺, H₂⁺, and H₃⁺ are present. Here are listed reaction equations for reaction processes (formation processes, destruction processes) of the hydrogen ion species.

e+H→e+H⁺+e (1)

e+H₂→e+H₂⁺+e (2)

e+H₂→e+(H₂)*→e+H+H (3)

e+H₂⁺→e+(H₂⁺)*→e+H⁺+H (4)

H₂⁺+H₂→H₃⁺+H (5)

H₂⁺+H₂→H⁺+H+H₂ (6)

e+H₃⁺→e+H⁺+H+H (7)

e+H₃⁺→H₂+H (8)

e+H₃⁺→H+H+H (9)

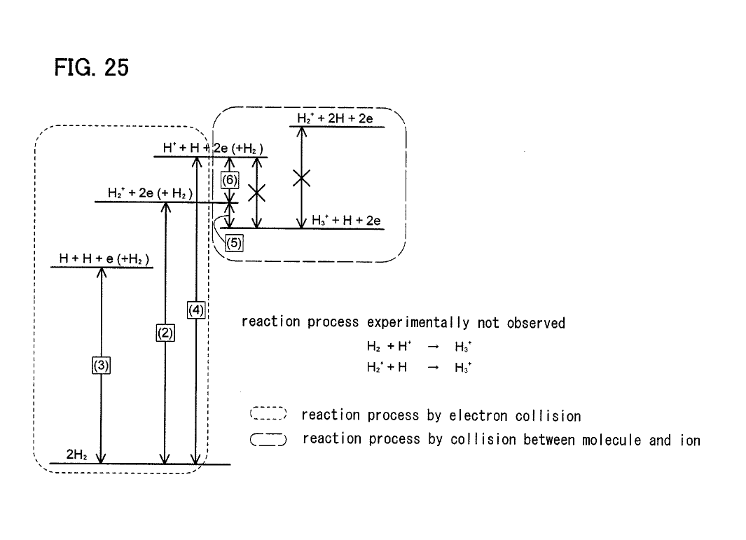

FIG. 25 is an energy diagram which schematically illustrates some of the above reactions. Note that the energy diagram illustrated in FIG. 25 is merely a schematic diagram and does not depict the relationships of energies of the reactions exactly.

(H₃⁺ Formation Process)

As shown above, H₃⁺ is mainly produced through the reaction process that is represented by the reaction equation (5). On the other hand, as a reaction that competes with the reaction equation (5), there is the reaction process represented by the reaction equation (6). For the amount of H₃⁺ to increase, at the least, it is necessary that the reaction of the reaction equation (5) occur more often than the reaction of the reaction equation (6) (note that because there are also other reactions, (7), (8), and (9), through which the amount of H₃⁺ is decreased, the amount of H₃⁺ is not necessarily increased even if the reaction of the reaction equation (5) occurs more often than the reaction of the reaction equation (6)). In contrast, when the reaction of the reaction equation (5) occurs less often than the reaction of the reaction equation (6), the proportion of H₃⁺ in a plasma is decreased.

The amount of increase in the product on the right-hand side (rightmost side) of each reaction equation given above depends on the density of a source material on the left-hand side (leftmost side) of the reaction equation, the rate coefficient of the reaction, and the like. Here, it is experimentally confirmed that, when the kinetic energy of H₂⁺ is lower than approximately 11 eV, the reaction of the reaction equation (5) is the main reaction (that is, the rate coefficient of the reaction equation (5) is sufficiently higher than the rate coefficient of the reaction equation (6)) and that, when the kinetic energy of H₂⁺ is higher than approximately 11 eV, the reaction of the reaction equation (6) is the main reaction.

A force is exerted on a charged particle by an electric field, and the charged particle gains kinetic energy. The kinetic energy corresponds to the amount of decrease in potential energy due to an electric field. For example, the amount of kinetic energy a given charged particle gains before colliding with another particle is equal to the difference between a potential energy at a potential before the charged particle moves and a potential energy at a potential before the collision. That is, in a situation where a charged particle can travel a long distance in an electric field without colliding with another particle, the kinetic energy (or the average thereof) of the charged particle tends to be higher than that in a situation where the charged particle cannot. Such a tendency toward an increase in kinetic energy of a charged particle can be shown in a situation where the mean free path of a particle is long, that is, in a situation where pressure is low.

Even in a situation where the mean free path is short, the kinetic energy of a charged particle is high if the charged particle can gain a high amount of kinetic energy while traveling through the path. That is, it can be said that, even in the situation where the mean free path is short, the kinetic energy of a charged particle is high if the potential difference is large.

This is applied to H₂⁺. Assuming that an electric field is present as in a plasma generation chamber, the kinetic energy of H₂⁺ is high in a situation where the pressure inside the chamber is low and the kinetic energy of H₂⁺ is low in a situation where the pressure inside the chamber is high. That is, because the reaction of the reaction equation (6) is the main reaction in the situation where the pressure inside the chamber is low, the amount of H₃⁺ tends to be decreased, and because the reaction of the reaction equation (5) is the main reaction in the situation where the pressure inside the chamber is high, the amount of H₃⁺ tends to be increased. In addition, in a situation where an electric field in a plasma generation region is high, that is, in a situation where the potential difference between given two points is large, the kinetic energy of H₂⁺ is high, and in the opposite situation, the kinetic energy of H₂⁺ is low. That is, because the reaction of the reaction equation (6) is the main reaction in the situation where the electric field is high, the amount of H₃⁺ tends to be decreased, and because the reaction of the reaction equation (5) is the main reaction in a situation where the electric field is low, the amount of H₃⁺ tends to be increased.

(Differences Depending on Ion Source)

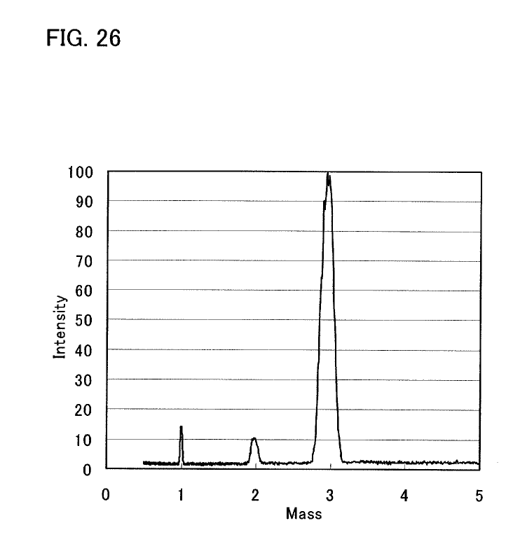

Here, an example, in which the proportions of ion species (particularly, the proportion of H₃⁺) are different, is described. FIG. 26 is a graph illustrating the results of mass spectrometry of ions that are generated from a 100% hydrogen gas (with the pressure of an ion source of 4.7×10⁻² Pa). Note that this mass spectrometry was performed by measurement of ions that were extracted from the ion source. The horizontal axis represents ion mass. In the spectrum, the mass 1 peak, the mass 2 peak, and the mass 3 peak correspond to H⁺, H₂⁺, and H₃⁺, respectively. The vertical axis represents the intensity of the spectrum, which corresponds to the number of ions. In FIG. 26, the number of ions with different masses is expressed as a relative proportion where the number of ions with a mass of 3 is defined as 100. It can be seen from FIG. 26 that the ratio between ion species that are generated from the ion source, i.e., the ratio between H⁺, H₂⁺, and H₃⁺, is approximately 1:1:8. Note that ions at such a ratio can also be generated by an ion doping apparatus which has a plasma source portion (ion source) that generates plasma, an extraction electrode that extracts an ion beam from the plasma, and the like.

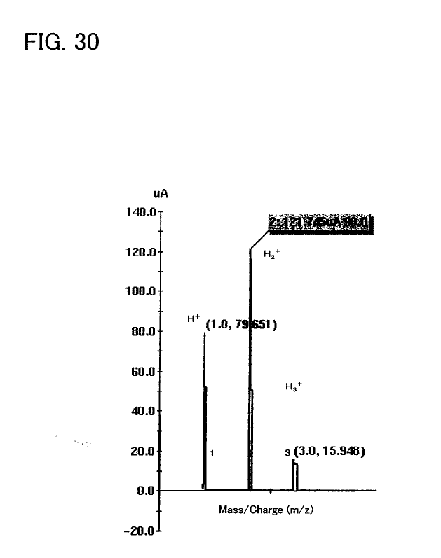

FIG. 30 is a graph illustrating the results of mass spectrometry of ions that are generated from PH₃ when an ion source different from that for the case of FIG. 26 is used and the pressure of the ion source is approximately 3×10⁻³ Pa. The results of this mass spectrometry focus on the hydrogen ion species. In addition, the mass spectrometry was performed by measurement of ions that were extracted from the ion source. As in FIG. 26, the horizontal axis represents ion mass, and the mass 1 peak, the mass 2 peak, and the mass 3 peak correspond to H⁺, H₂⁺, and H₃⁺, respectively. The vertical axis represents the intensity of a spectrum corresponding to the number of ions. It can be seen from FIG. 30 that the ratio between ion species in a plasma, i.e., the ratio between H⁺, H₂⁺, and H₃⁺, is approximately 37:56:7. Note that although FIG. 30 illustrates the data obtained when the source gas is PH₃, the ratio between the hydrogen ion species is about the same when a 100% hydrogen gas is used as a source gas, as well.

In the case of the ion source from which the data illustrated in FIG. 30 is obtained, H₃⁺, of H⁺, H₂⁺, and H₃⁺, is generated at a proportion of only approximately 7%. On the other hand, in the case of the ion source from which the data illustrated in FIG. 26 is obtained, the proportion of H₃⁺ can be greater than or equal to 50% (under the above-described conditions, approximately 80%). This is thought to result from the pressure and electric field inside a chamber, which is clearly shown in the above consideration.

(H₃⁺ Irradiation Mechanism)

When a plasma that contains a plurality of ion species as illustrated in FIG. 26 is generated and a single crystal semiconductor substrate is irradiated with the generated ion species without any mass separation being performed, the surface of the single crystal semiconductor substrate is irradiated with each of H⁺, H₂⁺, and H₃⁺ ions. In order to reproduce the mechanism, from the irradiation with ions to the formation of an ion-introduced region, the following five types of models are considered.

Model 1, where the ion species used for irradiation is H⁺, which is still H⁺(H) after the irradiation.

Model 2, where the ion species used for irradiation is H₂⁺, which is still H₂⁺(H₂) after the irradiation.

Model 3, where the ion species used for irradiation is H₂⁺, which splits into two H atoms (H⁺ ions) after the irradiation.

Model 4, where the ion species used for irradiation is H₃⁺, which is still H₃⁺(H₃) after the irradiation.

Model 5, where the ion species used for irradiation is H₃⁺, which splits into three H atoms (H⁺ ions) after the irradiation.

(Comparison of Simulation Results with Measured Values)

Based on the above models, the irradiation of an Si substrate with hydrogen ion species was simulated. As simulation software, SRIM, the Stopping and Range of Ions in Matter (an improved version of TRIM, the Transport of Ions in Matter, which is simulation software for ion introduction processes by a Monte Carlo method) was used. Note that for the calculation, a calculation based on Model 2 was performed with the H₂⁺ replaced by H⁺ that has twice the mass. In addition, a calculation based on Model 4 was performed with the H₃⁺ replaced by H⁺ that has three times the mass. Furthermore, a calculation based on Model 3 was performed with the H₂⁺ replaced by H⁺ that has half the kinetic energy, and a calculation based on Model 5, with the H₃⁺ replaced by H⁺ that has one-third the kinetic energy.

Note that SRIM is software intended for amorphous structures, but SRIM can be applied to cases where irradiation with the hydrogen ion species is performed with high energy at a high dose. This is because the crystal structure of an Si substrate changes into a non-single crystal structure due to the collision of the hydrogen ion species with Si atoms.

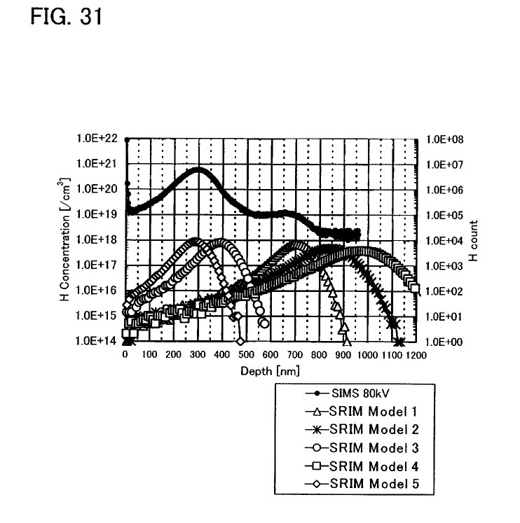

FIG. 31 illustrates the calculation results obtained when irradiation with the hydrogen ion species (irradiation with 100,000 atoms for H) is performed using Models 1 to 5. FIG. 26 also illustrates the hydrogen concentration (secondary ion mass spectrometry (SIMS) data) in an Si substrate irradiated with the hydrogen ion species of FIG. 26. The results of calculations performed using Models 1 to 5 are expressed on the vertical axis (right axis) as the number of hydrogen atoms, and the SIMS data is expressed on the vertical axis (left axis) as the density of hydrogen atoms. The horizontal axis represents depth from the surface of an Si substrate. If the SIMS data, which is measured values, is compared with the calculation results, Models 2 and 4 obviously do not match the peaks of the SIMS data and a peak corresponding to Model 3 cannot be observed in the SIMS data. This shows that the contribution of each of Models 2 to 4 is relatively small. Considering that the kinetic energy of ions is on the order of kiloelectron volts whereas the H—H bond energy is only approximately several electron volts, it is thought that the contribution of each of Models 2 and 4 is small because H₂⁺ and H₃⁺ mostly split into H⁺ or H by colliding with Si atoms.

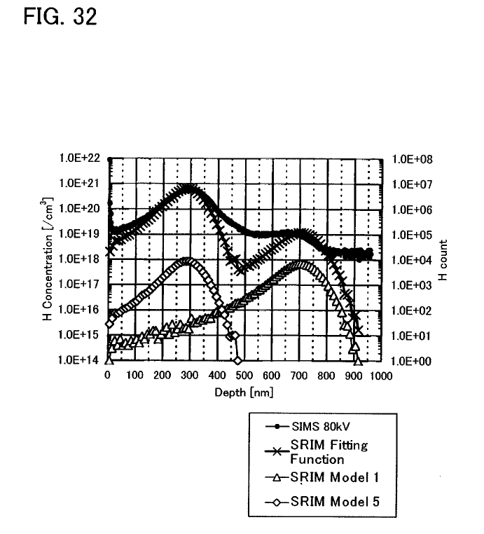

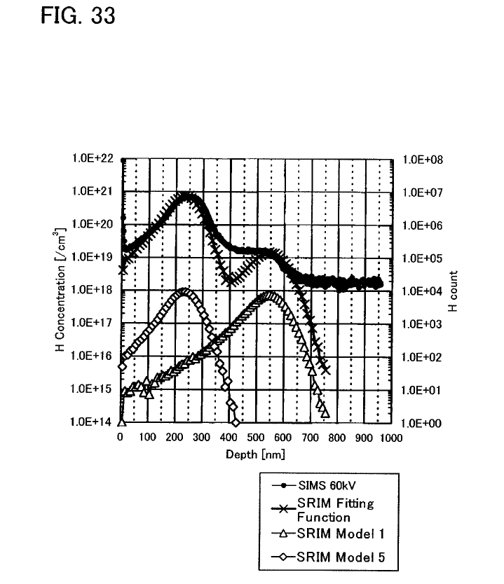

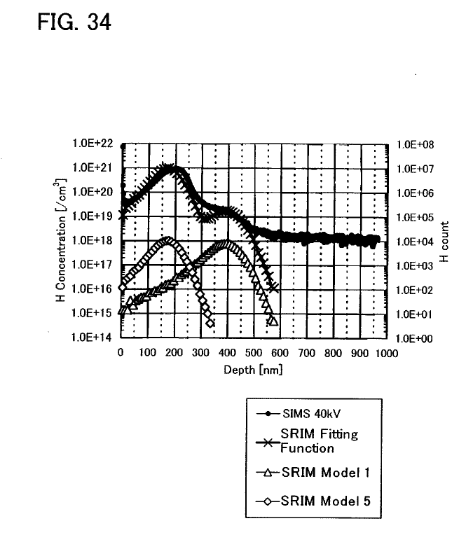

Accordingly, Models 2 to 4 will not be considered hereinafter. FIGS. 32 to 34 each illustrate the calculation results obtained when irradiation with the hydrogen ion species (irradiation with 100,000 atoms for H) is performed using Models 1 and 5. FIGS. 32 to 34 also each illustrate the hydrogen concentration (SIMS data) in an Si substrate irradiated with the hydrogen ion species of FIG. 26, and the simulation results fitted to the SIMS data (hereinafter referred to as a fitting function). Here, FIG. 32 illustrates the case where the acceleration voltage is 80 kV; FIG. 33, the case where the acceleration voltage is 60 kV; and FIG. 34, the case where the acceleration voltage is 40 kV. Note that the results of calculations performed using Models 1 and 5 are expressed on the vertical axis (right axis) as the number of hydrogen atoms, and the SIMS data and the fitting function are expressed on the vertical axis (left axis) as the density of hydrogen atoms. The horizontal axis represents depth from the surface of an Si substrate.

The fitting function is obtained using the calculation formula given below, in consideration of Models 1 and 5. Note that in the calculation formula, X and Y represent fitting parameters and V represents volume.

(Fitting Function)=X/V×(Data of Model 1)+Y/V×(Data of Model 5)

In consideration of the ratio between ion species used for actual irradiation (H⁺:H₂⁺:H₃⁺ is approximately 1:1:8), the contribution of H₂⁺ (i.e., Model 3) should also be considered; however, Model 3 is excluded from the consideration given here for the following reasons:
Because the amount of hydrogen introduced through the irradiation process represented by Model 3 is lower than that introduced through the irradiation process of Model 5, there is no significant influence even if Model 3 is excluded from the consideration (no peak appears in the SIMS data either).
Model 3, the peak position of which is close to that of Model 5, is likely to be obscured by channeling (movement of atoms due to crystal lattice structure) that occurs in Model 5. That is, it is difficult to estimate fitting parameters for Model 3. This is because this simulation assumes amorphous Si, and the influence due to crystallinity is not considered.

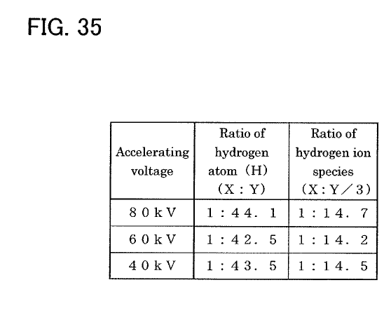

FIG. 35 lists the above-described fitting parameters. At any of the acceleration voltages, the ratio of the amount of H introduced according to Model 1 to that introduced according to Model 5 is approximately 1:42 to 1:45 (the amount of H in Model 5, when the amount of H in Model 1 is defined as 1, is approximately 42 to 45), and the ratio of the number of ions used for irradiation, H⁺ (Model 1) to that of H₃⁺ (Model 5) is approximately 1:14 to 1:15 (the amount of H₃⁺ in Model 5, when the amount of H⁺ in Model 1 is defined as 1, is approximately 14 to 15). Considering that Model 3 is not considered and the calculation assumes amorphous Si, it can be said that values close to that of the ratio between ion species used for actual irradiation (H⁺:H₂⁺:H₃⁺ is approximately 1:1:8) is obtained.

(Effects of Use of H₃⁺)

A plurality of benefits resulting from H₃⁺ can be enjoyed by irradiation of a substrate with hydrogen ion species with a higher proportion of H₃⁺ as illustrated in FIG. 26. For example, because H₃⁺ splits into H⁺, H, or the like to be introduced into a substrate, ion introduction efficiency can be improved compared with the case of irradiation mainly with H⁺ or H₂⁺. This leads to an improvement in semiconductor substrate production efficiency. In addition, because the kinetic energy of H⁺ or H after H₃⁺ splits similarly tends to be low, H₃⁺ is suitable for manufacture of thin semiconductor layers.

Note that in this specification, a method is described in which an ion doping apparatus that is capable of irradiation with the hydrogen ion species as illustrated in FIG. 26 is used in order to efficiently perform irradiation with H₃⁺. Ion doping apparatuses are inexpensive and excellent for use in large-area treatment. Therefore, by irradiation with H₃⁺ with the use of such an ion doping apparatus, significant effects such as an improvement in semiconductor characteristics, an increase in area, a reduction in costs, and an improvement in production efficiency can be obtained. On the other hand, if first priority is given to irradiation with H₃⁺, there is no need to interpret the present invention as being limited to the use of an ion doping apparatus.

When halogen ions such as fluorine ions are added to the single crystal silicon substrate, fluorine which is added knocks out (expels) silicon atoms in silicon crystal lattice, so that blank portions are created effectively and microvoids are made in the embrittlement layer. In this case, the volume change of the microvoids formed in the embrittlement layer occurs by heat treatment at a relatively low temperature, and a thin single crystal semiconductor layer can be formed by cleavage along the embrittlement layer. After the addition of fluorine ion, hydrogen ions may be added, so that hydrogen may be contained in the voids. Since the embrittlement layer which is formed to separate the thin semiconductor layer from the single crystal semiconductor substrate is cleaved using the volume change of the microvoids formed in the embrittlement layer, it is preferable to make effective use of fluorine ion action or hydrogen ion action in the above-described manner.

Note that, in this specification, a silicon oxynitride film means a film that contains more oxygen than nitrogen and, in the case where measurements are performed using Rutherford backscattering spectrometry (RBS) and hydrogen forward scattering (HFS), includes oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively. Further, a silicon nitride oxide film means a film that contains more nitrogen than oxygen and, in the case where measurements are performed using RBS and HFS, includes oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively. Note that percentages of nitrogen, oxygen, silicon, and hydrogen fall within the ranges given above, where the total number of atoms contained in the silicon oxynitride film or the silicon nitride oxide film is defined as 100 at. %.

In addition, a protection layer may be formed between the single crystal semiconductor substrate and the insulating layer which is to be bonded to the single crystal semiconductor layer. The protection layer can be a single layer or a stacked structure of a plurality of layers selected from a silicon nitride layer, a silicon oxide layer, a silicon nitride oxide layer, or a silicon oxynitride layer. These layers can be formed over the single crystal semiconductor substrate before the embrittlement layer is formed in the single crystal semiconductor substrate. Alternatively, these layers may be formed over the single crystal semiconductor substrate after the embrittlement layer is formed in the semiconductor substrate.

It is necessary to add ions under high dose conditions in the formation of the embrittlement layer, and the surface of the single crystal semiconductor substrate 108 becomes rough in some cases. Therefore, a protection layer against the ion addition, such as a silicon nitride film, a silicon nitride oxide film, or a silicon oxide film may be provided with a film thickness of 50 nm to 200 nm on the surface through which ions are added.

For example, a stacked layer of a silicon oxynitride film (a film thickness of 5 nm to 300 nm, preferably 30 nm to 150 nm (e.g., 50 nm)) and a silicon nitride oxide film (a film thickness of 5 nm to 150 nm, preferably 10 to 100 nm (e.g., 50 nm)) is formed by a plasma CVD method as the protection layer over the single crystal semiconductor substrate 108. As an example, a silicon oxynitride film is formed with a film thickness of 50 nm over the single crystal semiconductor substrate 108, and a silicon nitride oxide film is formed with a thickness of 50 nm over the silicon oxynitride film to be stacked. A silicon oxynitride film may be a silicon oxide film formed by a chemical vapor deposition method using an organosilane gas.

Alternatively, the single crystal semiconductor substrate 108 may be degreased and washed, an oxide film of the surface may be removed, and thermal oxidation may be performed. Although normal dry oxidation for thermal oxidation may be performed, it is preferable to perform oxidation in an oxidative atmosphere to which halogen is added. For example, heat treatment is performed at a temperature of greater than or equal to 700° C. in an atmosphere which contains HCl at 0.5 to 10% by volume (preferably 3% by volume) with respect to oxygen. Preferably, thermal oxidation is performed at a temperature of 950° C. to 1100° C. Processing time may be set at 0.1 to 6 hours, preferably 0.5 to 3.5 hour. An oxide film to be formed has a thickness of 10 nm to 1000 nm (preferably 50 nm to 200 nm), for example, 100 nm.

Instead of HCl, one or more selected from HF, NF₃, HBr, Cl₂, ClF₃, BCl₃, F₂, Br₂, or the like can be used as a substance containing a halogen.

Heat treatment is performed in such a temperature range, so that a gettering effect can be obtained by a halogen element. The gettering has an advantageous effect of removing a metal impurity, in particular. That is, by the action of chlorine, an impurity such as metal turns into volatile chloride, and then moved into the air and removed. It has an advantageous effect on the case where the surface of the single crystal semiconductor substrate 108 is subjected to a chemical mechanical polishing (CMP) treatment. In addition, hydrogen has action of compensating a defect at the interface between the single crystal semiconductor substrate 108 and the oxide film to be formed so as to lower a localized-level density at the interface, whereby the interface between the single crystal semiconductor substrate 108 and the oxide film is inactivated to stabilize electric characteristics.

A halogen can be contained in the oxide film which is formed by heat treatment. A halogen element is contained at a concentration of 1×10¹⁷/cm³ to 5×10²⁰/cm³, whereby the oxide film can function as a protection layer which captures an impurity such as metal and prevents contamination of the single crystal semiconductor substrate 108.

When the embrittlement layer 110 is formed, the accelerating voltage and the number of total ions can be adjusted by the thickness of a film deposited over the single crystal semiconductor substrate, the thickness of the targeted single crystal semiconductor layer which is separated from the single crystal semiconductor substrate and transferred to a supporting substrate, and ion species which are added.

For example, a hydrogen gas is used for a raw material, and ions are added at an accelerating voltage of 40 kV with the total ion number of 2×10¹⁶ ions/cm² by an ion doping method, so that the embrittlement layer can be formed. If the protection layer is made to be thick, when ions are added under the same condition and the embrittlement layer is formed, a thin single crystal semiconductor layer can be formed as a targeted single crystal semiconductor layer which is separated from the single crystal semiconductor substrate and transposed (transferred) to the supporting substrate. For example, although it depends on the proportion of ion species (H⁺, H₂⁺, and H₃⁺ ions), in the case where the embrittlement layer is formed under the above conditions and a silicon oxynitride film (film thickness: 50 nm) and a silicon nitride oxide film (film thickness: 50 nm) are stacked as a protection layer over the single crystal semiconductor substrate, the film thickness of the single crystal semiconductor layer to be transferred to the supporting substrate is approximately 120 nm; and in the case where a silicon oxynitride film (film thickness: 100 nm) and a silicon nitride oxide film (film thickness: 50 nm) are stacked as a protection layer over the single crystal semiconductor substrate under the above conditions, the film thickness of the single crystal semiconductor layer to be transferred to the supporting substrate is approximately 70 nm.

When helium (He) or hydrogen is used for a source gas, addition is performed with an accelerating voltage in the range of 10 kV to 200 kV with a dose in the range of 1×10¹⁶ ions/cm² to 6×10¹⁶ ions/cm², so that the embrittlement layer can be formed. When helium is used as a source gas, He⁺ ions can be added as main ions even when mass separation is not performed. In addition, when hydrogen is used as a source gas, H₃⁺ ions and H₂⁺ ions can be added as main ions. The ion species changes depending on a plasma generation method, the pressure, the supply quantity of a source gas, or the accelerating voltage.

As an example of forming the embrittlement layer, a silicon oxynitride film (film thickness: 50 nm), a silicon nitride oxide film (film thickness: 50 nm), and a silicon oxide film (film thickness: 50 nm) are stacked as a protection layer over the single crystal semiconductor substrate, hydrogen is added at an accelerating voltage of 40 kV with a dose of 2×10¹⁶ ions/cm², and the embrittlement layer is formed in the single crystal semiconductor substrate. Then, a silicon oxide film (film thickness: 50 nm) is formed as an insulating layer having a bonding surface over the silicon oxide film, which is an uppermost layer of the protection layer. As another example of forming the embrittlement layer, a silicon oxide film (film thickness: 100 nm) and a silicon nitride oxide film (film thickness: 50 nm) are stacked as a protection layer over the single crystal semiconductor substrate, and hydrogen is added at an accelerating voltage of 40 kV with a dose of 2×10¹⁶ ions/cm², and the embrittlement layer is formed in the single crystal semiconductor substrate. Then, a silicon oxide film (film thickness: 50 nm) is formed as an insulating layer having a bonding surface over the silicon nitride oxide film, which is an uppermost layer of the protection layer. Note that the silicon oxynitride film and the silicon nitride oxide film may be formed by a plasma CVD method, and the silicon oxide film may be formed by a CVD method, using an organosilane gas.

In the case where a glass substrate which is used in the electronics industry, such as an aluminosilicate glass substrate, an aluminoborosilicate glass substrate, or a barium borosilicate glass substrate, is used as the supporting substrate 101, alkali metal such as sodium is contained in a very small amount in a glass substrate, and a very small number of impurities may adversely affect the characteristics of semiconductor elements such as transistors. The silicon nitride oxide film has an advantageous effect of preventing such an impurity like a metal impurity contained in the supporting substrate 101 from diffusing into the single crystal semiconductor substrate side. Note that instead of the silicon nitride oxide film, a silicon nitride film may be formed. A stress relaxation layer such as a silicon oxynitride film or a silicon oxide film may be provided between the single crystal semiconductor substrate and the silicon nitride oxide film. When a stacked layer structure of the silicon nitride oxide film and the silicon oxynitride film is provided, an impurity can be prevented from diffusing into the single crystal semiconductor substrate and stress distortion can be reduced.

As a blocking layer (also referred to as a barrier layer), a silicon nitride film or a silicon nitride oxide film for preventing diffusion of an impurity element may be provided for the supporting substrate. Further, a silicon oxynitride film may be combined as an insulating film which has action of relieving stress. As illustrated in FIG. 3C, a blocking layer 109 is formed over the supporting substrate 101.

Next, as illustrated in FIG. 3B, a silicon oxide film is formed as an insulating layer 104 on the surface which forms a bond to the supporting substrate. It is preferable to use a silicon oxide film formed by a chemical vapor deposition method using an organosilane gas, as the silicon oxide film. Alternatively, a silicon oxide film formed by a chemical vapor deposition method using a silane gas, can be used. In film formation by a chemical vapor deposition method, a film formation temperature of, for example, less than or equal to 350° C. (a specific example is 300° C.) is applied as the temperature at which degasification does not occur from the embrittlement layer 110, which is formed in the single crystal semiconductor substrate. In addition, heat treatment temperature which is higher than the film formation temperature is applied for heat treatment by which the single crystal semiconductor layer is separated from a single crystal semiconductor substrate.

The insulating layer 104 has a smooth surface and forms a hydrophilic surface. A silicon oxide film is suitable for the insulating layer 104. In particular, a silicon oxide film formed by a chemical vapor deposition method using an organosilane gas, is preferable. Examples of organosilane gas which can be used include silicon-containing compounds, such as tetraethoxysilane (TEOS) (chemical formula: Si(OC₂H₅)₄), trimethylsilane (TMS) (chemical formula: (CH₃)₃SiH), tetramethylsilane (chemical formula: Si(CH₃)₄), tetramethylcyclotetrasiloxane (TMCTS), octamethylcyclotetrasiloxane (OMCTS), hexamethyldisilazane (HMDS), triethoxysilane (chemical formula: SiH(OC₂H₅)₃), and trisdimethylaminosilane (chemical formula: SiH(N(CH₃)₂)₃). Note that in the case where a silicon oxide layer is formed by a chemical vapor deposition method, using organosilane as a source gas, it is preferable to mix a gas which provides oxygen. As a gas which provides oxygen, oxygen, nitrous oxide, nitrogen dioxide, or the like can be used. Further, an inert gas such as argon, helium, nitrogen, or hydrogen may be mixed.

Alternatively, as the insulating layer 104, a silicon oxide film formed by a chemical vapor deposition method, using silane such as monosilane, disilane, or trisilane as a source gas, can be used. Also in this case, it is preferable to mix a gas which provides oxygen, an inert gas, or the like. The silicon oxide film which is an insulating layer to form a bond with the single crystal semiconductor layer may contain chlorine. In film formation by a chemical vapor deposition method, a film formation temperature of, for example, less than or equal to 350° C. is applied as the temperature at which degasification does not occur from the embrittlement layer 110, which is formed in the single crystal semiconductor substrate 108. In addition, heat treatment temperature which is higher than the film formation temperature is applied for heat treatment by which a single crystal semiconductor layer is separated from a single crystal semiconductor substrate. Note that in this specification, a chemical vapor deposition (CVD) method includes a plasma CVD method, a thermal CVD method, and a photo CVD method in its category.

In addition, as the insulating layer 104, silicon oxide formed by heat treatment under an oxidative atmosphere, silicon oxide which grows by reaction of an oxygen radical, chemical oxide formed using an oxidative chemical solution, or the like can be used. As the insulating layer 104, an insulating layer including a siloxane (Si—O—Si) bond may be used. Alternatively, the organosilane gas may be reacted with an oxygen radical or a nitrogen radical to form the insulating layer 104.

The insulating layer 104 which has a smooth surface and forms a hydrophilic surface is provided with a thickness of 5 nm to 500 nm, and preferably 10 nm to 200 nm. With such a thickness, it is possible to smooth the surface roughness of the insulating layer 104 and also to ensure smoothness of a growth surface of the insulating layer 104. In addition, the insulating layer 104 is provided, which can ease distortion of the single crystal semiconductor layer that result from bonding to the supporting substrate. The surface of the insulating layer 104 is preferably set as follows: preferably, arithmetic mean roughness Rₐ is less than 0.8 nm and root-mean-square roughness Rₘₛ is less than 0.9 nm; more preferably Rₐ is less than or equal to 0.4 nm and Rₘₛ is less than or equal to 0.5 nm; and still preferably Rₐ is less than or equal to 0.3 nm and Rₘₛ is less than or equal to 0.4 nm. For example, Rₐ is 0.27 nm and Rₘₛ is 0.34 nm. In this specification, Rₐ is arithmetic mean roughness, Rₘₛ is root-mean-square roughness, and the measurement range is 2 μm² or 10 μm².

A silicon oxide film which is similar to the insulating layer 104 may also be provided for a supporting substrate 101. That is, when a single crystal semiconductor layer 102 is bonded to the supporting substrate 101, a strong bond can be formed by preferably providing the insulating layer 104 which is formed of a silicon oxide film deposited using organosilane as a raw material for one surface or both surfaces which form a bond.

In FIG. 3C, a mode is shown in which the blocking layer 109 formed on the supporting substrate 101 and the surface of the insulating layer 104 which is formed on the single crystal semiconductor substrate 108, are disposed in close contact with each other and bonded. Surfaces which are to form a bond are cleaned sufficiently. The surface of the blocking layer 109 formed on the supporting substrate 101 and the surface of the insulating layer 104 which is formed on the single crystal semiconductor substrate 108 may be cleaned by megasonic cleaning or the like. In addition, the surfaces may be cleaned with ozone water after the megasonic cleaning to remove an organic substance and improve the hydrophilicity of the surfaces.

By making the blocking layer 109 on the supporting substrate 101 and the insulating layer 104 face each other and pressing one part thereof from the outside, the blocking layer 109 and the insulating layer 104 attract each other by increase in van der Waals forces or influence of hydrogen bonding due to local reduction in distance between the bonding surfaces. Further, since the distance between the blocking layer on the supporting substrate 101 and the insulating layer 104 in an adjacent region, which also face each other, is reduced, a region in which van der Waals forces strongly act or a region which is influenced by hydrogen bonding is widened. Accordingly, bonding proceeds and spreads to the entire bonding surfaces. For example, a pressure of approximately 100 kPa to 5000 kPa may be applied in pressing. Further, the supporting substrate and the semiconductor substrate can be disposed so as to overlap with each other, so that bonding can spread under the weight of the overlapping substrate.

The surfaces may be activated so as to form a favorable bond. For example, surfaces where a bond is formed are irradiated with an atomic beam or an ion beam. When an atomic beam or an ion beam is used, an inert gas neutral atom beam or an inert gas ion beam of argon or the like can be used. In addition, plasma irradiation or radical treatment is performed. By such surface treatment, a bond between different kinds of materials is easily formed even at a temperature of 200 to 400° C.

In order to improve the bonding strength of a bond interface between the supporting substrate and the insulating layer, heat treatment is preferably performed. For example, heat treatment is performed under a temperature condition of 70° C. to 350° C. (e.g., at 200° C. for 2 hours) in an oven, a furnace, or the like.

In FIG. 3D, after the supporting substrate 101 and the single crystal semiconductor substrate 108 are attached to each other, heat treatment is performed, and the single crystal semiconductor substrate 108 is separated from the supporting substrate 101 using the embrittlement layer 110 as a cleavage plane. When heat treatment is performed at, for example, 400° C. to 700° C., the volume change of the microvoids formed in the embrittlement layer 110 occurs, which enables cleavage along the embrittlement layer 110. Since the insulating layer 104 is bonded to the supporting substrate 101 with the blocking layer 109 interposed therebetween, the single crystal semiconductor layer 102 having the same crystallinity as the single crystal semiconductor substrate 108 remains over the supporting substrate 101.

Heat treatment in a temperature range of 400° C. to 700° C. may be continuously performed with the same device as the above heat treatment for improving the bonding strength or with another device. For example, after heat treatment in a furnace at 200° C. for 2 hours, a temperature is increased to approximately 600° C. and is held for 2 hours, the temperature is decreased to a temperature ranging from 400° C. to a room temperature, and then the substrate is taken out of the furnace. Alternatively, heat treatment may be performed with a temperature increasing from a room temperature. Further, after heat treatment may be performed in a furnace at 200° C. for 2 hours, heat treatment may be performed in a temperature range of 600° C. to 700° C. with a rapid thermal annealing (RTA) device for 1 to 30 minutes (e.g., at 600° C. for 7 minutes, or at 650° C. for 7 minutes).

By heat treatment in a temperature range of 400° C. to 700° C., bonding between the insulating layer and the supporting substrate shifts from hydrogen bonds to covalent bonds, and an element added to the embrittlement layer is separated out and the pressure rises, whereby the single crystal semiconductor layer can be separated from the single crystal semiconductor substrate. After the heat treatment, the supporting substrate and the single crystal semiconductor substrate are in a state where one of the supporting substrate and the single crystal semiconductor substrate is provided over the other, and the supporting substrate and the single crystal semiconductor substrate can be separated from each other without application of large force. For example, a substrate provided over the other is lifted by a vacuum chuck, so that the substrate can be easily separated. At this time, if a substrate on a lower side is fixed with a vacuum chuck or a mechanical chuck, both the supporting substrate and the single crystal semiconductor substrate can be separated from each other without horizontal misalignment.

Note that in FIGS. 3A to 3D, and FIGS. 4A to 4C, an example is shown in which the single crystal semiconductor substrate 108 is smaller than the supporting substrate 101; however, the present invention is not limited thereto, and the single crystal semiconductor substrate 108 and the supporting substrate 101 may have the same size or the single crystal semiconductor substrate 108 may be larger than the supporting substrate 101.

In FIGS. 4A to 4C, steps are illustrated in which the insulating layer is provided on the supporting substrate side and the single crystal semiconductor layer is formed. In FIG. 4A, a step is illustrated in which ions accelerated by an electric field are added to reach a predetermined depth of the single crystal semiconductor substrate 108 provided with a silicon oxide film as a protection layer 121 to form the embrittlement layer 110. Ion addition is performed similarly to the case of FIG. 3A. The protection layer 121 is formed on the surface of the single crystal semiconductor substrate 108, so that the surface can be prevented from being damaged by ion addition and planarity can be prevented from being damaged. In addition, the protection layer 121 has an advantageous effect of preventing the diffusion of an impurity into the single crystal semiconductor layer 102 formed using the single crystal semiconductor substrate 108.

In FIG. 4B, a step is illustrated in which the supporting substrate 101 provided with a blocking layer 109 and the insulating layer 104, and the surface of the single crystal semiconductor substrate 108 on which the protection layer 121 is formed are disposed in close contact with each other to form a bond. The bond is formed by disposing the insulating layer 104 over the supporting substrate 101 in close contact with the protection layer 121 of the single crystal semiconductor substrate 108.

Then, the single crystal semiconductor substrate 108 is separated, as illustrated in FIG. 4C. Heat treatment by which the single crystal semiconductor layer is separated is performed in a similar manner to the case of FIG. 3D. In this manner, a semiconductor substrate having an SOI structure including the single crystal semiconductor layer over the supporting substrate with the insulating layer interposed therebetween, illustrated in FIG. 4C can be obtained.

As the supporting substrate 101, a substrate having an insulating property or a substrate having an insulating surface can be used, and it is possible to use any of a variety of glass substrates which are used in the electronics industry and are referred to as non-alkali glass substrates, such as an aluminosilicate glass substrate, an aluminoborosilicate glass substrate, or a barium borosilicate glass substrate. For example, it is preferable that a non-alkali glass substrate (product name: AN100), a non-alkali glass substrate (product name: EAGLE2000 (registered trademark)), or a non-alkali glass substrate (product name: EAGLE XG (registered trademark)) be used as the supporting substrate 100. Further, instead of a glass substrate, an insulating substrate made of an insulating material, such as a ceramic substrate, a quartz substrate, or a sapphire substrate, or the like can be used.

Through the above-described process, as illustrated in FIGS. 1A and 1E, the blocking layer 109 and the insulating layer 104 are provided over the supporting substrate 101 which is a substrate having an insulating surface, and the single crystal semiconductor layer 102 which is separated from the single crystal semiconductor substrate 108 is formed.

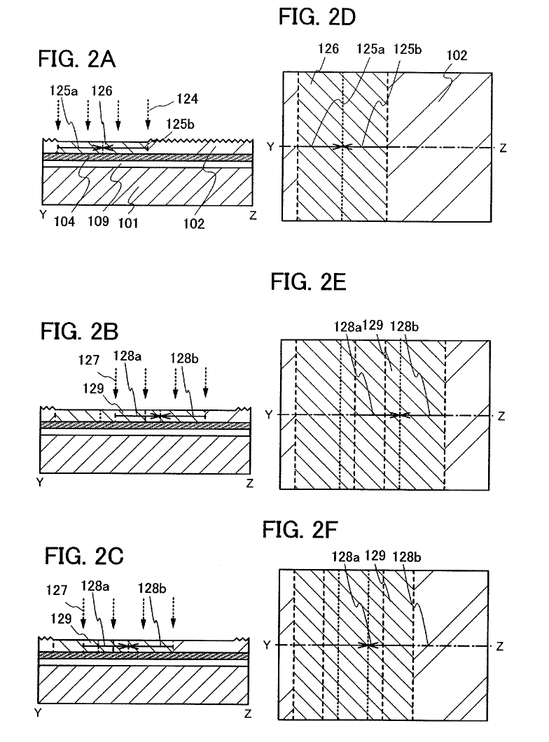

FIGS. 1A to 1D and FIGS. 2A to 2C are plan views and FIGS. 1E to 1H and FIGS. 2D to 2F are cross-sectional views taken along a line Y-Z of FIGS. 1A to 1D and FIGS. 2A to 2C.

The single crystal semiconductor layer 102 over the supporting substrate 101 has crystal defects due to the separation step and the ion addition step. The surface planarity of the single crystal semiconductor layer 102 is damaged and projections and depressions are formed. When a transistor is formed as a semiconductor element using the single crystal semiconductor layer 102, it is difficult to form a thin gate insulating layer with high withstand voltage on the surface of the single crystal semiconductor layer 102 having such projections and depressions. In addition, if the single crystal semiconductor layer 102 has a crystal defect, performance and reliability of the transistor are adversely affected; for example, a local interface state density with the gate insulating layer is increased.

In the present invention, such a single crystal semiconductor layer 102 is irradiated with pulsed laser light 124 and melted completely in a depth direction as well, so that a single crystal semiconductor layer 130 in which re-single-crystallization is caused and which has reduced crystal defects, high crystallinity and high planarity is obtained.

The single crystal semiconductor layer 102 transferred to the supporting substrate 101 is irradiated with the pulsed laser light 124 to cause re-single-crystallization of the single crystal semiconductor layer 102. The entire region in the region of the single crystal semiconductor layer 102, which is irradiated with the laser light 124, is melted at least in a depth direction, and re-single-crystallization is caused toward the center of the irradiation region (a melted region) (in directions indicated by an arrow 125a and an arrow 125b in FIGS. 1B and 1F) using peripheral non-irradiation regions (non-melted regions) as crystal nuclei (seed crystals). Crystal growth occurs from interfaces between the melted region and the non-melted regions at end portions of the melted region toward the inside of the melted region (the center of the melted region), and regions in which re-single-crystallization is caused by the crystal growth are in contact with each other as indicated by the arrow 125a and the arrow 125b, so that re-single-crystallization is caused in the entire region in the region of the single crystal semiconductor layer 102, which is irradiated with the laser light 124. By re-single-crystallization of the single crystal semiconductor layer 102, a single crystal semiconductor region 126 with high crystallinity and high planarity is formed (see FIGS. 1B and 1F). Note that in FIGS. 1A to 1H and FIGS. 2A to 2F, a region where the regions in which re-single-crystallization is caused by the crystal growth are in contact with each other is indicated by a dotted line.

Next, re-single-crystallization is caused by irradiation with laser light 127 of a region adjacent to the single crystal semiconductor region 126 in which re-single-crystallization is caused by irradiation with the laser light 124. The entire region of the region of the single crystal semiconductor layer 102, which is irradiated with the laser light 127, is melted at least in a depth direction, and re-single-crystallization is caused toward the center of the irradiation region (a melted region) (in directions indicated by an arrow 128a and an arrow 128b in FIGS. 1C and 1G) using peripheral non-irradiation regions (non-melted regions) as crystal nuclei (seed crystals). Crystal growth occurs from interfaces between the melted region and the non-melted regions at end portions of the melted region toward the inside of the melted region (the center of the melted region), and regions in which re-single-crystallization is caused by the crystal growth are in contact with each other as indicated by the arrow 128a and the arrow 128b, so that re-single-crystallization is caused in the entire region of the region of the single crystal semiconductor layer 102, which is irradiated with the laser light 127. By re-single-crystallization of the single crystal semiconductor layer 102, a single crystal semiconductor region 129 having high crystallinity and high planarity is formed (see FIGS. 1C and 1G).

The entire region of the single crystal semiconductor layer is melted by irradiation with the laser light and re-single-crystallization is caused in the entire region by repeating re-single-crystallization of the single crystal semiconductor layer by irradiation with the laser light as described above, so that a single crystal semiconductor layer 130 having high crystallinity and high planarity can be formed (see FIGS. 1D and 1H).

In the present invention, the region of the single crystal semiconductor layer, which is irradiated with the laser light, is entirely melted in a depth direction as well. Accordingly, in the present invention, the entire region of the laser light irradiation region in the single crystal semiconductor layer (in a plane direction and a depth direction) is a melted region. In this specification, “the entire region of the laser light irradiation region in the single crystal semiconductor layer” refers to an entire region in a region of a single crystal semiconductor layer, which is irradiated with laser light, in a plane direction and a depth direction. Since the entire region of the laser light irradiation region in the single crystal semiconductor layer is melted completely at least in a depth direction, the melting can be referred to as “complete melting”.

Accordingly, the crystal nuclei (seed crystals) for re-single-crystallization are the peripheral non-melted regions which are not irradiated with the laser light. Crystal growth occurs toward the center of the melted region in a parallel direction to the surface of the single crystal semiconductor layer (or the supporting substrate) using the non-melted regions as the crystal nuclei. Crystal growth occurs from the interfaces between the melted region and the non-melted regions at end portions of the melted region toward the inside (center) of the melted region, and the regions in which re-single-crystallization is caused by the crystal growth are in contact with each other. In this manner, re-single-crystallization is caused in the entire region of the laser light irradiation region in the single crystal semiconductor layer.

In the present invention, since crystal growth which occurs by irradiation with the laser light occurs in a parallel direction to the surface of the single crystal semiconductor layer (or the supporting substrate), the crystal growth is referred to as crystal growth of lateral growth (growth in a lateral direction) when a depth direction (a film thickness direction) to the surface of the single crystal semiconductor layer (or the supporting substrate) is a longitudinal direction.

The crystal growth in the melted region occurs in a supercooled state which is a state where the region of the single crystal semiconductor layer, which is irradiated with the laser light, remains in a melting state without being solidified even when the region is cooled down to a temperature of less than or equal to the melting point after the region is heated to a temperature of greater than or equal to the melting point to be melted by irradiation with the laser light. How long the supercooled state lasts depends on the thickness of the single crystal semiconductor layer, conditions for irradiation with the laser light (energy density, irradiation time (a pulse width), or the like), or the like. When the supercooled state lasts longer, a region in which re-single-crystallization is caused by crystal growth is widened; therefore, a region irradiated with laser light at once can be widened. Accordingly, treatment efficiency is increased and throughput is improved. Further, heating the single crystal semiconductor layer to be irradiated with laser light is effective in extension of time of a supercooled state. The temperature of the single crystal semiconductor layer may be in the range of a room temperature to less than or equal to 500° C. (less than or equal to the strain point of the supporting substrate), and heat treatment of the single crystal semiconductor layer can be performed by heating the supporting substrate or blowing heated gas or the like to the single crystal semiconductor layer.

Accordingly, in the present invention, the region irradiated with the laser light (the melted region) is set to have an area in which the end portions (end portions of crystal growth) of the single crystal regions are in contact with each other by the re-single-crystallization. For example, the shape of a laser light profile (also referred to as a beam profile) in the minor-axis direction of the region of the single crystal semiconductor layer, which is irradiated with the pulsed laser light, is rectangular and the width thereof is less than or equal to 20 μm. The shape of a laser light profile in the minor-axis direction of the region of the single crystal semiconductor layer, which is irradiated with the pulsed laser light, is Gaussian and the width thereof is less than or equal to 100 μm. When the pulse width of the laser light is made long, the width of the laser light profile can be made long. When the laser light profile is set as described above, the entire melted region can be changed into the re-single-crystallization region by crystal growth within the time of the supercooled state. Further, the shape of the region of the single crystal semiconductor layer, which is irradiated with pulsed laser light, can be rectangular (a long rectangular shape by linear laser light may also be used). Alternatively, irradiation with a plurality of rectangular shapes of laser light may be performed with the use of a mask.

When the region irradiated with the laser light is large, re-single-crystallization cannot be completed in the entire region of the irradiation region within time of a supercooled state in which the crystal growth of the single crystal semiconductor layer occurs, and a microcrystalline region is generated in the center of the irradiation region. Accordingly, the region irradiated with the laser light is set to have such an area that the end portions of the crystal growth are in contact with (meet) each other in the irradiation region (the melted region) within time of a supercooled state of the single crystal semiconductor layer, so that re-single-crystallization can be completed in the entire region of the laser light irradiation region. If the microcrystalline region is small, re-single-crystallization of the microcrystalline region can be caused by irradiation with laser light by scanning the microcrystalline region with the laser light so that the irradiation region overlaps with the microcrystalline region.

The regions which are near the peripheral end portions of the single crystal semiconductor layer and which are not irradiated with the laser light (the regions in which re-single-crystallization is not caused), serving as the crystal nuclei for forming the semiconductor region in which re-single-crystallization is caused by irradiation with the laser light, may be removed.

Since irradiation with the pulsed laser light is performed, temperature rise of the supporting substrate can be suppressed, so that a substrate having low heat resistance such as a glass substrate can be used as the supporting substrate. Thus, damage to the single crystal semiconductor layer due to an ion addition step can be sufficiently recovered.

Further, the single crystal semiconductor layer is melted to cause re-single-crystallization, whereby the surface thereof can be planarized. Accordingly, by re-single-crystallization of the single crystal semiconductor layer by irradiation with the pulsed laser light, a semiconductor substrate having the single crystal semiconductor layer with reduced crystal defects and high planarity can be manufactured.

Note that an oxide film (a natural oxide film or a chemical oxide film) formed on the surface of the single crystal semiconductor layer may be removed using a dilute hydrofluoric acid before irradiation with the laser light.

Any laser light may be used as long as it provides high energy to the single crystal semiconductor layer, and a pulsed laser light can be preferably used.

The wavelength of the laser light is set to a wavelength that is absorbed by the single crystal semiconductor layer. The wavelength can be determined in consideration of the skin depth of the laser light, and the like. For example, the wavelength of the laser light can be 190 nm to 600 nm. Further, the energy of the laser light can be determined in consideration of the wavelength of the laser light, the skin depth of the laser light, the thickness of the single crystal semiconductor layer to be irradiated, or the like.

A laser emitting the laser light can be a pulsed laser. For example, there are a gas laser such as an excimer laser like a KrF laser, an Ar laser, a Kr laser, or the like; and a solid-state laser such as a YAG laser, a YVO₄ laser, a YLF laser, a YAlO₃ laser, a GdVO₄ laser, a KGW laser, a KYW laser, an alexandrite laser, a Ti:sapphire laser, a Y₂O₃ laser, or the like. Note that in a solid-state laser, the second to fifth harmonics of a fundamental wave can be preferably used. In addition, a semiconductor laser such as GaN, GaAs, GaAlAs, InGaAsP, or the like can be used.

A shutter, a reflector such as a mirror or a half mirror, an optical system including a cylindrical lens, a convex lens, or the like may be provided in order to adjust the shape or path of laser light.

Note that laser light may be selectively emitted or laser light can be emitted while being moved in the X-axis and Y-axis directions. In this case, a polygon mirror or a galvanometer mirror is preferably used for an optical system.

For example, in the case where an XeCl excimer laser having a wavelength of 308 nm and a pulse width of 25 nsec is used as laser light and the single crystal semiconductor layer to be irradiated is a single crystal silicon layer, the energy density to be given to the silicon layer may be set as appropriate in a range of 600 J/cm² to 2000 mJ/cm² when the thickness of the silicon layer is 90 nm to 120 nm.

The irradiation with the laser light can be performed in an atmosphere containing oxygen such as an air atmosphere or an inert atmosphere such as a nitrogen atmosphere. In order to perform the irradiation with the laser light in an inert atmosphere, irradiation with the laser light may be performed in an airtight chamber while the atmosphere in the chamber is controlled. In the case where the chamber is not used, by blowing an inert gas such as a nitrogen gas to the surface which is irradiated with the laser light, an nitrogen atmosphere can be formed.

When the laser light irradiation treatment is performed in a nitrogen atmosphere which contains oxygen of less than or equal to 10 ppm, preferably less than or equal to 6 ppm, the surface of the single crystal semiconductor layer can be relatively flat.

Further, polishing treatment may be performed on the surface of the single crystal semiconductor layer whose crystal defects are reduced by supply of high energy by laser light irradiation or the like. Polishing treatment can enhance the planarity of the surface of the single crystal semiconductor layer.

For the polishing treatment, a chemical mechanical polishing (CMP) method or a liquid jet polishing method can be used. Note that the surface of the single crystal semiconductor layer is cleaned and purified before the polishing treatment. The cleaning may be megasonic cleaning, two-fluid jet cleaning, or the like and dust or the like of the surface of the single crystal semiconductor layer is removed by cleaning. In addition, it is preferable to remove a natural oxide film or the like on the surface of the single crystal semiconductor layer by using dilute hydrofluoric acid to expose the single crystal semiconductor layer.

In addition, polishing treatment (or etching treatment) may be performed on the surface of the single crystal semiconductor layer before irradiation with the laser light. The etching treatment can be performed by a wet etching method, a dry etching method, or a combination of a wet etching method and a dry etching method.

When polishing treatment is performed on the single crystal semiconductor layer before a laser light irradiation step, the following effects can be obtained. Polishing treatment can planarize the surface of the single crystal semiconductor layer and control the thickness of the single crystal semiconductor layer. The surface of the single crystal semiconductor layer is planarized, whereby heat capacity of the single crystal semiconductor layer can be uniform in a laser light irradiation step, and uniform crystals can be formed by performing a uniform heating and cooling step or a uniform melting and solidification step. In addition, in polishing treatment (or etching treatment instead of polishing treatment), the thickness of the single crystal semiconductor layer is set at an appropriate value so that the single crystal semiconductor layer can absorb laser light energy; thus, energy can be efficiently provided to the single crystal semiconductor layer. Further, since the surface of the single crystal semiconductor layer has many crystal defects, the surface with many crystal defects is removed so that a crystal defect in the single crystal semiconductor layer after laser light irradiation can be reduced.

Further, the regions irradiated with the laser light (the regions of the single crystal semiconductor layer in which re-single-crystallization is caused) may not be overlapped with each other as illustrated in FIGS. 1A to 1H, or irradiation with the laser light may be performed by scanning with the laser light so that the laser light irradiation regions overlap with each other. FIGS. 2A to 2F illustrate an example in which a semiconductor substrate is manufactured in such a manner that the laser light irradiation regions (the regions of the single crystal semiconductor layer in which re-single-crystallization is caused) are overlapped with each other.

FIGS. 2A and 2D correspond to FIGS. 1B and 1F. The single crystal semiconductor region 126 in which re-single-crystallization is caused is formed in the single crystal semiconductor layer 102 by irradiation with the laser light 124.

In FIGS. 2B and 2E and FIGS. 2C and 2F, irradiation with the laser light 127 is performed so as to overlap with part of the single crystal semiconductor region 126 which has been irradiated with the laser light 124, and the part of the single crystal semiconductor region 126 is melted again to cause re-single-crystallization.

Since ridges (projections) are easily generated at end portions of the single crystal semiconductor region 126 which has been irradiated with the laser light 124, re-single-crystallization of the single crystal semiconductor region 126 which is melted again by irradiation with the laser light 127 is effective in reducing the ridges and further enhancing planarity thereof. As illustrated in FIGS. 2C and 2F, irradiation with the laser light 127 may be performed so that the laser light 127 overlaps a region of the single crystal semiconductor region 126 where the end portions of the crystal growth are in contact with each other (a region indicated by a dotted line in FIGS. 2A to 2F, and the single crystal semiconductor region 126 may be melted again to cause re-single-crystallization.

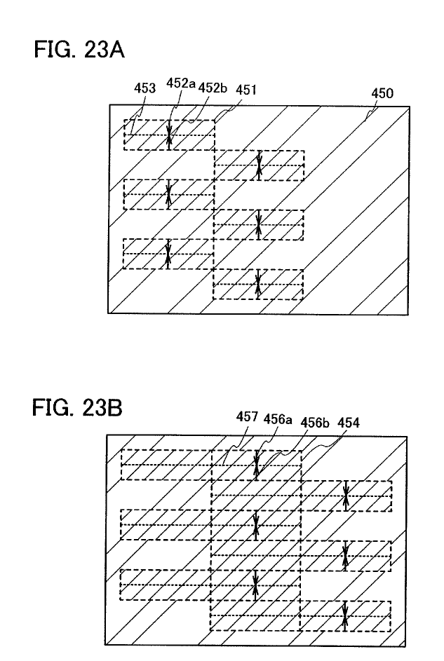

Alternatively, the laser light is processed with a mask and a plurality of regions may be selectively melted at the same time to cause re-single-crystallization. FIGS. 23A and 23B illustrate examples of patterns for irradiating the single crystal semiconductor layer with the laser light. In FIGS. 23A and 23B, first, as illustrated in FIG. 23A, a single crystal semiconductor layer 450 transferred to the supporting substrate is irradiated with laser light using a plurality of rectangular irradiation patterns 451. The rectangular regions of the single crystal semiconductor layer 450, which are irradiated with the laser light, are melted and crystal growth occurs until the regions in which re-single-crystallization is caused are in contact with each other at a center portion 453 as indicated by an arrow 452a and an arrow 452b; thus, re-single-crystallization is caused.

Next, as illustrated in FIG. 23B, the mask for laser beam irradiation is moved and irradiation with the laser light is performed using a plurality of rectangular irradiation patterns 454. Similarly, the rectangular regions of the single crystal semiconductor layer 450, which are irradiated with the laser light, are melted and crystal growth occurs until the regions in which re-crystal-crystallization is caused are in contact with each other at a center portion 457 as indicated by an arrow 456a and an arrow 456b; thus, re-single-crystallization is caused in the regions. In this manner, the plurality of regions are selectively melted to cause re-single-crystallization at the same time, whereby processing speed can be improved; therefore, productivity is improved.

As described above, a semiconductor substrate having the single crystal semiconductor layer which is transferred from the single crystal semiconductor substrate to the supporting substrate and the entire region of which is melted by laser light irradiation to cause re-crystal-crystallization can be manufactured. The single crystal semiconductor layer 130 of the semiconductor substrate has reduced crystal defects, high crystallinity and high planarity.

A semiconductor element such as a transistor or the like is formed using the single crystal semiconductor layer 130 provided for the semiconductor substrate, whereby a gate insulating layer can be made to be thin and the localized interface state density with the gate insulating layer can be reduced. In addition, the thickness of the single crystal semiconductor layer 130 is made to be small, whereby a transistor of complete depletion type can be formed using a single crystal semiconductor layer over the supporting substrate.

In this embodiment mode, when a single crystal silicon substrate is used for the single crystal semiconductor substrate 108, a single crystal silicon layer can be obtained as the single crystal semiconductor layer 130. In addition, in a method for manufacturing a semiconductor substrate in this embodiment mode, a process temperature can be set at less than or equal to 700° C.; therefore, a glass substrate can be used as the supporting substrate 101. That is, similarly to the conventional thin film transistor, a transistor can be formed over a glass substrate and a single crystal silicon layer can be used for the single crystal semiconductor layer. These make it possible to form a transistor with high performance and high reliability in which high speed operation is possible and which can be driven with a low subthreshold value, high field effect mobility, and low consumption voltage can be formed over a supporting substrate such as a glass substrate or the like.

Note that, in the present invention, the term “semiconductor device” refers to a device which can be operated by utilizing semiconductor characteristics. A device having a circuit including a semiconductor element (a transistor, a memory element, a diode, or the like) and a semiconductor device such as a chip having a processor circuit can be manufactured by using the present invention.

The present invention can also be applied to a semiconductor device (also referred to as a display device) having a display function. The semiconductor device using the present invention includes a semiconductor device (a light emitting display device) in which a transistor and a light-emitting element having electrodes sandwiching a layer containing an organic substance, an inorganic substance, or a mixture of an organic substance and an inorganic substance which exhibits light emission referred to as electroluminescence (hereinafter also referred to as EL) are connected to each other, a semiconductor device (a liquid crystal display device) in which a liquid crystal element (a liquid crystal display element) including a liquid crystal material is used as a display element, and the like. In this specification, a display device means a device having a display element. Note that the display device may be a main body of a display panel for which a plurality of pixels including a display element and a peripheral driver circuit for driving the pixels are provided over a substrate. Moreover, the display device may indicate a device which is provided with a flexible printed circuit (FPC) or a printed wiring board (PWB) (an IC, a resistor, a capacitor, an inductor, a transistor, or the like). The display device may also include an optical sheet such as a polarizing plate or a retardation plate. Further, it may include a backlight (which may include a light guiding plate, a prism sheet, a diffusion sheet, a reflective sheet, and a light source (e.g., an LED or a cold-cathode tube)).

Note that as a display element or a semiconductor device, various modes and various elements can be used. For example, a display medium whose contrast changes by an electromagnetic action, such as an EL element (e.g., an organic EL element, an inorganic EL element, or an EL element including both organic and inorganic substances), an electron-emissive element, a liquid crystal element, electronic ink, a grating light valve (GLV), a plasma display panel (PDP), a digital micromirror device (DMD), a piezoelectric ceramic display, a carbon nanotube, or the like can be employed. Note that semiconductor devices that use an EL element include an EL display; semiconductor devices that use an electron-emissive element include a field-emission display (FED), an SED-type flat panel display (SED: surface-conduction electron-emitter display), and the like; semiconductor devices that use a liquid crystal element include a liquid crystal display, a transmissive liquid crystal display, a semi-transmissive liquid crystal display, a reflective liquid crystal display, and the like; and semiconductor devices that use electronic ink include electronic paper.

In this manner, a semiconductor substrate and a semiconductor device having high performance and high reliability can be manufactured with high yield.

### Embodiment Mode 2

This embodiment mode describes an example in which steps of separating a semiconductor layer from the single crystal semiconductor substrate and bonding the single crystal semiconductor layer to a supporting substrate are different from the steps in Embodiment Mode 1. Repetitive description of the same portion as or a portion having a similar function to the portions in Embodiment Mode 1 is omitted.

In this embodiment mode, when a single crystal semiconductor layer is transferred from a single crystal semiconductor substrate, the single crystal semiconductor substrate is selectively etched (this step is also referred to as groove processing) and a plurality of single crystal semiconductor layers of which shapes are processed are transferred to a supporting substrate. Thus, a plurality of island-shaped single crystal semiconductor layers can be formed over the supporting substrate. The single crystal semiconductor layers of which shapes are processed in advance are transferred; therefore, the size and shape of the single crystal semiconductor substrate are not limited. Accordingly, the single crystal semiconductor layers can be more efficiently transferred to a large-sized supporting substrate.

The single crystal semiconductor layer which is thus formed over the supporting substrate is etched so that the shape is processed, modified, and controlled precisely. Accordingly, the single crystal semiconductor layer can be processed into the shape of a semiconductor element, and error in a formation position and a defect in the shape of the single crystal semiconductor layer due to pattern misalignment caused by light or the like in light exposure for forming a resist mask going around the resist mask, positional misalignment caused by a bonding step in transferring the single crystal semiconductor layer, or the like can be modified.

Accordingly, a plurality of single crystal semiconductor layers having a desired shape can be formed over the supporting substrate with a high yield. Therefore, a semiconductor device which includes high performance semiconductor elements and an integrated circuit which are more precise can be manufactured over a large-sized substrate with high throughput and high productivity.

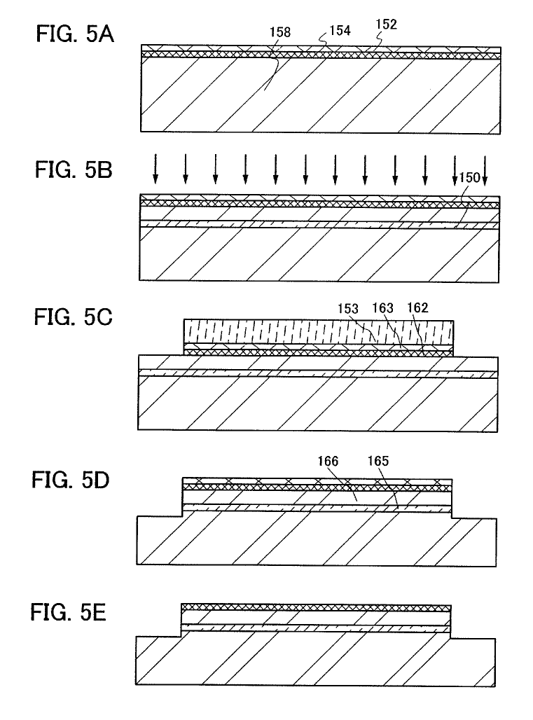

FIG. 5A illustrates a state in which a protection layer 154 and a silicon nitride film 152 are formed over a single crystal semiconductor substrate 158. The silicon nitride film 152 is used as a hard mask in performing groove processing on the single crystal semiconductor substrate 158. The silicon nitride film 152 may be formed by depositing silane and ammonia by a vapor deposition method.

Then, ion addition is performed to form an embrittlement layer 150 in the single crystal semiconductor substrate 158 (see FIG. 5B). Ion addition is performed in consideration of the thickness of a single crystal semiconductor layer which is to be transferred to the supporting substrate. In consideration of the thickness, an accelerating voltage for adding ions is set so that the ions are added into a deep part of the single crystal semiconductor substrate 158. With this treatment, the embrittlement layer 150 is formed in a region at a predetermined depth from the surface of the single crystal semiconductor substrate 158.

The groove processing is performed in consideration of the shape of single crystal semiconductor layers of semiconductor elements. That is, in order to transfer a single crystal semiconductor layer of a semiconductor element to the supporting substrate, the groove processing is performed on the single crystal semiconductor substrate 158 such that a portion which is transferred as a single crystal semiconductor layer remains as a projection portion.

A mask 153 is formed of photoresist. The silicon nitride film 152 and the protection layer 154 are etched using the mask 153 to form a protection layer 162 and a silicon nitride layer 163 (see FIG. 5C).

Then, the single crystal semiconductor substrate 158 is etched using the silicon nitride layer 163 as a hard mask to form the single crystal semiconductor substrate 158 having an embrittlement layer 165 and a single crystal semiconductor layer 166 (see FIG. 5D). In the present invention, a semiconductor region which is part of a single crystal semiconductor substrate which is processed into a convex shape using an embrittlement layer and by groove processing is referred to as the single crystal semiconductor layer 166 as in FIG. 5D.

The depth of etching the single crystal semiconductor substrate 158 is set as appropriate in consideration of the thickness of the single crystal semiconductor layer which is transferred to the supporting substrate. The thickness of the single crystal semiconductor layer can be set in accordance with a depth where hydrogen ions reach by addition. The groove formed in the single crystal semiconductor substrate 158 is preferably deeper than the embrittlement layer. In this groove processing, if the groove is processed to be deeper than the embrittlement layer, the embrittlement layer can be left only in a region of the single crystal semiconductor layer which is to be separated.

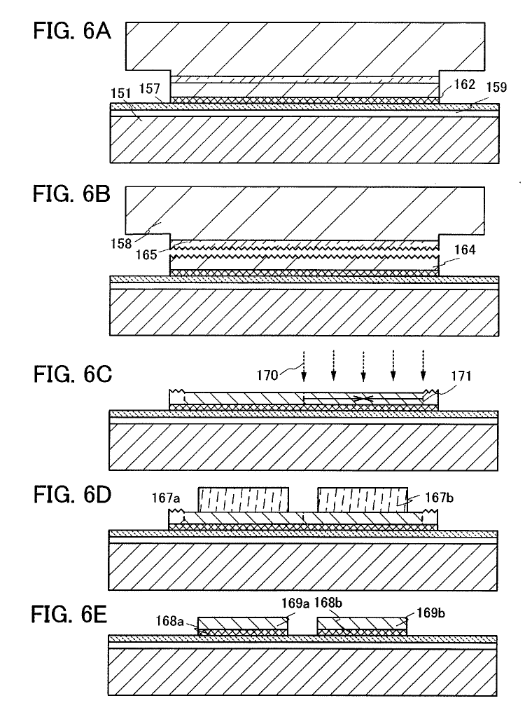

The silicon nitride layer 163 on the surface is removed (see FIG. 5E). Then, the surface of the protection layer 162 of the single crystal semiconductor substrate 158 and the supporting substrate 151 are bonded to each other (see FIG. 6A).

The surface of the supporting substrate 151 is provided with a blocking layer 159 and an insulating layer 157. The blocking layer 159 is provided so as to prevent impurities such as sodium ions from diffusing from the supporting substrate 151 and contaminating the single crystal semiconductor layer. Note that in a case where there is no possibility of diffusion of impurities from the supporting substrate 151 which causes adverse effects on the single crystal semiconductor layer, the blocking layer 159 can be omitted. The insulating layer 157 is provided to form a bond with the protection layer 162.

The bond can be formed by disposing the protection layer 162 of the single crystal semiconductor substrate 158 and the insulating layer 157 of the supporting substrate, the surfaces of which are cleaned, in close contact with each other. The bond can be formed at room temperature. This bond is performed at the atomic level, and a strong bond is formed at room temperature by van der Waals forces. Since groove processing has been performed on the single crystal semiconductor substrate 158, a convex portion forming the single crystal semiconductor layer is in contact with the supporting substrate 151.

After the bond between the single crystal semiconductor substrate 158 and the supporting substrate 151 is formed, heat treatment is performed to separate a single crystal semiconductor layer 164 from the single crystal semiconductor substrate 158 and to fix the semiconductor layer 164 to the supporting substrate 151, as illustrated in FIG. 6B. The volume of microvoids formed in the embrittlement layer 150 is changed and a crack is generated along the embrittlement layer 150, whereby the single crystal semiconductor layer is separated. After that, in order to further strengthen the bond, heat treatment is preferably performed. As described above, the single crystal semiconductor layer is formed over the insulating surface. FIG. 6B illustrates a state in which the single crystal semiconductor layer 164 is bonded to the supporting substrate 151.

In this embodiment mode, the shapes of the single crystal semiconductor layers are processed in advance and the single crystal semiconductor layers are transferred; thus, there is no restriction on the size or shape of a single crystal semiconductor substrate. Accordingly, single crystal semiconductor layers having various shapes can be formed over the semiconductor substrate. For example, the shapes of the single crystal semiconductor layers can be freely formed in accordance with a mask of a light-exposure apparatus which is used for etching, a stepper of the light-exposure apparatus for forming the mask pattern, and a panel or chip size of a semiconductor device which is cut from a large-sized substrate.

Laser light irradiation is performed on the single crystal semiconductor layer 164 transferred to the supporting substrate 151, so that re-single-crystallization of the single crystal semiconductor layer is caused. The entire region in the region of the single crystal semiconductor layer 164, which is irradiated with a laser light 170, is melted at least in a depth direction, and re-single-crystallization is caused toward the center of the irradiation region (a melted region) (in the directions indicated by the arrows in FIG. 6C) using peripheral non-irradiation regions (non-melted regions) as crystal nuclei (seed crystals). By re-single-crystallization of the single crystal semiconductor layer 164, a single crystal semiconductor layer 171 having high crystallinity and high planarity is formed (see FIG. 6C).

A mask 167a and a mask 167b are selectively formed over the single crystal semiconductor layer 171 so as to manufacture corresponding semiconductor elements.

The single crystal semiconductor layer 171 is etched using the mask 167a and the mask 167b to form a single crystal semiconductor layer 169a and a single crystal semiconductor layer 169b, respectively. In this embodiment mode, the protection layer 162 which is below the single crystal semiconductor layer is also etched together with the single crystal semiconductor layer to form a protection layer 168a and a protection layer 168b (see FIGS. 6D and 6E). In this manner, the single crystal semiconductor layer is transferred to the supporting substrate, and then the shape thereof is processed, whereby the single crystal semiconductor layers of a semiconductor element can be manufactured using only the single crystal semiconductor layers in which re-single-crystallization is caused and which has high crystallinity and high planarity, and misalignment of formation regions of the single crystal semiconductor layer, a defective shape or the like which is generated in the manufacturing step can be corrected.

As described above, a semiconductor substrate having the single crystal semiconductor layer which is transferred from the single crystal semiconductor substrate to the supporting substrate and the entire region of which is melted by laser light irradiation to cause re-single-crystallization can be manufactured. The single crystal semiconductor layer 169a and the single crystal semiconductor layer 169b of the semiconductor substrate have reduced crystal defects, high crystallinity and high planarity.

Semiconductor elements such as transistors are manufactured using the single crystal semiconductor layer 169a and the single crystal semiconductor layer 169b formed over the semiconductor substrate, whereby a semiconductor substrate and a semiconductor device with high performance and high reliability can be manufactured with high yield.

This embodiment mode can be combined with Embodiment Mode 1 as appropriate.

### Embodiment Mode 3

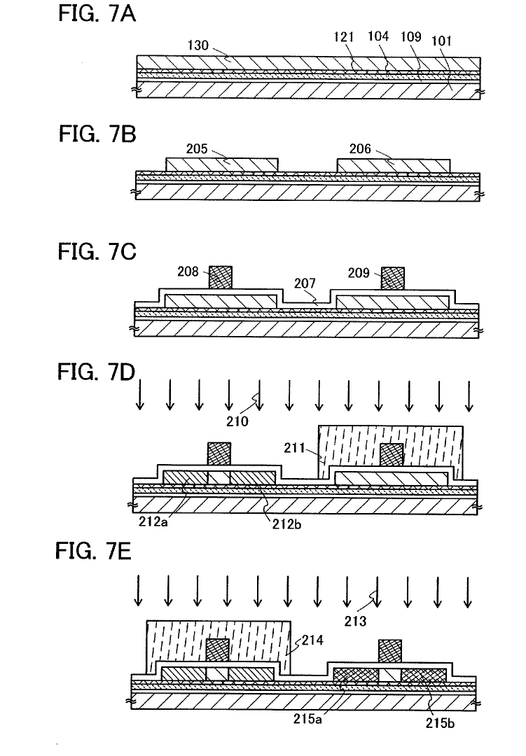

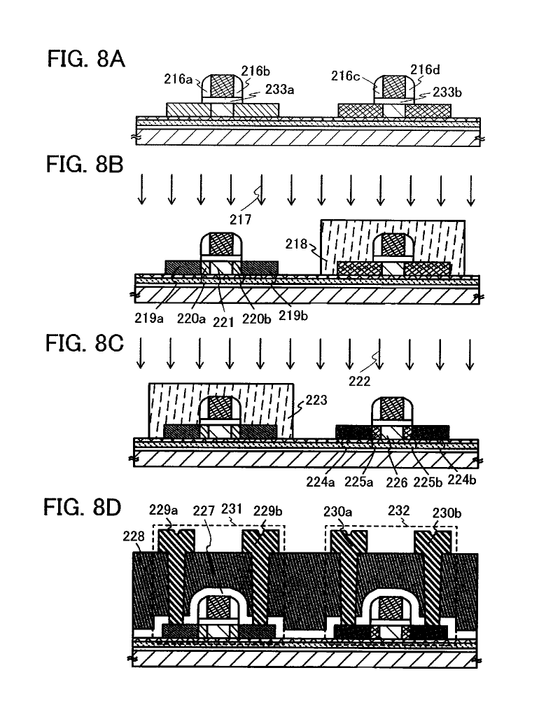

In this embodiment mode, a method for manufacturing a CMOS (complementary metal oxide semiconductor) device will be described as an example of a method for manufacturing a semiconductor device including a semiconductor element having high performance and high reliability with high yield with reference to FIGS. 7A to 7E and FIGS. 8A to 8D. Note that repetitive descriptions for the same components as or components having similar functions to the components in Embodiment Mode 1 are omitted.

In FIG. 7A, the blocking layer 109, the insulating layer 104, the protection layer 121, and the single crystal semiconductor layer 130 are formed over the supporting substrate 101. The single crystal semiconductor layer 130 corresponds to FIGS. 1(D1) and 1(D2); and the blocking layer 109, the insulating layer 104, and the protection layer 121 correspond to FIG. 4C. Note that here, although an example is shown in which a semiconductor substrate having a structure illustrated in FIG. 7A is used, a semiconductor substrate having another structure described in this specification can also be used. Note that the blocking layer 109, the insulating layer 104, and the protection layer 121 can be referred to as a buffer layer which is provided between the supporting substrate 101 and the single crystal semiconductor layer 130. The structure of the buffer layer is not limited to the above-described structure.

The single crystal semiconductor layer 130 is a single crystal semiconductor layer which is transferred from a single crystal semiconductor substrate 108 to the supporting substrate 101, the entire region of which is melted by laser light irradiation to cause re-single-crystallization; therefore, the single crystal semiconductor layer 130 has reduced crystal defects, high crystallinity and high planarity.

In the single crystal semiconductor layer 130, a p-type impurity such as boron, aluminum, or gallium or an n-type impurity such as phosphorus or arsenic may be added depending on a conductivity type of the separated single crystal semiconductor substrate (an impurity element imparting one conductivity type which is contained) in accordance with a formation region of an n-channel field effect transistor or a p-channel field effect transistor in order to control the threshold voltage. The dose of impurity ions may range from about 1×10¹² ions/cm² to 1×10¹⁴ ions/cm².

The single crystal semiconductor layer 130 is etched into island shapes to form separated single crystal semiconductor layers 205 and 206 in accordance with the position of the semiconductor elements (see FIG. 7B).

An oxide film over the single crystal semiconductor layer is removed, and a gate insulating layer 207 that covers the single crystal semiconductor layers 205 and 206 is formed. Since the single crystal semiconductor layers 205 and 206 in this embodiment mode have high planarity, even if a gate insulating layer formed over the single crystal semiconductor layers 205 and 206 is a thin gate insulating layer, the gate insulating layer can cover the single crystal semiconductor layers 205 and 206 with good coverage. Therefore, deterioration in characteristics due to poor coverage of the gate insulating layer can be prevented, and a semiconductor device having high reliability can be manufactured with high yield. The thinned gate insulating layer 207 is effective in operating a thin film transistor with low voltage at high speed.

The gate insulating layer 207 may be formed using silicon oxide, or may be formed with a stacked structure of silicon oxide and silicon nitride. The gate insulating layer 207 may be formed by depositing an insulating film by a plasma CVD method or a low-pressure CVD method. Alternatively, the gate insulating layer 207 may preferably be formed by solid-phase oxidation or solid-phase nitridation with plasma treatment because a gate insulating layer formed by oxidizing or nitriding a single crystal semiconductor layer by plasma treatment is dense, has high withstand voltage, and is highly reliable. For example, dinitrogen monoxide (N₂O) is diluted with Ar by 1 to 3 times (flow rate) and a microwave (2.45 GHz) power of 3 kW to 5 kW is applied with a pressure of 10 Pa to 30 Pa to oxidize or nitride the surfaces of the semiconductor layers 205 and 206. By this process, an insulating film with a thickness of 1 nm to 10 nm (preferably 2 nm to 6 nm) is formed. Moreover, dinitrogen monoxide (N₂O) and silane (SiH₄) are introduced and a microwave (2.45 GHz) power of 3 kW to 5 kW is applied with a pressure of 10 Pa to 30 Pa to form a silicon oxynitride film by a vapor deposition method, thereby forming a gate insulating film. With a combination of a solid-phase reaction and a reaction by a vapor deposition method, the gate insulating layer with low interface state density and excellent withstand voltage can be formed.

As the gate insulating layer 207, a high dielectric constant material such as zirconium dioxide, hafnium oxide, titanium dioxide, tantalum pentoxide, or the like may be used. If a high dielectric constant material is used for the gate insulating layer 207, gate leakage current can be reduced.

A gate electrode layer 208 and a gate electrode layer 209 are formed over the gate insulating layer 207 (see FIG. 7C). The gate electrode layers 208 and 209 can be formed by a sputtering method, an evaporation method, a CVD method, or the like. The gate electrode layers 208 and 209 may be formed of an element selected from tantalum (Ta), tungsten (W), titanium (Ti), molybdenum (Mo), aluminum (Al), copper (Cu), chromium (Cr), or neodymium (Nd); or an alloy material or a compound material that contains any of these elements as its main component. In addition, as the gate electrode layers 208 and 209, a semiconductor film typified by a polycrystalline silicon film doped with an impurity element such as phosphorus or the like, or an AgPdCu alloy may be used.

A mask 211 that covers the single crystal semiconductor layer 206 is formed. Using the mask 211 and the gate electrode layer 208 as masks, an impurity element 210 that imparts n-type conductivity is added to form first n-type impurity regions 212a and 212b (see FIG. 7D). In this embodiment mode, phosphine (PH₃) is used as a doping gas that contains an impurity element. Here, an impurity element that imparts n-type conductivity is added so as to be contained in the first n-type impurity regions 212a and 212b at a concentration of about 1×10¹⁷ atoms/cm³ to 5×10¹⁸ atoms/cm³. In this embodiment mode, phosphorus (P) is used as an impurity element that imparts n-type conductivity.

Next, a mask 214 that covers the single crystal semiconductor layer 205 is formed. The mask 214 and the gate electrode layer 209 are used as masks, and an impurity element 213 that imparts p-type conductivity is added to form first p-type impurity regions 215a and 215b (see FIG. 7E). In this embodiment mode, diborane (B₂H₆) or the like is used as a doping gas that contains an impurity element because boron (B) is used as an impurity element.

The mask 214 is removed, sidewall insulating layers 216a to 216d with a sidewall structure are formed on side surfaces of the gate electrode layers 208 and 209, and gate insulating layers 233a and 233b are formed (see FIG. 8A). The sidewall insulating layers 216a to 216d with a sidewall structure may be formed on the side surfaces of the gate electrode layers 208 and 209 in a self-aligning manner, in the following manner: an insulating layer covering the gate electrode layers 208 and 209 is formed and is processed by anisotropic etching using an RIE (reactive ion etching) method. Here, there is no particular limitation on materials of the insulating layers and the insulating layers are preferably layers of silicon oxide with good step coverage, which are formed by reacting TEOS (tetraethyl orthosilicate), silane, or the like with oxygen, dinitrogen monoxide, or the like. The insulating layers can be formed by a thermal CVD method, a plasma CVD method, a normal-pressure CVD method, a bias ECRCVD method, a sputtering method, or the like. The gate insulating layers 233a and 233b can be formed by etching the gate insulating layer 207 with the use of the gate electrode layers 208 and 209 and the sidewall insulating layers 216a to 216d as masks.

In this embodiment mode, in etching the insulating layer, portions of the insulating layer over the gate electrode layers are removed to expose the gate electrode layers. However, the sidewall insulating layers 216a to 216d may be formed to have a shape in which portions of the insulating layer over the gate electrode layers remain. In addition, a protection film may be formed over the gate electrode layers in a later step. By protecting the gate electrode layers in this manner, film reduction of the gate electrode layers can be prevented in an etching processing. In the case of forming silicide in a source region and a drain region, since a metal film formed for formation of the silicide is not in contact with the gate electrode layers, even when a material of the metal film can easily react with a material of the gate electrode layer, defects such as chemical reaction, diffusion, and the like can be prevented. Various etching methods such as a dry etching method or a wet etching method may be used for etching. In this embodiment mode, a dry etching method is used. As an etching gas, a chlorine-based gas typified by Cl₂, BCl₃, SiCl₄, CCl₄, or the like, a fluorine-based gas typified by CF₄, SF₆, NF₃, or the like, or O₂ can be used as appropriate.

Next, a mask 218 which covers the single crystal semiconductor layer 206 is formed. The mask 218, the gate electrode layer 208, and the sidewall insulating layers 216a and 216b are used as masks, and an impurity element 217 that imparts n-type conductivity is added to form second n-type impurity regions 219a and 219b and third n-type impurity regions 220a and 220b. In this embodiment mode, PH₃ is used as a doping gas that contains an impurity element. Here, the addition is performed so that the second n-type impurity regions 219a and 219b contain an impurity element that imparts n-type conductivity at a concentration of about 5×10¹⁹ atoms/cm³ to 5×10²⁰ atoms/cm³. In addition, a channel formation region 221 is formed in the single crystal semiconductor layer 205 (see FIG. 8B).

The second n-type impurity regions 219a and 219b are high-concentration n-type impurity regions and function as a source and a drain. On the other hand, the third n-type impurity regions 220a and 220b are low-concentration impurity regions, or LDD (lightly doped drain) regions. Since the third n-type impurity regions 220a and 220b are formed in Loff regions, which are not covered with the gate electrode layer 208, off current can be reduced. Accordingly, a semiconductor device with higher reliability and lower power consumption can be manufactured.

The mask 218 is removed, and a mask 223 that covers the single crystal semiconductor layer 205 is formed. The mask 223, the gate electrode layer 209, and the sidewall insulating layers 216c and 216d are used as masks, and an impurity element 222 that imparts p-type conductivity is added to form second p-type impurity regions 224a and 224b, and third p-type impurity regions 225a and 225b.

an impurity element that imparts p-type conductivity is added so as to be contained in the second p-type impurity regions 224a and 224b at a concentration of about 1×10²⁰ atoms/cm³ to 5×10²¹ atoms/cm³. In this embodiment mode, the third p-type impurity regions 225a and 225b are formed in a self-aligning manner using the sidewall insulating layers 216c and 216d so as to have a lower concentration than the second p-type impurity regions 224a and 224b. In addition, a channel formation region 226 is formed in the single crystal semiconductor layer 206 (see FIG. 8C).

The second p-type impurity regions 224a and 224b are high-concentration p-type impurity regions and function as a source and a drain. On the other hand, the third p-type impurity regions 225a and 225b are low-concentration impurity regions, or LDD (lightly doped drain) regions. Since the third p-type impurity regions 225a and 225b are formed in Loff regions, which are not covered with the gate electrode layer 209, off current can be reduced. Accordingly, a semiconductor device with higher reliability and lower power consumption can be manufactured.

The mask 223 is removed, and heat treatment, strong light irradiation, or laser light irradiation may be performed in order to activate the impurity element. At the same time as the activation, plasma damage to the gate insulating layer and plasma damage to an interface between the gate insulating layer and the single crystal semiconductor layer can be repaired.

Next, an interlayer insulating layer which covers the gate electrode layers and the gate insulating layers is formed. In this embodiment mode, a stacked structure of an insulating film 227 that contains hydrogen to serve as a protection film and an insulating layer 228 is employed. The insulating film 227 and the insulating layer 228 may be formed by using a silicon nitride film, a silicon nitride oxide film, a silicon oxynitride film, or a silicon oxide film by a sputtering method or a plasma CVD method. Alternatively, a single layer structure or a stacked structure of three or more layers using a different insulating film containing silicon may also be employed.

Further, a step in which heat treatment is performed at 300° C. to 550° C. for 1 to 12 hours in a nitrogen atmosphere and the single crystal semiconductor layer is hydrogenated is performed. Preferably, the temperature is 400° C. to 500° C. This step is a step for terminating a dangling bond of the single crystal semiconductor layer by hydrogen contained in the insulating film 227, which is an interlayer insulating layer. In this embodiment mode, heat treatment is performed at 410° C. for 1 hour.

The insulating film 227 and the insulating layer 228 can also be formed of a material selected from aluminum nitride (AlN), aluminum oxynitride (AlON), aluminum nitride oxide having a higher content of nitrogen than that of oxygen (AlNO), aluminum oxide, diamond-like carbon (DLC), nitrogen-containing carbon (CN), or other substances containing an inorganic insulating material. A siloxane resin may also be used. The siloxane resin is a resin including a Si—O—Si bond. Siloxane is composed of a skeleton formed by the bond of silicon (Si) and oxygen (O), in which an organic group containing at least hydrogen (such as an alkyl group and an aryl group) is used as a substituent. A fluoro group may be included in the organic group. Further, an organic insulating material such as polyimide, acrylic, polyamide, polyimide amide, resist, benzocyclobutene, or polysilazane may also be used. A coating film with a favorable planarity formed by a coating method may also be used.

The insulating film 227 and the insulating layer 228 can be formed by using dipping, spray coating, a doctor knife, a roll coater, a curtain coater, a knife coater, a CVD method, an evaporation method, or the like. The insulating film 227 and the insulating layer 228 may also be formed by a droplet discharge method. A droplet discharge method requires less material solution. In addition, a method capable of transferring or drawing a pattern similarly to a droplet discharge method, for example, a printing method (a method for forming a pattern such as screen printing, offset printing, or the like) can also be used.

Next, contact holes (openings) which reach the single crystal semiconductor layers are formed in the insulating film 227 and the insulating layer 228 using a mask made of a resist. Etching may be performed once or plural times depending on selectivity of a material to be used. The insulating film 227 and the insulating layer 228 are partly removed by the etching to form the openings which reach the second n-type impurity regions 219a and 219b and the second p-type impurity regions 224a and 224b, which are source regions and drain regions. The etching may be performed by wet etching, dry etching, or both wet etching and dry etching. A hydrofluoric-acid-based solution such as a mixed solution of ammonium hydrogen fluoride and ammonium fluoride may be used as an etchant of wet etching. As an etching gas, a chlorine-based gas typified by Cl₂, BCl₃, SiCl₄, CCl₄, or the like, a fluorine-based gas typified by CF₄, SF₆, NF₃, or the like, or O₂ can be used as appropriate. Further, an inert gas may be added to an etching gas to be used. As an inert element to be added, one or a plurality of elements selected from He, Ne, Ar, Kr, or Xe can be used.

A conductive film is formed so as to cover the openings, and the conductive film is etched to form wiring layers 229a, 229b, 230a, and 230b which function as source and drain electrode layers which are electrically connected to parts of source regions and drain regions. The wiring layers can be formed by forming a conductive film by a PVD method, a CVD method, an evaporation method, or the like, and then, etching the conductive film into a desired shape. Further, a conductive layer can be selectively formed in a predetermined position by a droplet discharge method, a printing method, an electroplating method, or the like. Moreover, a reflow method or a damascene method may also be used. As a material for the wiring layers, metal such as Ag, Au, Cu, Ni, Pt, Pd, Ir, Rh, W, Al, Ta, Mo, Cd, Zn, Fe, Ti, Zr, Ba, or the like; Si or Ge; or an alloy or nitride thereof can be used. A stacked structure of these materials may also be employed.

Through the above process, a semiconductor device having a CMOS structure which includes a thin film transistor 231, which is an n-channel thin film transistor, and a thin film transistor 232, which is a p-channel thin film transistor, can be formed (see FIG. 8D). Although not illustrated in the drawings, a CMOS structure is described in this embodiment mode; therefore, the thin film transistor 231 and the thin film transistor 232 are electrically connected to each other.

A structure of the thin film transistor is not limited to this embodiment mode, and a single gate structure in which one channel formation region is formed, a double gate structure in which two channel formation regions are formed, or a triple gate structure in which three channel formation regions are formed may be employed.

As described above, a semiconductor substrate having a single crystal semiconductor layer which is transferred from a single crystal semiconductor substrate to a supporting substrate, the entire region of which is melted by laser light irradiation to cause re-single-crystallization is used; therefore, the single crystal semiconductor layer has reduced crystal defects, high crystallinity and high planarity.

Accordingly, a high-performance and high-reliability semiconductor device can be manufactured with high yield.

This embodiment mode can be combined with any one of Embodiment Modes 1 and 2, as appropriate.

### Embodiment Mode 4

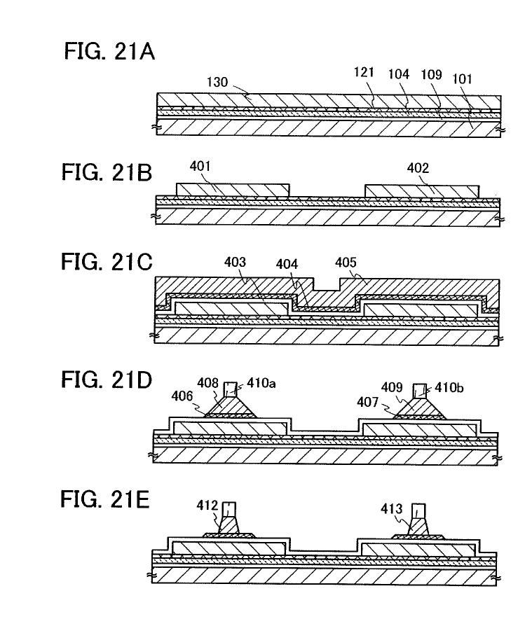

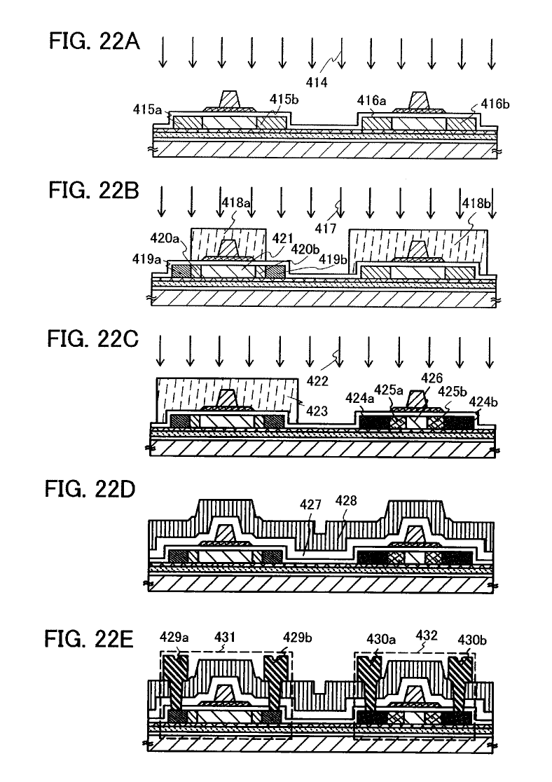

In this embodiment mode, a method for manufacturing a CMOS different from that in Embodiment Mode 3 will be described as an example of a method for manufacturing a semiconductor device including a semiconductor element having high performance and high reliability with high yield with reference to FIGS. 21A to 21E and FIGS. 22A to 22E. Note that repetitive descriptions for the same components as or components having similar functions to the components in Embodiment Modes 1 and 3 are omitted.

As illustrated in FIG. 21A, a semiconductor substrate is prepared. In this embodiment mode, a semiconductor substrate in FIG. 7A is used. A semiconductor substrate is used in which a single crystal semiconductor layer 130 is fixed over a supporting substrate 101 having an insulating surface with a blocking layer 109, an insulating layer 104, and a protection layer 121 interposed therebetween. The single crystal semiconductor layer 130 corresponds to FIGS. 1(D1) and 1(D2), and the blocking layer 109, the insulating layer 104 and the protection layer 121 correspond to FIG. 4C. Note that this embodiment mode will describe an example in which the semiconductor substrate having a structure illustrated in FIG. 7A is used; however, the semiconductor substrates having the other structures described in this specification can be also used. Note that the blocking layer 109, the insulating layer 104, and the protection layer 121 can be collectively referred to as a buffer layer provided between the supporting substrate 101 and the single crystal semiconductor layer 130. The structure of the buffer layer is not limited to the above-described structure.

The single crystal semiconductor layer 130 is a single crystal semiconductor layer which is transferred from a single crystal semiconductor substrate 108 to the supporting substrate 101, the entire region of which is melted by laser light irradiation to cause re-single-crystallization; therefore, the single crystal semiconductor layer 130 has reduced crystal defects, high crystallinity and high planarity.

In the single crystal semiconductor layer 130, a p-type impurity such as boron, or aluminum, gallium or an n-type impurity such as phosphorus or arsenic may be added depending on a conductivity type of the separated single crystal semiconductor substrate (an impurity element imparting one conductivity type which is contained) in accordance with a formation region of an n-channel field effect transistor or a p-channel field effect transistor in order to control the threshold voltage. The dose of impurity ions may range from about 1×10¹² ions/cm² to 1×10¹⁴ ions/cm².

The single crystal semiconductor layer 130 is etched and separated into island shapes in accordance with the position of the semiconductor elements to form single crystal semiconductor layers 401 and 402 (see FIG. 21B).

An oxide film over the single crystal semiconductor layer is removed, and a gate insulating layer 403 which covers the single crystal semiconductor layers 401 and 402 is formed. Since the single crystal semiconductor layers 401 and 402 in this embodiment mode have high planarity, even if a gate insulating layer formed over the single crystal semiconductor layers 401 and 402 is a thin gate insulating layer, the gate insulating layer can cover the single crystal semiconductor layers 401 and 402 with good coverage. Therefore, deterioration in characteristics due to poor coverage of the gate insulating layer can be prevented, and a semiconductor device having high reliability can be manufactured with high yield. The thinned gate insulating layer 403 is effective in operating a thin film transistor with low voltage at high speed.

The gate insulating layer 403 may be formed of silicon oxide or a stacked structure of silicon oxide and silicon nitride. The gate insulating layer 403 may be formed by deposition of an insulating film by a plasma CVD method or a low pressure CVD method or is preferably formed by solid phase oxidation or solid phase nitridation by plasma treatment. This is because a gate insulating layer formed by oxidation or nitridation of a single crystal semiconductor layer by plasma treatment is dense, has high withstand voltage, and is excellent in reliability. For example, dinitrogen monoxide (N₂O) is diluted with Ar at a flow rate of 1 to 3, and 3 kW to 5 kW of microwave (2.45 GHz) power is applied at a pressure of 10 Pa to 30 Pa to oxidize or nitride the surfaces of the single crystal semiconductor layers 401 and 402. By this treatment, an insulating film having a thickness of 1 nm to 10 nm (preferably 2 nm to 6 nm) is formed. Further, dinitrogen monoxide (N₂O) and silane (SiH₄) are introduced and 3 kW to 5 kW of microwave (2.45 GHz) power is applied at a pressure of 10 Pa to 30 Pa to form a silicon oxynitride film as a gate insulating layer by a vapor deposition method. By combination of solid-phase reaction and vapor deposition, a gate insulating layer having low interface state density and excellent withstand voltage can be formed.

As the gate insulating layer 403, a high dielectric constant material such as zirconium dioxide, hafnium oxide, titanium dioxide, or tantalum pentoxide may be used. Using a high dielectric constant material for the gate insulating layer 403 makes it possible to reduce gate leakage current.

Further, a conductive film 404 and a conductive film 405 for forming a gate electrode layer are formed in this order over the gate insulating layer 403 (see FIG. 21C)

The conductive films 404 and 405 for forming gate electrode layers are formed by a CVD method or a sputtering method with a single-layer film or stacked-layer film using an element selected from tantalum, tantalum nitride, tungsten, titanium, molybdenum, aluminum, copper, chromium, niobium, or the like, an alloy or compound material containing the above element as a main component, or a semiconductor material typified by polycrystalline silicon doped with an impurity element such as phosphorus. In a case where the gate electrode has a stacked-layer structure, the stacked layers can be formed using various conductive materials or one conductive material. This embodiment mode illustrates an example in which the conductive films for forming a gate electrode has a stacked layer structure of the conductive films 404 and 405.

If the conductive film for forming the gate electrode has a two-layer structure of the conductive films 404 and 405, stacked-layer films of a tantalum nitride film and a tungsten film, a tungsten nitride film and a tungsten film, or a molybdenum nitride film and a molybdenum film can be formed, for example. Note that a stacked film of a tantalum nitride film and a tungsten film is preferable because selectivity of both films is easily obtained. In the stacked two layers shown above as examples, it is preferable to form the former film on the gate insulating layer 403. In this embodiment mode, the conductive film 404 is formed with a thickness of 20 nm to 100 nm. The conductive film 405 is formed with a thickness of 100 nm to 400 nm. The gate electrode layer can also have a stacked-layer structure of three or more layers; in that case, it is preferable to employ a stacked-layer structure of a molybdenum film, an aluminum film, and a molybdenum film.

Next, resist masks 410a and 410b are formed selectively on the conductive film 405. Then, first etching treatment and second etching treatment are performed using the resist masks 410a and 410b.

First, in the first etching treatment using the resist masks 410a and 410b, the conductive films 404 and 405 are etched selectively to form a first gate electrode layer 406 and a conductive layer 408 over the single crystal semiconductor film layer 401, and a first gate electrode layer 407 and a conductive layer 409 over the single crystal semiconductor layer 402 (see FIG. 21D).

Subsequently, in the second etching treatment using the resist masks 410a and 410b, end portions of the conductive layer 408 and the conductive layer 409 are etched selectively to form a second gate electrode layer 412 and a second gate electrode layer 413 (see FIG. 21E). The second gate electrode layers 412 and 413 are formed so as to have smaller widths (lengths in the direction parallel to the direction in which carriers flow through channel formation regions (a direction in which a source region and a drain region are connected)) than those of the first gate electrode layers 406 and 407. In such a manner, a gate electrode layer having two-layer structure of the first gate electrode layer 407 and the second gate electrode layer 413 is formed.

The etching method applied to the first etching treatment and the second etching treatment may be determined as appropriate; preferably, a dry etching apparatus using a high-density plasma source such as an electron cyclotron resonance (ECR) source, an inductively coupled plasma (ICP) source, or the like is used in order to improve the etching rate. With appropriate control of the etching conditions of the first etching treatment and the second etching treatment, the first gate electrode layers 406 and 407 and the second gate electrode layers 412 and 413 can each have a desired tapered shape at a side surface. After forming the first gate electrode layers 406 and 407 with desired shapes and the second gate electrode layers 412 and 413 with desired shapes, the resist masks 410a and 410b are removed.

Subsequently, an impurity element 414 is added into the single crystal semiconductor layers 401 and 402 using the first gate electrode layer 406 and the second gate electrode layer 412, and the first gate electrode layer 407 and the second gate electrode layer 413 as masks, respectively. In the single crystal semiconductor layer 401, a pair of impurity regions 415a and 415b are formed in a self-aligned manner using the first gate electrode layer 406 and the second gate electrode layer 412 as masks. In the single crystal semiconductor layer 402, a pair of impurity regions 416a and 416b are formed in a self-aligning manner using the first gate electrode layer 407 and the second gate electrode layer 413 as masks (see FIG. 22A).

As the impurity element 414, a p-type impurity element such as boron, aluminum, or gallium, or an n-type impurity element such as phosphorus or arsenic is added. Here, as the impurity element 414, phosphorus, which is an n-type impurity element, is added in order to form low-concentration impurity regions of an n-channel transistor. Phosphorus is added into the impurity regions 415a and 415b and the impurity regions 416a and 416b so as to be contained at a concentration of about 1×10¹⁷ atoms/cm³ to 5×10¹⁸ atoms/cm³.

Then, in order to form impurity regions (high-concentration impurity regions) serving as source and drain regions of the n-channel transistor, a resist mask 418a is formed to partially cover the single crystal semiconductor layer 401 and a resist mask 418b is selectively formed to cover the single crystal semiconductor layer 402. Then, impurity regions 419a and 419b are formed in the single crystal semiconductor layer 401 by addition of an impurity element 417 to the single crystal semiconductor layer 401 using the resist mask 418a as a mask (FIG. 22B).

As the impurity element 417, phosphorus of an n-type impurity element is added to the single crystal semiconductor layer 401, and the concentration of the added phosphorus is 5×10¹⁹ atoms/cm³ to 5×10²⁰ atoms/cm³. The impurity regions 419a and 419b are high-concentration n-type impurity regions and each serve as a source region or a drain region. The impurity regions 419a and 419b are formed in regions not overlapping with the first gate electrode layer 406 and the second gate electrode layer 412.

In addition, in the single crystal semiconductor layer 401, the impurity regions 420a and 420b are low-concentration impurity regions into which the impurity element 417 is not added. The concentration of the impurity element imparting n-type conductivity included in the impurity regions 420a and 420b is lower than that in the impurity regions 419a and 419b and serve as low-concentration impurity regions; therefore, the impurity regions 420a and 420b serve as high-resistance regions or LDD regions. In the single crystal semiconductor layer 401, a channel formation region 421 is formed in a region overlapping with the first gate electrode layer 406 and the second gate electrode layer 412.

An LDD region means a region to which an impurity element is added at a low concentration and which is formed between a channel formation region and a source or drain region that is formed by adding the impurity element at a high concentration. When an LDD region is provided, there is an advantageous effect in that an electric field in the vicinity of a drain region is reduced to prevent deterioration due to hot carrier injection. Further, a structure in which an LDD region overlaps with a gate electrode with a gate insulating layer interposed therebetween (also called a “gate-drain overlapped LDD (GOLD) structure”) may also be employed in order to prevent deterioration of an on-current value due to hot carrier.

Next, after removing the resist masks 418a and 418b, a resist mask 423 is formed to cover the single crystal semiconductor layer 401 so that a source region and a drain region of a p-channel transistor can be formed. Then, an impurity element 422 is added using the resist mask 423, the first gate electrode layer 407, and the second gate electrode layer 413 as masks, so that impurity regions 424a and 424b, impurity regions 425a and 425b and a channel formation region 426 are formed in the single crystal semiconductor layer 402 (FIG. 22C).

As the impurity element 422, a p-type impurity element such as boron, aluminum or gallium can be used. Here, boron that is a p-type impurity element is added so as to be contained at a concentration of approximately 1×10²⁰ atoms/cm³ to 5×10²¹ atoms/cm³.

In the single crystal semiconductor layer 402, the impurity regions 424a and 424b which are high-concentration impurity regions are formed in regions not overlapping with the first gate electrode layer 407 and the second gate electrode layer 413, and each serve as a source region or a drain region. Here, boron that is a p-type impurity element is added so as to be contained at a concentration of approximately 1×10²⁰ atoms/cm³ to 5×10²¹ atoms/cm³. The impurity region 424a and 424b are regions of the impurity regions 416a and 416b to which the impurity element 422 is added, respectively. Since the impurity regions 416a and 416b exhibit n-type conductivity, the impurity element 422 is added so that the impurity regions 424a and 424b have p-type conductivity. By adjusting the concentration of the impurity element 422 included in the impurity regions 424a and 424b, the impurity regions 424a and 424b can serve as a source region or a drain region.

The impurity regions 425a and 425b are formed in regions overlapping with the first gate electrode layer 407 but not overlapping with the second gate electrode layer 413, and the impurity regions are formed by adding the impurity element 422 to the single crystal semiconductor layer 402 through the first gate electrode layer 407. The impurity region 425a and 425b can serve as LDD regions.

In the single crystal semiconductor layer 402, the channel formation region 426 is formed in a region overlapping with the first gate electrode layer 407 and the second gate electrode layer 413.

Next, an interlayer insulating layer is formed. The interlayer insulating layer can be formed as a single layer or a stacked layer; here, the interlayer insulating layer has a two-layer structure of an insulating layer 427 and an insulating layer 428 (see FIG. 22D).

As the interlayer insulating layer, a silicon oxide layer, a silicon oxynitride layer, a silicon nitride layer, a silicon nitride oxide layer, or the like can be formed by a CVD method or a sputtering method. Further, the interlayer insulating film can also be formed by an application method such as a spin coating method, using an organic material such as polyimide, polyamide, polyvinylphenol, benzocyclobutene, acrylic, or epoxy, a siloxane material such as a siloxane resin, an oxazole resin, or the like. A siloxane material corresponds to a material having Si—O—Si bonds. Siloxane is composed of a skeleton formed by the bond of silicon (Si) and oxygen (O), in which an organic group containing at least hydrogen (such as an alkyl group and aromatic hydrocarbon) is used as a substituent. A fluoro group may be included in the organic group.

In this mode, a silicon nitride oxide layer is formed with a thickness of 100 nm as the insulating film 427, and a silicon oxynitride layer is formed with a thickness of 900 nm as the insulating film 428. The insulating films 427 and 428 are formed successively by a plasma CVD method. The interlayer insulating layer may also have a stacked-layer structure including three or more layers. Further, the interlayer insulating film may also have a stacked-layer structure including a silicon oxide layer, a silicon oxynitride layer, or a silicon nitride layer, and an insulating film formed using an organic material such as polyimide, polyamide, polyvinylphenol, benzocyclobutene, acrylic, or epoxy, a siloxane material such as a siloxane resin, or an oxazole resin.

Subsequently, contact holes are formed in the interlayer insulating layers (in this mode, the insulating layers 427 and 428), and wiring layers 429a, 429b, 430a and 430b each of which functions as a source electrode layer or a drain electrode layer are formed in the contact holes.

The contact holes are formed selectively in the insulating layers 427 and 428 so as to reach the impurity regions 419a and 419b which are formed in the single crystal semiconductor layer 401 and the impurity regions 424a and 424b which are formed in the single crystal semiconductor layer 402.

As the wiring layers 429a, 429b, 430a and 430b, a single layer formed of one element selected from aluminum, tungsten, titanium, tantalum, molybdenum, nickel, or neodymium, or an alloy containing a plurality of the above elements; or stacked layers of such layers can be used. As a conductive layer formed of an alloy containing the plurality of above elements, an aluminum alloy film containing titanium, an aluminum alloy film containing neodymium, or the like can be formed, for example. When the wiring layers have a stacked-layer structure, a structure can be employed in which an aluminum layer or an aluminum alloy layer as described above is sandwiched between titanium layers, for example.

Through the above-described steps, an n-channel transistor 431 and a p-channel transistor 432 can be manufactured using the semiconductor substrate having the single crystal semiconductor layer.

In this embodiment mode, the semiconductor substrate having the single crystal semiconductor layer which is transferred from the single crystal semiconductor substrate to the supporting substrate, and the entire region of which is melted by laser light irradiation to cause re-single-crystallization is used; therefore, the single crystal semiconductor layer has reduced crystal defects, high crystallinity and high planarity.

Accordingly, a high-performance and highly reliable semiconductor device can be manufactured with high yield.

This embodiment mode can be combined with any one of Embodiment Modes 1 to 3, as appropriate.

### Embodiment Mode 5

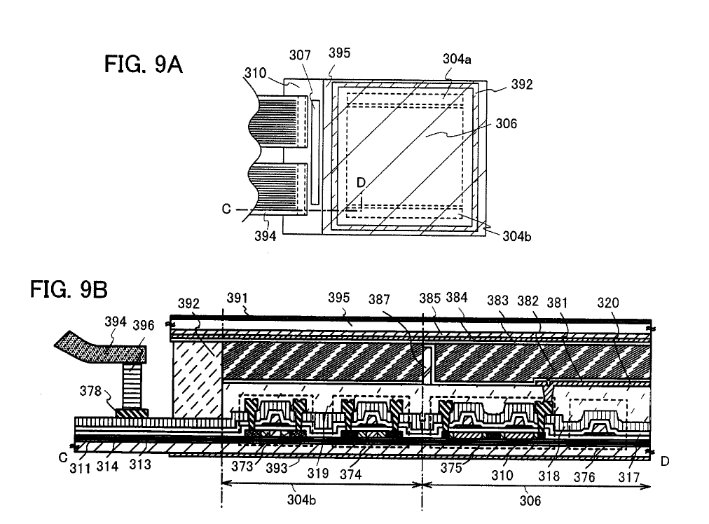

In this embodiment mode, an example of a method for manufacturing a semiconductor device (also referred to as a liquid crystal display device) having a display function as a semiconductor device having high performance and high reliability with high yield will be described with reference to FIGS. 9A and 9B. Specifically, a liquid crystal display device that includes a liquid crystal display element as a display element will be described.

FIG. 9A is a top view of a semiconductor device which is one mode of the present invention, and FIG. 9B is a cross-sectional view taken along a line C-D of FIG. 9A.

As illustrated in FIG. 9A, a pixel region 306 and driver circuit regions 304a and 304b which are scanning line driver circuits are sealed between a supporting substrate 310 and a counter substrate 395 with a sealant 392. In addition, a driver circuit region 307 which is a signal line driver circuit formed using a driver IC is provided over the supporting substrate 310. A transistor 375 and a capacitor 376 are provided in the pixel region 306. A driver circuit having transistors 373 and 374 is provided in the driver circuit region 304b. In the semiconductor device of this embodiment mode, the semiconductor substrate having high performance and high reliability using the present invention described in Embodiment Mode 1 is used.

In the pixel region 306, the transistor 375 to serve as a switching element is provided over a blocking layer 311, an insulating layer 314 having a bonding surface, and a protection layer 313. In this embodiment mode, a multi-gate thin film transistor (TFT) is used for the transistor 375, which includes a single crystal semiconductor layer having impurity regions functioning as source and drain regions, a gate insulating layer, a gate electrode layer having a two-layer structure, and source and drain electrode layers. The source or drain electrode layer is in contact with and electrically connected to the impurity region of the single crystal semiconductor layer and an electrode layer 320 which is used for a display element and also referred to as a pixel electrode layer.

Impurity regions in the single crystal semiconductor layer can be formed as high-concentration impurity regions and low-concentration impurity regions by controlling the concentration of the impurity element. A thin film transistor having low-concentration impurity regions is referred to as a transistor having an LDD (lightly doped drain) structure. Further, the low-concentration impurity regions may be formed to overlap with the gate electrode. A thin film transistor having such a structure is referred to as a transistor having a GOLD (gate overlapped LDD) structure. The polarity of the thin film transistor is to be an n-type by using phosphorus (P) or the like in the impurity regions. When p-channel thin film transistors are formed, boron (B) or the like may be added. After that, insulating films 317 and 318 are formed to cover the gate electrode and the like.

Further, in order to enhance a level of planarity, an insulating film 319 is formed as an interlayer insulating film. The insulating film 319 can be formed using an organic material, an inorganic material, or a stacked structure of them. For example, the insulating film 319 can be formed using a material such as silicon oxide, silicon nitride, silicon oxynitride, silicon nitride oxide, aluminum nitride, aluminum oxynitride, aluminum nitride oxide having a higher content of nitrogen than that of oxygen, aluminum oxide, diamond-like carbon (DLC), polysilazane, nitrogen-containing carbon (CN), PSG (phosphosilicate glass), BPSG (borophosphosilicate glass), alumina, and other substances containing an inorganic insulating material. Further, an organic insulating material can also be used. The organic material can be either photosensitive or non-photosensitive. For example, polyimide, acrylic, polyamide, polyimide amide, resist, benzocyclobutene, a siloxane resin, or the like can be used.

Since a single crystal semiconductor layer used for a semiconductor element is formed similarly to the case of Embodiment Mode 1 of the preset invention, a single crystal semiconductor layer transferred from a single crystal semiconductor substrate can be used as the semiconductor layer, and a pixel region and a driver circuit region can be formed over the same substrate. In that case, transistors in the pixel region 306 and transistors in the driver circuit region 304b are formed at the same time. Needless to say, the driver circuit region 307 may also be formed over the same substrate in a similar manner. Transistors used for the driver circuit region 304b form a CMOS circuit. Although the thin film transistors that form the CMOS circuit have a GOLD structure, an LDD structure like the transistor 375 can also be used.

Next, an insulating layer 381 which functions as an alignment film is formed so as to cover the electrode layer 320 used for a display element and the insulating film 319 by a printing method or a droplet discharge method. Note that when a screen printing method or an offset printing method is used, the insulating layer 381 can be formed selectively. After that, a rubbing treatment is performed. This rubbing treatment is not required to be performed depending on modes of liquid crystals, e.g., a VA mode. The same as the insulating layer 381 can be said for an insulating layer 383 which functions as an alignment film. Next, the sealant 392 is formed in a peripheral region of pixels by a droplet discharge method.

Then, the counter substrate 395, which has the insulating layer 383 that functions as the alignment film, an electrode layer 384 that is used for a display element and also referred to as a counter electrode layer, a coloring layer 385 functioning as a color filter, and a polarizer 391 (also referred to as polarizing plate), is attached to the supporting substrate 310 that is a TFT substrate with a spacer 387 interposed therebetween. A gap between the two substrates is provided with a liquid crystal layer 382. The semiconductor device in this embodiment mode is a transmissive type. Therefore, a polarizer (a polarizing plate) 393 is also provided on the side opposite to the surface of the supporting substrate 310 having elements. The stacked structure of the polarizer and the coloring layer is also not limited to that of FIGS. 9A and 9B and may be determined as appropriate depending on materials of the polarizer and the coloring layer or conditions of a manufacturing process. The polarizer can be provided on the substrate with an adhesive layer. In addition, a filler may be mixed in the sealant and further, a light-shielding film (black matrix) or the like may be formed on the counter substrate 395. When the liquid crystal display device is formed to be a full-color display device, color filters and the like may be formed using materials which exhibit red (R), green (G), and blue (B) colors. On the other hand, when the liquid crystal display device is formed to be a monochrome display device, coloring layers are not required. Alternatively, a coloring layer may be formed of a material which exhibits at least one color. In addition, an anti-reflective film having an antireflective function may be provided on the viewing side of the semiconductor device. Further, the polarizing plate and the liquid crystal layer may be stacked with a retardation plate interposed therebetween.

Note that, when a successive additive color mixture method (a field sequential method) is employed in which RGB light-emitting diodes (LEDs) and the like are used as a backlight and color display is performed by a time division method, a color filter is not provided in some cases. The black matrix, which can reduce reflection of external light by wirings of transistors or CMOS circuits, is preferably provided so as to overlap with the transistors or the CMOS circuits. Note that the black matrix may also be provided so as to overlap with a capacitor because reflection of light by metal films of the capacitor can be prevented.

The liquid crystal layer can be formed by a dispenser method (a dripping method) or an injection method in which the supporting substrate 310 having elements and the counter substrate 395 are bonded first and then liquid crystals are injected into a space therebetween by using a capillary phenomenon. When handling a large-sized substrate to which the injection method is difficult to be applied, the dripping method is preferably used.

The spacer can be provided by dispersing particles with a size of several μm. In this embodiment mode, however, a method for forming a resin film over the entire surface, followed by etching is employed. After applying such a spacer material by a spinner, the material is subjected to light-exposure and development treatment, so that a given pattern is formed. Further, the material is heated at 150° C. to 200° C. in a clean oven or the like so as to be hardened. Although the shape of the spacer formed in the above manner can vary depending on the conditions of light-exposure and development treatment, the shape of the spacer is preferably a columnar shape with a flat top. This is because mechanical strength that is high enough as a semiconductor device can be secured when attaching the counter substrate to the TFT substrate. The shape of the spacer can also be conic or pyramidal, but the present invention is not limited thereto.

Next, an FPC 394 which is a connection wiring board is connected to a terminal electrode layer 378 that is electrically connected to the pixel region, with an anisotropic conductive layer 396 interposed therebetween. The FPC 394 functions to transmit signals and potentials from outside. Through the above process, a semiconductor device having a display function can be manufactured.

In the semiconductor device of this embodiment mode, as described in Embodiment Mode 1, a semiconductor substrate having a single crystal semiconductor layer which is transferred from a single crystal semiconductor substrate to a supporting substrate, and the entire region of which is melted by laser light irradiation to cause re-single-crystallization is used; therefore, the single crystal semiconductor layer has reduced crystal defects, high crystallinity and high planarity.

Therefore, a semiconductor device which has high performance and high reliability can be formed with high yield.

This embodiment mode can be combined with any one of Embodiment Modes 1 to 4 as appropriate.

### Embodiment Mode 6

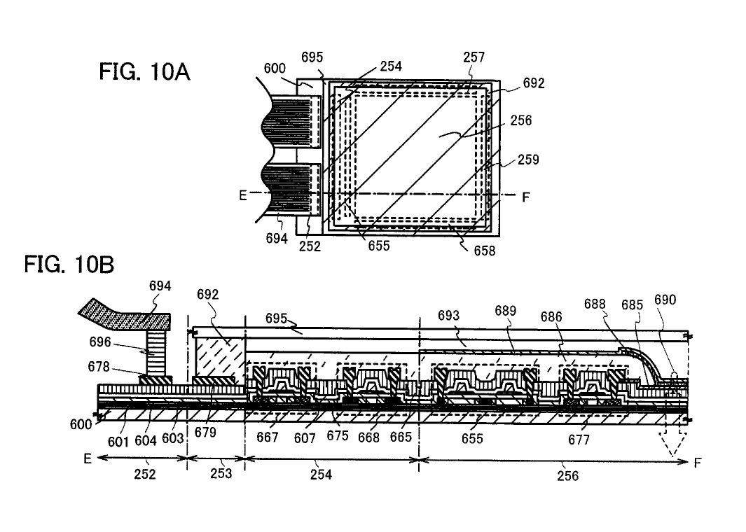

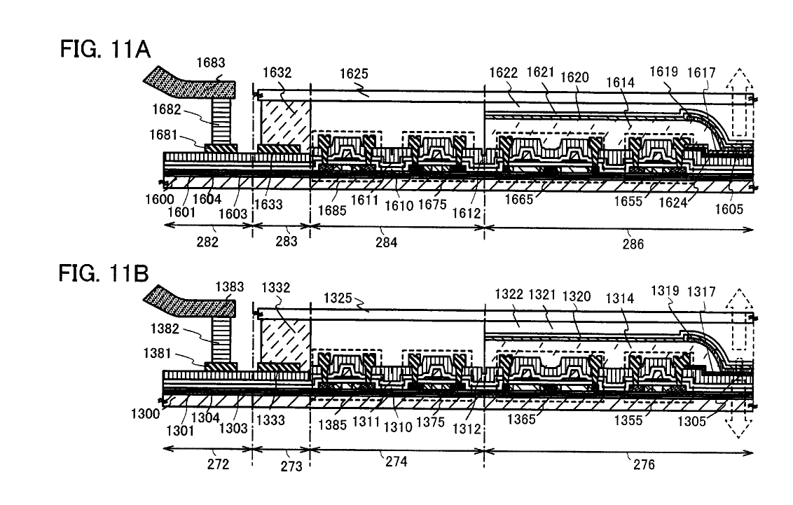

A semiconductor device having a light-emitting element can be formed by applying the present invention, and the light-emitting element emits light by any one of bottom emission, top emission, and dual emission. This embodiment mode will describe an example of a method for manufacturing a semiconductor device in which a semiconductor device having a display function (also called a display device or a light-emitting device) is manufactured with high yield as a bottom-emission, dual-emission, or top-emission semiconductor device with high performance and high reliability with reference to FIGS. 10A and 10B and FIGS. 11A and 11B.

A semiconductor device illustrated in FIGS. 10A and 10B employs a bottom-emission structure in which light is emitted in a direction indicated by an arrow. FIG. 10A is a plane view of the semiconductor device, and FIG. 10B is a cross-sectional view taken along a line E-F of FIG. 10A. In FIGS. 10A and 10B, the semiconductor device includes an external terminal connection region 252, a sealing region 253, a driver circuit region 254, and a pixel region 256.

The semiconductor device illustrated in FIGS. 10A and 10B includes an element substrate 600, a thin film transistor 655, a thin film transistor 677, a thin film transistor 667, a thin film transistor 668, a light-emitting element 690 including a first electrode layer 685, a light-emitting layer 688, and a second electrode layer 689, a filler 693, a sealant 692, a blocking layer 601, an insulating layer 604, an oxide film 603, a gate insulating layer 675, an insulating film 607, an insulating film 665, an insulating layer 686, a sealing substrate 695, a wiring layer 679, a terminal electrode layer 678, an anisotropic conductive layer 696, and an FPC 694. The semiconductor device includes the external terminal connection region 252, the sealing region 253, the driver circuit region 254, and the pixel region 256. The filler 693 can be formed by a dropping method using a composition in a liquid state. A semiconductor device (light-emitting display device) is sealed by attaching the element substrate 600 provided with the filler by a dropping method and the sealing substrate 695 to each other.

In the semiconductor device illustrated in FIGS. 10A and 10B, the first electrode layer 685 is formed using a light-transmitting conductive material so as to transmit light emitted from the light-emitting element 690, and the second electrode layer 689 is formed using a reflective conductive material so as to reflect light emitted from the light-emitting element 690.

Since the second electrode layer 689 is required to have reflectivity, a conductive film or the like formed of titanium, tungsten, nickel, gold, platinum, silver, copper, tantalum, molybdenum, aluminum, magnesium, calcium, lithium, or an alloy thereof may be used. It is preferable to use a substance having high reflectivity in a visible light range, and an aluminum film is used in this embodiment mode.

The first electrode layer 685 may be specifically formed using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. Needless to say, indium tin oxide (ITO), indium zinc oxide (IZO), indium tin oxide added with silicon oxide (ITSO), or the like can also be used.

A semiconductor device illustrated in FIG. 11A employs a top-emission structure in which light is emitted in a direction indicated by an arrow. The semiconductor device illustrated in FIG. 11A includes an element substrate 1600, a thin film transistor 1655, a thin film transistor 1665, a thin film transistor 1675, a thin film transistor 1685, a wiring layer 1624, a first electrode layer 1617, a light-emitting layer 1619, a second electrode layer 1620, a filler 1622, a sealant 1632, a blocking layer 1601, an insulating layer 1604, an oxide film 1603, a gate insulating layer 1610, an insulating film 1611, an insulating film 1612, an insulating layer 1614, a sealing substrate 1625, a wiring layer 1633, a terminal electrode layer 1681, an anisotropic conductive layer 1682, and an FPC 1683.

The semiconductor device shown in FIG. 11A includes an external terminal connection region 282, a sealing region 283, a driver circuit region 284, and a pixel region 286. In the semiconductor device shown in FIG. 11A, the wiring layer 1624 that is a reflective metal layer is provided below the first electrode layer 1617. The first electrode layer 1617 that is a transparent conductive film is formed over the wiring layer 1624. Since the wiring layer 1624 is required to have reflectivity, a conductive film or the like formed of titanium, tungsten, nickel, gold, platinum, silver, copper, tantalum, molybdenum, aluminum, magnesium, calcium, lithium, or an alloy thereof may be used. It is preferable to use a substance having high reflectivity in a visible light range. A conductive film may also be used as the first electrode layer 1617, and in that case, the wiring layer 1624 having reflectivity is not required to be provided.

The first electrode layer 1617 and the second electrode layer 1620 may each be specifically formed using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. Needless to say, indium tin oxide (ITO), indium zinc oxide (IZO), indium tin oxide added with silicon oxide (ITSO), or the like can also be used.

Further, when a material such as a metal film having no light-transmitting property is formed thin (preferably, a thickness of about 5 nm to 30 nm) so as to be able to transmit light, light can be emitted through the first electrode layer 1617 and the second electrode layer 1620. As a metal thin film which can be used for the first electrode layer 1617 and the second electrode layer 1620, a conductive film formed of titanium, tungsten, nickel, gold, platinum, silver, aluminum, magnesium, calcium, lithium, or an alloy thereof, or the like can be used.

A semiconductor device illustrated in FIG. 11B includes an element substrate 1300, a thin film transistor 1355, a thin film transistor 1365, a thin film transistor 1375, a thin film transistor 1385, a first electrode layer 1317, a light-emitting layer 1319, a second electrode layer 1320, a filler 1322, a sealant 1332, a blocking layer 1301, an insulating layer 1304, an oxide film 1303, a gate insulating layer 1310, an insulating film 1311, an insulating film 1312, an insulating layer 1314, a sealing substrate 1325, a wiring layer 1333, a terminal electrode layer 1381, an anisotropic conductive layer 1382, and an FPC 1383. The semiconductor device includes an external terminal connection region 272, a sealing region 273, a driver circuit region 274, and a pixel region 276.

The semiconductor device illustrated in FIG. 11B is dual-emission type and has a structure in which light is emitted in directions indicated by arrows from both the element substrate 1300 side and the sealing substrate 1325 side. Therefore, a light-transmitting electrode layer is used for each of the first electrode layer 1317 and the second electrode layer 1320.

In this embodiment mode, the first electrode layer 1317 and the second electrode layer 1320, which are light-transmitting electrode layers, may each be specifically formed using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. Needless to say, indium tin oxide (ITO), indium zinc oxide (IZO), indium tin oxide added with silicon oxide (ITSO), or the like can also be used.

Further, when a material such as a metal film having no light-transmitting property is formed thin (preferably, a thickness of about 5 nm to 30 nm) so as to be able to transmit light, light can be emitted through the first electrode layer 1317 and the second electrode layer 1320. As a metal thin film which can be used for the first electrode layer 1317 and the second electrode layer 1320, a conductive film or the like formed of titanium, tungsten, nickel, gold, platinum, silver, aluminum, magnesium, calcium, lithium, or an alloy thereof can be used.

In the above-described manner, the semiconductor device illustrated in FIG. 11B has a structure in which light emitted from a light-emitting element 1305 passes through the first electrode layer 1317 and the second electrode layer 1320 so that light is emitted from both sides.

A pixel of a semiconductor device that is formed using a light-emitting element can be driven by a passive matrix mode or an active matrix mode. Further, either digital driving or analog driving can be employed.

A color filter (coloring layer) may be formed over a sealing substrate. The color filter (coloring layer) can be formed by an evaporation method or a droplet discharge method. By using the color filter (coloring layer), high-definition display can also be carried out. This is because a broad peak can be modified to be sharp in the light emission spectrum of each color of RGB by the color filter (coloring layer).

Full color display can be performed by formation of a material to emit light of a single color and combination of the material with a color filter or a color conversion layer. The color filter (coloring layer) or the color conversion layer may be provided for, for example, the sealing substrate, and the sealing substrate may be attached to the element substrate.

Needless to say, display of single color light emission may also be performed. For example, an area color type semiconductor device may be formed by using single color light emission. The area color type is suitable for a passive matrix display portion and can mainly display characters and symbols.

By using a single crystal semiconductor layer, a pixel region and a driver circuit region can be formed to be integrated over the same substrate. In that case, a transistor in the pixel region and a transistor in the driver circuit region are formed at the same time.

The transistors provided in a semiconductor device of this embodiment mode illustrated in FIGS. 10A and 10B and FIGS. 11A and 11B can be manufactured similarly to the transistors described in Embodiment Mode 2.

In the semiconductor device of this embodiment mode, as described in Embodiment Mode 1, a semiconductor substrate having a single crystal semiconductor layer which is transferred from a single crystal semiconductor substrate to a supporting substrate, the entire region of which is melted by laser light irradiation to cause re-single-crystallization is used; therefore, the single crystal semiconductor layer has reduced crystal defects, high crystallinity and high planarity.

Therefore, a semiconductor device which has high performance and high reliability can be formed with high yield.

This embodiment mode can be combined with any one of Embodiment Modes 1 to 4, as appropriate.

### Embodiment Mode 7

This embodiment mode will describe an example of a semiconductor device (also referred to as a display device or a light-emitting device) including a display function as a semiconductor device having high performance and high reliability. Specifically, a light-emitting display device using a light-emitting element for a display element will be described.

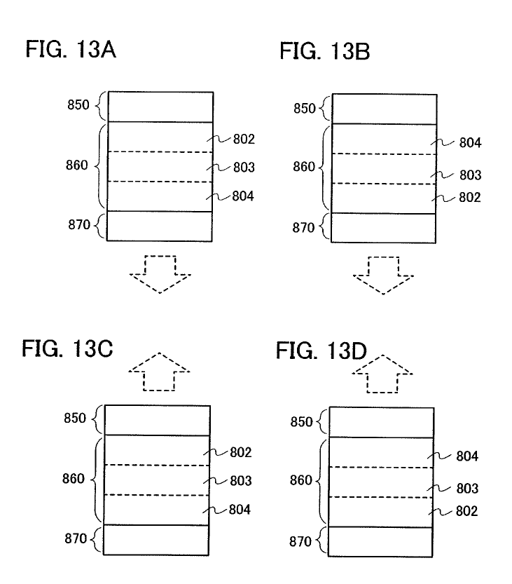

This embodiment mode will describe structures of light-emitting elements that can be used for display elements in the display device of the present invention with reference to FIGS. 13A to 13D.

FIGS. 13A to 13D illustrate structures of a light-emitting element in which an EL layer 860 is sandwiched between a first electrode layer 870 and a second electrode layer 850. The EL layer 860 includes a first layer 804, a second layer 803, and a third layer 802 as illustrated in the drawings. In FIGS. 13A to 13D, the second layer 803 is a light-emitting layer, and the first layer 804 and the third layer 802 are functional layers.

The first layer 804 is a layer having a function of transporting holes to the second layer 803. In FIGS. 13A to 13D, a hole-injecting layer included in the first layer 804 includes a substance having a high hole-injecting property, and molybdenum oxide, vanadium oxide, ruthenium oxide, tungsten oxide, manganese oxide, or the like can be used. Further, the first layer 804 can also be formed using the following: a phthalocyanine-based compound such as phthalocyanine (abbrev.: H₂Pc), copper phthalocyanine (abbrev.: CuPc), or the like; an aromatic amine compound such as 4,4′-bis[N-(4-diphenylaminophenyl)-N-phenylamino]biphenyl (abbrev.: DPAB), 4,4′-bis(N-{4-[N-(3-methylphenyl)-N-phenylamino]phenyl}-N-phenylamino)biphenyl (abbrev.: DNTPD), or the like; a high molecular compound such as poly(ethylene dioxythiophene)/poly(styrenesulfonic acid) (abbrev.: PEDOT/PSS); and the like.

Further, a composite material including an organic compound and an inorganic compound can be used for the hole-injecting layer. In particular, a composite material including an organic compound and an inorganic compound showing an electron-accepting property with respect to the organic compound is excellent in a hole-injecting property and a hole-transporting property since electrons are transferred between the organic compound and the inorganic compound and carrier density is increased.

Further, in the case where a composite material including an organic compound and an inorganic compound is used for the hole-injecting layer, the hole-injecting layer can form an ohmic contact with the electrode layer; therefore, a material of the electrode layer can be selected regardless of the work function.

As the inorganic compound used for the composite material, oxide of a transition metal is preferably used. In addition, oxide of a metal belonging to Groups 4 to 8 of the periodic table can be used. Specifically, the following are preferable because an electron-accepting property is high: vanadium oxide, niobium oxide, tantalum oxide, chromium oxide, molybdenum oxide, tungsten oxide, manganese oxide, and rhenium oxide. Among them, molybdenum oxide is particularly preferable because it is stable in the atmosphere, low in hygroscopicity, and is easy to be handled.

As the organic compound used for the composite material, various compounds can be used, such as an aromatic amine compound, a carbazole derivative, aromatic hydrocarbon, or a high molecular compound (e.g., an oligomer, a dendrimer, a polymer, or the like). Note that, as the organic compound used for the composite material, it is preferable to use an organic compound having a high hole-transporting property. Specifically, it is preferable to use a substance having a hole mobility of greater than or equal to 10⁻⁶ cm²/Vs. Further, other materials may also be used as long as a hole-transporting property thereof is higher than an electron-transporting property. Examples of the organic compound which can be used for the composite material are specifically listed below.

For example, as the aromatic amine compound, the following can be given: N,N′-di(p-tolyl)-N,N′-diphenyl-p-phenylenediamine (abbrev.: DTDPPA); 4,4′-bis[N-(4-diphenylaminophenyl)-N-phenylamino]biphenyl (abbrev.: DPAB); 4,4′-bis(N-{4-[N-(3-methylphenyl)-N-phenylamino]phenyl}-N-phenylamino)biphenyl (abbrev.: DNTPD); 1,3,5-tris[N-(4-diphenylaminophenyl)-N-phenylamino]benzene (abbrev.: DPA3B); and the like.

As specific examples of the carbazole derivative which can be used for the composite material, the following can be given: 3-[N-(9-phenylcarbazol-3-yl)-N-phenylamino]-9-phenylcarbazole (abbrev.: PCzPCA1); 3,6-bis[N-(9-phenylcarbazol-3-yl)-N-phenylamino]-9-phenylcarbazole (abbrev.: PCzPCA2); 3-[N-(1-naphthyl)-N-(9-phenylcarbazol-3-yl)amino]-9-phenylcarbazole (abbrev.: PCzPCN1); and the like.

Further, the following can also be used: 4,4′-di(N-carbazolyl)biphenyl (abbrev.: CBP); 1,3,5-tris[4-(N-carbazolyl)phenyl]benzene (abbrev.: TCPB); 9-[4-(N-carbazolyl)]phenyl-10-phenylanthracene (abbrev.: CzPA); 1,4-bis[4-(N-carbazolyl)phenyl]-2,3,5,6-tetraphenylbenzene; and the like.

Further, as the aromatic hydrocarbon which can be used for the composite material, the following can be given: 2-tert-butyl-9,10-di(2-naphthyl)anthracene (abbrev.: t-BuDNA); 2-tert-butyl-9,10-di(1-naphthyl)anthracene; 9,10-bis(3,5-diphenylphenyl)anthracene (abbrev.: DPPA); 2-tert-butyl-9,10-bis(4-phenylphenyl)anthracene (abbrev.: t-BuDBA); 9,10-di(2-naphthyl)anthracene (abbrev.: DNA); 9,10-diphenylanthracene (abbrev.: DPAnth); 2-tert-butylanthracene (abbrev.: t-BuAnth); 9,10-bis(4-methyl-1-naphthyl)anthracene (abbrev.: DMNA); 2-tert-butyl-9,10-bis[2-(1-naphthyl)phenyl]anthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. Besides the above, pentacene, coronene, or the like can also be used. As described above, an aromatic hydrocarbon which has a hole mobility of greater than or equal to 1×10⁻⁶ cm²/Vs and of which the carbon number is 14 to 42 is more preferable.

Note that the aromatic hydrocarbon which can be used for the composite material may have a vinyl skeleton. As examples of the aromatic hydrocarbon having a vinyl group, 4,4′-bis(2,2-diphenylvinyl)biphenyl (abbrev.: DPVBi), 9,10-bis[4-(2,2-diphenylvinyl)phenyl]anthracene (abbrev.: DPVPA), and the like can be given.

Further, a high molecular compound such as poly(N-vinylcarbazole) (abbrev.: PVK), poly(4-vinyltriphenylamine) (abbrev.: PVTPA), or the like can also be used.

As a substance for forming a hole-transporting layer included in the first layer 804 in FIGS. 13A to 13D, a substance having a high hole-transporting property, specifically, an aromatic amine compound (that is, a compound having a benzene ring-nitrogen bond) is preferable. As examples of the material which are widely used, the following can be given: 4,4′-bis[N-(3-methylphenyl)-N-phenylamino]biphenyl; a derivative thereof such as 4,4′-bis[N-(1-napthyl)-N-phenylamino]biphenyl (hereinafter referred to as NPB); and a starburst aromatic amine compound such as 4,4′,4″-tris(N,N-diphenyl-amino)triphenylamine, 4,4′,4″-tris[N-(3-methylphenyl)-N-phenylamino]triphenylamine, and the like. These substances described here are mainly substances each having a hole mobility of greater than or equal to 10⁻⁶ cm²/Vs. Further, other materials may also be used as long as a hole-transporting property thereof is higher than an electron-transporting property. The hole-transporting layer is not limited to a single layer and may be a mixed layer of any of the aforementioned substances or a stacked layer which includes two or more layers each containing the aforementioned substance.

The third layer 802 has a function of transporting and injecting electrons to the second layer 803. With reference to FIGS. 13A to 13D, an electron-transporting layer included in the third layer 802 is described. As the electron-transporting layer, a substance having a high electron-transporting property can be used. For example, a layer containing a metal complex or the like including a quinoline or benzoquinoline skeleton, such as tris(8-quinolinolato)aluminum (abbrev.: Alq), tris(4-methyl-8-quinolinolato)aluminum (abbrev.: Almq₃), bis(10-hydroxybenzo[h]quinolinato)beryllium (abbrev.: BeBq₂), bis(2-methyl-8-quinolinolato)(4-phenylphenolato)aluminum (abbrev.: BAlq), or the like can be used. Further, a metal complex or the like including an oxazole-based or thiazole-based ligand, such as bis[2-(2-hydroxyphenyl)benzoxazolato]zinc (abbrev.: Zn(BOX)₂), bis[2-(2-hydroxyphenyl)benzothiazolato]zinc (abbrev.: Zn(BTZ)₂), or the like can be used. Besides the above metal complexes, the following can be used: 2-(4-biphenylyl)-5-(4-tert-butylphenyl)-1,3,4-oxadiazole (abbrev.: PBD); 1,3-bis[5-(p-tert-butylphenyl)-1,3,4-oxadiazol-2-yl]benzene (abbrev.: OXD-7); 3-(4-biphenylyl)-4-phenyl-5-(4-tert-butylphenyl)-1,2,4-triazole (abbrev.: TAZ), bathophenanthroline (abbrev.: BPhen); bathocuproine (abbrev.: BCP); and the like. These substances described here are mainly substances each having an electron mobility of greater than or equal to 10⁻⁶ cm²/Vs. Further, other substances may also be used for the electron-transporting layer as long as an electron transporting property thereof is higher than a hole transporting property. The electron-transporting layer is not limited to a single layer and may be a stacked layer which includes two or more layers each containing the aforementioned substance.

With reference to FIGS. 13A to 13D, an electron-injecting layer included in the third layer 802 is described. As the electron-injecting layer, a substance having a high electron-injecting property can be used. As the electron-injecting layer, an alkali metal, an alkaline earth metal, or a compound thereof such as lithium fluoride (LiF), cesium fluoride (CsF), or calcium fluoride (CaF₂) can be used. For example, a layer which is made of a substance having an electron-transporting property and contains an alkali metal, an alkaline earth metal, or a compound thereof, for example, a layer of Alq containing magnesium (Mg) or the like can be used. It is preferable to use the layer which is made of a substance having an electron-transporting property and contains an alkali metal or an alkaline earth metal as the electron-injecting layer because electron injection from the electrode layer is efficiently performed by using the layer.

Next, the second layer 803 which is a light-emitting layer is described. The light-emitting layer has a function of emitting light and includes an organic compound having a light-emitting property. Further, the light-emitting layer may include an inorganic compound. The light-emitting layer may be formed using various light-emitting organic compounds and inorganic compounds. The thickness of the light-emitting layer is preferably about 10 nm to 100 nm.

There are no particular limitations on the organic compound used for the light-emitting layer as long as it is a light-emitting organic compound. As the organic compound, for example, the following can be given: 9,10-di(2-naphthyl)anthracene (abbrev.: DNA), 9,10-di(2-naphthyl)-2-tert-butylanthracene (abbrev.: t-BuDNA), 4,4′-bis(2,2-diphenylvinyl)biphenyl (abbrev.: DPVBi), coumarin 30, coumarin 6, coumarin 545, coumarin 545T, perylene, rubrene, periflanthene, 2,5,8,11-tetra(tert-butyl)perylene (abbrev.: TBP), 9,10-diphenylanthracene (abbrev.: DPA), 5,12-diphenyltetracene, 4-(dicyanomethylene)-2-methyl-[p-(dimethylamino)styryl]-4H-pyran (abbrev.: DCM1), 4-(dicyanomethylene)-2-methyl-6-[2-(julolidin-9-yl)ethenyl]-4H-pyran (abbrev.: DCM2), 4-(dicyanomethylene)-2,6-bis[p-(dimethylamino)styryl]-4H-pyran (abbrev.: BisDCM), and the like. Further, a compound capable of emitting phosphorescence such as bis[2-(4′,6′-difluorophenyl)pyridinato-N,C^{2′}]iridium(picolinate) (abbrev.: FIrpic), bis{2-[3′,5′-bis(trifluoromethyl)phenyl]pyridinato-N,C^{2′}}iridium(picolinate) (abbrev.: Ir(CF₃ ppy)₂(pic)), tris(2-phenylpyridinato-N,C^{2′})iridium (abbrev.: Ir(ppy)₃), bis(2-phenylpyridinato-N,C^{2′})iridium(acetylacetonate) (abbrev.: Ir(ppy)₂(acac)), bis[2-(2′-thienyl)pyridinato-N,C^{3′}]iridium(acetylacetonate) (abbrev.: Ir(thp)₂(acac)), bis(2-phenylquinolinato-N,C^{2′})iridium(acetylacetonate) (abbrev.: Ir(pq)₂(acac)), or bis[2-(2′-benzothienyl)pyridinato-N,C^{3′}]iridium(acetylacetonate) (abbrev.: Ir(btp)₂(acac)) may be used.

Further, a triplet excitation light-emitting material containing a metal complex or the like may be used for the light-emitting layer in addition to a singlet excitation light-emitting material. For example, among pixels emitting light of red, green, and blue, the pixel emitting light of red whose luminance is reduced by half in a relatively short time is formed using a triplet excitation light-emitting material and the other pixels are formed using a singlet excitation light-emitting material. A triplet excitation light-emitting material has a feature of favorable light-emitting efficiency, so that less power is consumed to obtain the same luminance. In other words, when a triplet excitation light-emitting material is used for the pixel emitting light of red, a smaller amount of current is necessary to be applied to a light-emitting element; thus, reliability can be improved. The pixel emitting light of red and the pixel emitting light of green may be formed using a triplet excitation light-emitting material and the pixel emitting light of blue may be formed using a singlet excitation light-emitting material in order to achieve low power consumption. Low power consumption can be further achieved by formation of a light-emitting element that emits light of green, which has high visibility for human eyes, with the use of a triplet excitation light-emitting material.

Another organic compound may be further added to the light-emitting layer including any of the above-described organic compounds which emit light. Examples of the organic compound that can be added are TDATA, MTDATA, m-MTDAB, TPD, NPB, DNTPD, TCTA, Alq₃, Almq₃, BeBq₂, BAlq, Zn(BOX)₂, Zn(BTZ)₂, BPhen, BCP, PBD, OXD-7, TPBI, TAZ, p-EtTAZ, DNA, t-BuDNA, DPVBi, and the like, and 4,4′-bis(N-carbazolyl)biphenyl (abbrev.: CBP), 1,3,5-tris[4-(N-carbazolyl)phenyl]benzene (abbrev.: TCPB), and the like. However, the present invention is not limited thereto. It is preferable that the organic compound which is added in addition to the organic compound which emits light have a larger excitation energy and be added in a larger amount than the organic compound which emits light, in order to make the organic compound emit light efficiently (which makes it possible to prevent concentration quenching of the organic compound). Further, as another function, the added organic compound may emit light along with the organic compound which emits light (which makes it possible to emit white light or the like).

The light-emitting layer may have a structure in which color display is performed by formation of a light-emitting layer having a different emission wavelength range for each pixel. Typically, light-emitting layers corresponding to respective colors of R (red), G (green), and B (blue) are formed. Also in this case, color purity can be improved and a pixel region can be prevented from having a mirror surface (reflection) by provision of a filter which transmits light of the emission wavelength range on the light-emission side of the pixel. By provision of the filter, a circularly polarizing plate or the like that has been conventionally considered to be necessary can be omitted, and further, the loss of light emitted from the light-emitting layer can be eliminated. Further, change in color tone, which occurs when a pixel region (display screen) is obliquely seen, can be reduced.

Either a low-molecular organic light-emitting material or a high-molecular organic light-emitting material may be used for a material of the light-emitting layer. A high-molecular organic light-emitting material has higher physical strength than a low-molecular material and an element using the high-molecular organic light-emitting material has higher durability than an element using a low-molecular material. In addition, since a high-molecular organic light-emitting material can be formed by coating, the element can be relatively easily formed.

The color of light emission is determined depending on a material forming the light-emitting layer; therefore, a light-emitting element which emits light of a desired color can be formed by selecting an appropriate material for the light-emitting layer. As a high-molecular electroluminescent material which can be used for forming the light-emitting layer, a polyparaphenylene-vinylene-based material, a polyparaphenylene-based material, a polythiophene-based material, a polyfluorene-based material, and the like can be given.

As the polyparaphenylene-vinylene-based material, a derivative of poly(paraphenylenevinylene) [PPV] such as poly(2,5-dialkoxy-1,4-phenylenevinylene) [RO-PPV], poly(2-(2′-ethyl-hexoxy)-5-methoxy-1,4-phenylenevinylene) [MEH-PPV], poly(2-(dialkoxyphenyl)-1,4-phenylenevinylene) [ROPh-PPV], and the like can be given. As the polyparaphenylene-based material, a derivative of polyparaphenylene [PPP] such as poly(2,5-dialkoxy-1,4-phenylene) [RO-PPP], poly(2,5-dihexoxy-1,4-phenylene), and the like can be given. As the polythiophene-based material, a derivative of polythiophene [PT] such as poly(3-alkylthiophene) [PAT], poly(3-hexylthiophen) [PHT], poly(3-cyclohexylthiophen) [PCHT], poly(3-cyclohexyl-4-methylthiophene) [PCHMT], poly(3,4-dicyclohexylthiophene) [PDCHT], poly[3-(4-octylphenyl)-thiophene] [POPT], poly[3-(4-octylphenyl)-2,2bithiophene] [PTOPT], and the like can be given. As the polyfluorene-based material, a derivative of polyfluorene [PF] such as poly(9,9-dialkylfluorene) [PDAF], poly(9,9-dioctylfluorene) [PDOF], and the like can be given.

The inorganic compound used for the light-emitting layer may be any inorganic compound as long as light emission of the organic compound is not easily quenched by the inorganic compound, and various kinds of metal oxide and metal nitride may be used. In particular, oxide of a metal that belongs to Group 13 or 14 of the periodic table is preferable because light emission of the organic compound is not easily quenched, and specifically, aluminum oxide, gallium oxide, silicon oxide, and germanium oxide are preferable. However, the inorganic compound is not limited thereto.

Note that the light-emitting layer may be formed by stacking a plurality of layers each containing a combination of the organic compound and the inorganic compound, which are described above, or may further contain another organic compound or inorganic compound. A layer structure of the light-emitting layer can be changed, and an electrode layer for injecting electrons may be provided or light-emitting materials may be dispersed, instead of provision of a specific electron-injecting region or light-emitting region. Such a change can be permitted unless it departs from the spirit of the present invention.

A light-emitting element formed using the above materials emits light by being forwardly biased. A pixel of a semiconductor device which is formed using a light-emitting element can be driven by a passive matrix mode or an active matrix mode. In either case, each pixel emits light by application of forward bias thereto at a specific timing; however, the pixel is in a non-light-emitting state for a certain period. Reliability of a light-emitting element can be improved by application of reverse bias in the non-light-emitting time. In a light-emitting element, there is a deterioration mode in which light emission intensity is decreased under a constant driving condition or a deterioration mode in which a non-light-emitting region is increased in the pixel and luminance is apparently decreased. However, progression of deterioration can be slowed down by performing alternating driving in which bias is applied forwardly and reversely; thus, reliability of a semiconductor device including a light-emitting element can be improved. In addition, either digital driving or analog driving can be applied.

A color filter (coloring layer) may be provided for a sealing substrate. The color filter (coloring layer) can be formed by an evaporation method or a droplet discharge method. High-definition display can be performed with the use of the color filter (coloring layer). This is because a broad peak can be modified to be sharp in a light emission spectrum of each of RGB by the color filter (coloring layer).

Full color display can be performed by formation of a material emitting light of a single color and combination of the material with a color filter or a color conversion layer. The color filter (coloring layer) or the color conversion layer may be provided for, for example, the sealing substrate, and the sealing substrate may be attached to the element substrate.

Needless to say, display of single color light emission may also be performed. For example, an area color type semiconductor device may be formed by using single color light emission. The area color type is suitable for a passive matrix display portion and can mainly display characters and symbols.

It is necessary to select materials for the first electrode layer 870 and the second electrode layer 850 considering the work function. The first electrode layer 870 and the second electrode layer 850 can be either an anode (an electrode layer with high potential) or a cathode (an electrode layer with low potential) depending on the pixel structure. In the case where the polarity of a driving thin film transistor is a p-channel type, the first electrode layer 870 may serve as an anode and the second electrode layer 850 may serve as a cathode as illustrated in FIG. 13A. In the case where the polarity of the driving thin film transistor is an n-channel type, the first electrode layer 870 may serve as a cathode and the second electrode layer 850 may serve as an anode as illustrated in FIG. 13B. Materials that can be used for the first electrode layer 870 and the second electrode layer 850 are described below. It is preferable to use a material having a high work function (specifically, a material having a work function of greater than or equal to 4.5 eV) for one of the first electrode layer 870 and the second electrode layer 850, which serves as an anode, and a material having a low work function (specifically, a material having a work function of less than or equal to 3.5 eV) for the other electrode layer which serves as a cathode. However, since the first layer 804 is excellent in a hole-injecting property and a hole-transporting property and the third layer 802 is excellent in an electron-injecting property and an electron-transporting property, both the first electrode layer 870 and the second electrode layer 850 are scarcely restricted by a work function and various materials can be used.

The light-emitting elements in FIGS. 13A and 13B each have a structure in which light is extracted from the first electrode layer 870 and thus, the second electrode layer 850 need not necessarily have a light-transmitting property. The second electrode layer 850 may be formed of a film mainly containing an element selected from Ti, Ni, W, Cr, Pt, Zn, Sn, In, Ta, Al, Cu, Au, Ag, Mg, Ca, Li or Mo, or an alloy material or a compound material containing any of the above elements as its main component, such as titanium nitride, TiSiₓN_{y}, WSiₓ, tungsten nitride, WSiₓN_{y}, or NbN; or a stacked film thereof with a total thickness of 100 nm to 800 nm.

In addition, when the second electrode layer 850 is formed using a light-transmitting conductive material similarly to the material used for the first electrode layer 870, light can be extracted from the second electrode layer 850 as well, and a dual emission structure can be obtained, in which light from the light-emitting element is emitted through both the first electrode layer 870 and the second electrode layer 850.

Note that the light-emitting element of the present invention can have variations by changing types of the first electrode layer 870 and the second electrode layer 850.

FIG. 13B illustrates the case where the EL layer 860 is formed by stacking the third layer 802, the second layer 803, and the first layer 804 in this order from the first electrode layer 870 side.

FIG. 13C illustrates a structure in which an electrode layer having reflectivity is used for the first electrode layer 870 and an electrode layer having a light-transmitting property is used for the second electrode layer 850 in FIG. 13A. Light emitted from the light-emitting element is reflected at the first electrode layer 870, transmitted through the second electrode layer 850, and emitted to the outside. Similarly, FIG. 13D illustrates a structure in which an electrode layer having reflectivity is used for the first electrode layer 870 and an electrode layer having a light-transmitting property is used for the second electrode layer 850 in FIG. 13B. Light emitted from the light-emitting element is reflected at the first electrode layer 870, transmitted through the second electrode layer 850, and emitted to the outside.

Further, various methods can be used as a method for forming the EL layer 860 when an organic compound and an inorganic compound are mixed in the EL layer 860. For example, there is a co-evaporation method of vaporizing both an organic compound and an inorganic compound by resistance heating. Further, for co-evaporation, an inorganic compound may be vaporized by an electron beam (EB) while an organic compound is vaporized by resistance heating. Furthermore, a method for sputtering an inorganic compound while vaporizing an organic compound by resistance heating to deposit the both at the same time may also be used. Instead, the EL layer 860 may be formed by a wet method.

As a method for manufacturing the first electrode layer 870 and the second electrode layer 850, an evaporation method by resistance heating, an EB evaporation method, a sputtering method, a CVD method, a spin coating method, a printing method, a dispenser method, a droplet discharge method, or the like can be used.

This embodiment mode can be combined with any of Embodiment Modes 1 to 4 and Embodiment Mode 6, as appropriate.

### Embodiment Mode 8

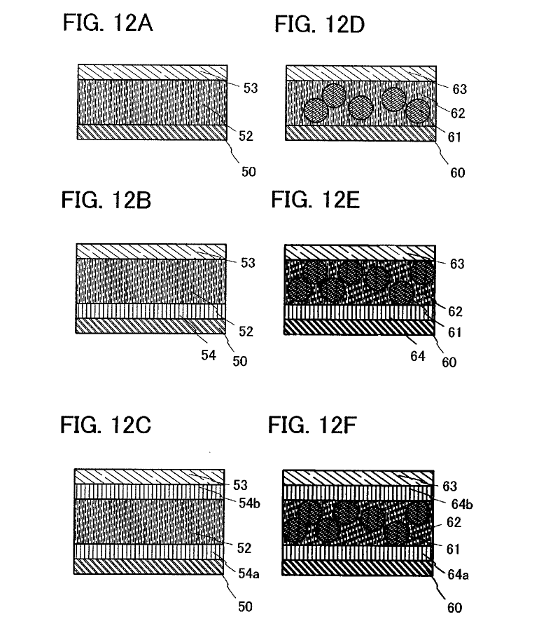

This embodiment mode will describe other examples of a semiconductor device having a display function as a semiconductor device with high performance and high reliability. In this embodiment mode, other structures that can be applied to the light-emitting element in the semiconductor device of the present invention will be described with reference to FIGS. 12A to 12F.

Light-emitting elements using electroluminescence can be roughly classified into light-emitting elements that use an organic compound as a light-emitting material and light-emitting elements that use an inorganic compound as a light-emitting material. In general, the former are referred to as organic EL elements, while the latter are referred to as inorganic EL elements.

Inorganic EL elements are classified into a dispersion-type inorganic EL element and a thin-film-type inorganic EL element according to their element structures. The difference between the two EL elements lies in that the former dispersion-type inorganic EL element includes an electroluminescent layer in which particles of a light-emitting material are dispersed in a binder, while the latter thin-film-type inorganic EL element includes an electroluminescent layer made of a thin film of a light-emitting material. Although the two light-emitting elements are different in the above points, they have a common characteristic in that both require electrons that are accelerated by a high electric field. As light-emission mechanisms, there are donor-acceptor recombination type light emission that utilizes a donor level and an acceptor level, and localized type light emission that utilizes inner-shell electron transition of a metal ion. In general, donor-acceptor recombination light emission is employed in dispersion type inorganic EL elements and localized type light emission is employed in thin-film type inorganic EL elements in many cases.

A light-emitting material that can be used in the present invention contains a base material and an impurity element which serves as a luminescence center. By changing the impurity element to be contained in the light-emitting material, light emission of various colors can be obtained. As a method for forming a light-emitting material, various methods such as a solid-phase method and a liquid-phase method (a coprecipitation method) can be used. Further, an evaporative decomposition method, a double decomposition method, a method utilizing thermal decomposition reaction of a precursor, a reversed micelle method, a method which combines the foregoing method with high-temperature baking, a liquid-phase method such as a freeze-drying method, or the like can also be used.

A solid phase method is a method in which a base material, and an impurity element or a compound containing an impurity element are weighed, mixed in a mortar, heated in an electric furnace, and baked to be reacted, whereby the impurity element is contained in the base material. The baking temperature is preferably 700° C. to 1500° C. This is because the solid-phase reaction will not proceed when the temperature is too low, whereas the base material will be decomposed when the temperature is too high. The baking may be performed in a powder state; however, it is preferably performed in a pellet state. Although the solid-phase method requires baking at a relatively high temperature, the solid-phase method is easy to perform and has high productivity. Thus, it is suitable for mass production.

A liquid-phase method (a coprecipitation method) is a method in which a base material or a compound containing a base material, and an impurity element or a compound containing an impurity element are reacted in a solution, dried, and then baked. Particles of a light-emitting material are uniformly distributed, and the reaction can progress even when the grain size is small and the baking temperature is low.

As a base material of a light-emitting material, sulfide, oxide, or nitride can be used. Examples of sulfide include zinc sulfide (ZnS), cadmium sulfide (CdS), calcium sulfide (CaS), yttrium sulfide (Y₂S₃), gallium sulfide (Ga₂S₃), strontium sulfide (SrS), and barium sulfide (BaS). Examples of oxide include zinc oxide (ZnO) and yttrium oxide (Y₂O₃). Examples of nitride include aluminum nitride (AlN), gallium nitride (GaN), and indium nitride (InN). Further, it is also possible to use zinc selenide (ZnSe), zinc telluride (ZnTe), or ternary mixed crystals such as calcium gallium sulfide (CaGa₂S₄), strontium gallium sulfide (SrGa₂S₄), barium gallium sulfide (BaGa₂S₄), or the like.

For a luminescence center of an EL element which exhibits localized type light emission, the following can be used: manganese (Mn), copper (Cu), samarium (Sm), terbium (Tb), erbium (Er), thulium (Tm), europium (Eu), cerium (Ce), praseodymium (Pr), and the like. Note that a halogen element such as fluorine (F), chlorine (Cl), or the like may also be added. The halogen element can function to compensate electric charge.

Meanwhile, for a luminescence center of an EL element which exhibits donor-acceptor recombination light emission, a light-emitting material containing a first impurity element which forms a donor level and a second impurity element which forms an acceptor level can be used. Examples of the first impurity element include fluorine (F), chlorine (Cl), aluminum (Al), and the like. Meanwhile, examples of the second impurity element include copper (Cu), silver (Ag), and the like.

In the case of synthesizing a light-emitting material of an EL element which exhibits donor-acceptor recombination light emission by using a solid-phase method, the following steps are performed: weighing a base material, weighing a first impurity element or a compound containing the first impurity element, weighing a second impurity element or a compound containing the second impurity element, mixing them in a mortar, and heating and baking them in an electric furnace. As a base material, the above-described base materials can be used. As a first impurity element or a compound containing the first impurity element, fluorine (F), chlorine (Cl), aluminum sulfide (Al₂S₃), or the like can be used, for example. As a second impurity element or a compound containing the second impurity element, copper (Cu), silver (Ag), copper sulfide (Cu₂S), silver sulfide (Ag₂S), or the like can be used, for example. The baking temperature is preferably 700° C. to 1500° C. This is because the solid-phase reaction will not proceed when the temperature is too low, whereas the base material will be decomposed when the temperature is too high. The baking may be performed in a powder state; however, it is preferably performed in a pellet state.

In the case of performing solid-phase reaction, it is also possible to use a compound containing the first impurity element and the second impurity element as the impurity element. In that case, the impurity elements can be easily diffused, and solid-phase reaction can easily proceed; therefore, a uniform light-emitting material can be obtained. Further, since unnecessary impurity elements are not mixed, a light-emitting material with high purity can be obtained. As the compound containing the first impurity element and the second impurity element, copper chloride (CuCl), silver chloride (AgCl), or the like can be used.

Note that the concentration of the impurity element with respect to the base material may be 0.01 at. % to 10 at. %, preferably, 0.05 at. % to 5 at. %.

With regard to a thin-film-type inorganic EL element, an electroluminescent layer contains the above-described light-emitting material and can be formed by a vacuum evaporation method such as a resistance heating evaporation method or an electron beam evaporation (EB evaporation) method, a physical vapor deposition (PVD) method such as a sputtering method, a chemical vapor deposition (CVD) method such as a metal organic CVD method or a low pressure hydride transport CVD method, an atomic layer epitaxy (ALE) method, or the like.

FIGS. 12A to 12C illustrate examples of a thin-film-type inorganic EL element that can be used as a light-emitting element. Each of the light-emitting elements illustrated in FIGS. 12A to 12C includes a first electrode layer 50, an electroluminescent layer 52, and a second electrode layer 53.

The light-emitting elements illustrated in FIGS. 12B and 12C each have a structure in which an insulating layer is provided between the electrode layer and the electroluminescent layer of the light-emitting element illustrated in FIG. 12A. The light-emitting element illustrated in FIG. 12B has an insulating layer 54 between the first electrode layer 50 and the electroluminescent layer 52. The light-emitting element illustrated in FIG. 12C has an insulating layer 54a between the first electrode layer 50 and the electroluminescent layer 52, and an insulating layer 54b between the second electrode layer 53 and the electroluminescent layer 52. As described above, the insulating layer may be provided between the electroluminescent layer and one or both of the pair of electrode layers. In addition, the insulating layer may be either a single layer or a plurality of stacked layers.

Although the insulating layer 54 is provided to be in contact with the first electrode layer 50 in FIG. 12B, the insulating layer 54 may also be provided to be in contact with the second electrode layer 53 by reversing the order of the insulating layer and the electroluminescent layer.

In the case of forming a dispersion-type inorganic EL element, a film-form electroluminescent layer is formed by dispersing particles of a light-emitting material in a binder. When particles with a desired size cannot be obtained due to a method for forming a light-emitting material, the material may be processed into particulate forms by being ground in a mortar or the like. A binder is a substance for fixing particles of a light-emitting material in a dispersed state in order to keep the shape of the electroluminescent layer. Light-emitting materials are uniformly dispersed and fixed in the electroluminescent layer by the binder.

The electroluminescent layer of the dispersion-type inorganic EL element can be formed by a droplet discharge method by which an electroluminescent layer can be selectively formed, a printing method (e.g., screen printing or offset printing), a coating method such as a spin coating method, a dipping method, a dispenser method, or the like. The thickness of the electroluminescent layer is not limited to a specific value; however, it is preferably in the range of 10 nm to 1000 nm. In the electroluminescent layer which contains a light-emitting material and a binder, the percentage of the light-emitting material is preferably greater than or equal to 50 wt % and less than or equal to 80 wt %.

FIGS. 12D to 12F illustrate examples of a dispersion-type inorganic EL element that can be used as a light-emitting element. The light-emitting element illustrated in FIG. 12D has a structure in which a first electrode layer 60, an electroluminescent layer 62, and a second electrode layer 63 are stacked, and the electroluminescent layer 62 contains a light-emitting material 61 fixed by a binder.

As a binder that can be used in this embodiment mode, an organic material, an inorganic material, or a mixed material of an organic material and an inorganic material can be used. As an organic material, the following resins can be used: a polymer having a relatively high dielectric constant such as a cyanoethyl cellulose based resin, a polyethylene resin, a polypropylene resin, a polystyrene based resin, a silicone resin, an epoxy resin, and vinylidene fluoride. Further, it is also possible to use thermally stable high molecular materials such as aromatic polyamide, polybenzimidazole, and the like; or a siloxane resin. Note that a siloxane resin has a Si—O—Si bond. Siloxane is composed of a skeleton formed by the bond of silicon (Si) and oxygen (O), in which an organic group containing at least hydrogen (such as an alkyl group and aromatic hydrocarbon) is used as a substituent. A fluoro group may be included in the organic group. Further, it is also possible to use a resin material such as a vinyl resin (e.g., polyvinyl alcohol, polyvinyl butyral, or the like), a phenol resin, a novolac resin, an acrylic resin, a melamine resin, a urethane resin, an oxazole resin (e.g., polybenzoxazole), or the like. When high-dielectric-constant microparticles of, for example, barium titanate (BaTiO₃), strontium titanate (SrTiO₃), or the like are mixed as appropriate into the above-described resin, the dielectric constant of the material can be controlled.

As an inorganic material contained in the binder, the following materials can be used: silicon oxide (SiOₓ), silicon nitride (SiNₓ), silicon containing oxygen and nitrogen, aluminum nitride (AlN), aluminum containing oxygen and nitrogen, aluminum oxide (Al₂O₃), titanium oxide (TiO₂), BaTiO₃, SrTiO₃, lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), ZnS, and other substances containing an inorganic material. When a high-dielectric-constant inorganic material is mixed into an organic material (by addition or the like), it becomes possible to control the dielectric constant of the electroluminescent layer which contains a light-emitting material and a binder more efficiently, whereby the dielectric constant can be further increased.

In the manufacturing process, light-emitting materials are dispersed in a solution containing a binder. As a solvent of the solution containing a binder that can be used in this embodiment mode, it is preferable to appropriately select a solvent in which a binder material can be dissolved and with which a solution having a viscosity suitable for a method for forming the electroluminescent layer (various wet processes) and a desired film thickness can be formed. An organic solvent or the like can be used. For example, when a siloxane resin is used as a binder, propylene glycolmonomethyl ether, propylene glycolmonomethyl ether acetate (also referred to as PGMEA), 3-methoxy-3-methyl-1-butanol (also referred to as MMB), or the like can be used.

The light-emitting elements illustrated in FIGS. 12E and 12F each have a structure in which an insulating layer is provided between the electrode layer and the electroluminescent layer of the light-emitting element illustrated in FIG. 12D. The light-emitting element illustrated in FIG. 12E has an insulating layer 64 between the first electrode layer 60 and the electroluminescent layer 62. The light-emitting element illustrated in FIG. 12F has an insulating layer 64a between the first electrode layer 60 and the electroluminescent layer 62, and an insulating layer 64b between the second electrode layer 63 and the electroluminescent layer 62. As described above, the insulating layer may be provided between the electroluminescent layer and one or both of the pair of electrode layers. In addition, the insulating layer may be either a single layer or a plurality of stacked layers.

Note that the insulating layer 64 is provided in contact with the first electrode layer 60 in FIG. 12E, but, the insulating layer 64 may be provided in contact with the second electrode layer 63 by reversing the positions of the insulating layer and the electroluminescent layer.

There is no particular limitation on the insulating layers 54, 54a, 54b, 64, 64a, and 64b illustrated in FIGS. 12A to 12F, but they preferably have high withstand voltage and are dense films. Further, the insulating layers preferably have high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like can be used. Alternatively, a mixed film of any of those materials or a stacked-layer film including two or more of those materials can be used. An insulating film of a material selected from the foregoing materials can be formed by sputtering, evaporation, CVD, or the like. Alternatively, the insulating layer may be formed by dispersing particles of a material selected from the foregoing insulating materials in a binder. A material for the binder may be the same as the binder contained in the electroluminescent layer and may be formed by the same method. There is no particular limitation on a film thickness, but preferably it is in a range of 10 nm to 1000 nm.

The light-emitting element of this embodiment mode emits light when voltage is applied between the pair of electrode layers sandwiching the electroluminescent layer. The light-emitting element of this embodiment can operate with either direct current driving or alternating current driving.

This embodiment mode can be combined with any of Embodiment Modes 1 to 4 and Embodiment Mode 6, as appropriate.

### Embodiment Mode 7

A television device can be completed using a semiconductor device which includes a display element and is formed by the present invention. An example of a television device having high performance and high reliability will be described.

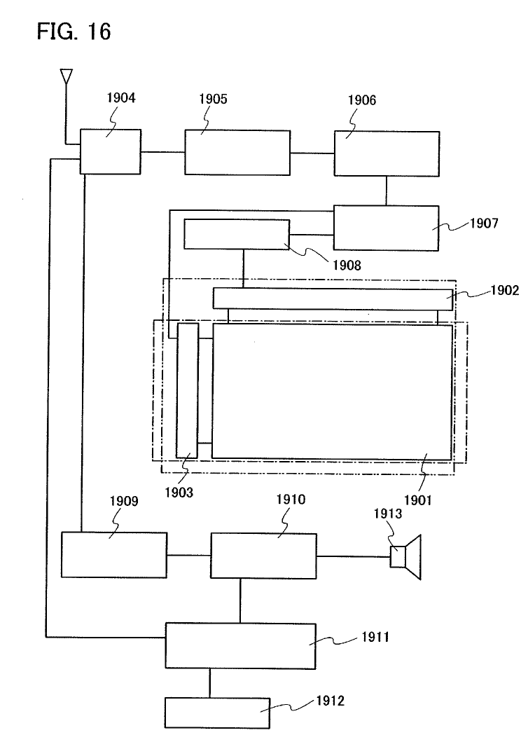

FIG. 16 is a block diagram illustrating a main configuration of a television device (a liquid crystal television device or an EL television device).

As for the structures of other external circuits, a video signal amplifier circuit 1905 for amplifying video signals among signals received at a tuner 1904, a video signal processing circuit 1906 for converting signals output from the video signal amplifier circuit 1905 into color signals corresponding to red, green, and blue, a control circuit 1907 for converting the video signals into an input specification of the driver ICs, and the like are provided on the input side of the video signals. The control circuit 1907 outputs signals to each of the scanning line side and the signal line side. In the case of digital driving, a signal divider circuit 1908 may be provided on the signal line side so that input digital signals can be divided into m pieces to be supplied.

Audio signals among the signals received at the tuner 1904 are transmitted to an audio signal amplifier circuit 1909, and an output thereof is supplied to a speaker 1913 through an audio signal processing circuit 1910. A control circuit 1911 receives control data on the receiving station (reception frequency) or sound volume from an input portion 1912, and transmits signals to the tuner 1904 and the audio signal processing circuit 1910.

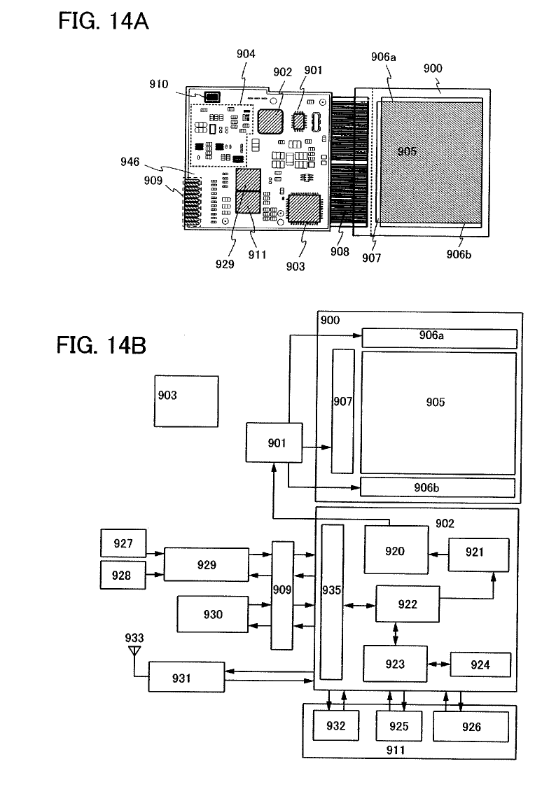

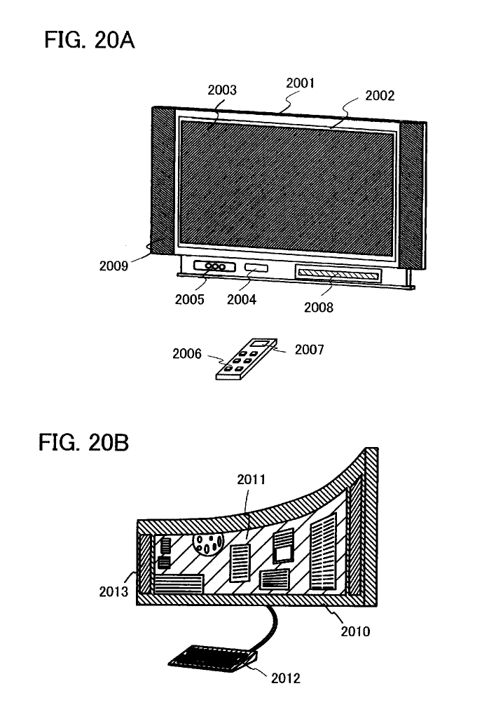

By incorporating a display module into a housing as illustrated in FIGS. 20A and 20B, a television device can be completed. A display panel in which components up to an FPC are set as illustrated in FIGS. 14A and 14B is generally called an EL display module. When an EL display module is used, an EL television device can be completed, and when a liquid crystal display module is used, a liquid crystal television device can be completed. Using a display module, a main display screen 2003 can be formed, and other accessories such as speaker portions 2009 and operation switches are provided. In this manner, a television device can be completed according to the present invention.

In addition, reflected light of incident light from external may be blocked with the use of a retardation plate or a polarizing plate. In a top-emission semiconductor device, an insulating layer serving as a partition wall may be colored to be used as a black matrix. This partition wall can also be formed by a droplet discharge method or the like. Carbon black or the like may be mixed into a black resin of a pigment material or a resin material such as polyimide or the like, or a stacked layer thereof may be used. By a droplet discharge method, different materials may be discharged to the same region plural times to form the partition wall. A quarter wave plate (λ/4) or a half wave plate (λ/2) may be used as the retardation plate and may be designed to be able to control light. As the structure, the light-emitting element, the sealing substrate (sealant), the retardation plates (a quarter wave plate (λ/4) and a half wave plate (λ/2)), and the polarizing plate are formed over a TFF element substrate in this order, and light emitted from the light-emitting element is transmitted therethrough and is emitted to the outside from the polarizing plate side. The retardation plate or the polarizing plate may be provided on a side to which light is emitted or may be provided on both sides in the case of a dual-emission semiconductor device in which light is emitted from the both sides. In addition, an anti-reflective film may be provided on the outer side of the polarizing plate. Accordingly, high-definition and precise images can be displayed.

A display panel 2002 using a display element is incorporated into a housing 2001 as illustrated in FIG. 20A. In addition to reception of general TV broadcast with the use of a receiver 2005, communication of information can also be performed in one way (from a transmitter to a receiver) or in two ways (between a transmitter and a receiver or between receivers) by connection to a wired or wireless communication network through a modem 2004. The television device can be operated with switches incorporated in the housing or with a remote control device 2006 separated from the main body. A display portion 2007 that displays information to be output may also be provided for this remote control device.

In addition, for the television device, a structure for displaying a channel, sound volume, or the like may be additionally provided by formation of a sub-screen 2008 with a second display panel in addition to the main screen 2003. In this structure, the main screen 2003 may be formed using an EL display panel excellent in viewing angle, and the sub-screen 2008 may be formed using a liquid crystal display panel capable of displaying with low power consumption. In order to prioritize low power consumption, a structure in which the main screen 2003 is formed using a liquid crystal display panel, the sub-screen 2008 is formed using an EL display panel, and the sub-screen is able to flash on and off may be employed. By the present invention, a semiconductor device with high performance and high reliability can be manufactured with high productivity even with the use of a large-sized substrate with a number of TFTs and electronic components.

FIG. 20B illustrates a television device which has a large display portion, for example, 20-inch to 80-inch display portion and includes a housing 2010, a keyboard portion 2012 which is an operation portion, a display portion 2011, a speaker portion 2013, and the like. The present invention is applied to manufacture of the display portion 2011. The display portion in FIG. 20B is formed using a bendable material; therefore, the television device includes the bent display portion. Since the shape of the display portion can be freely set, a television device having a desired shape can be manufactured.

In accordance with the present invention, a semiconductor device with high performance and high reliability which has a display function can be manufactured with high productivity. Therefore, a television device with high performance and high reliability can be manufactured with high productivity.

The present invention is certainly not limited to the television device and is also applicable to various uses such as a monitor of a personal computer and a display medium having a large area, for example, an information display board at a train station, an airport, or the like, or an advertisement display board on the street.

### Embodiment Mode 10

In this embodiment mode, an example of a semiconductor device having high performance and high reliability will be described. Specifically, as examples of the semiconductor device, examples of a microprocessor and a semiconductor device which has an arithmetic function and can transmit and receive data without contact are described.

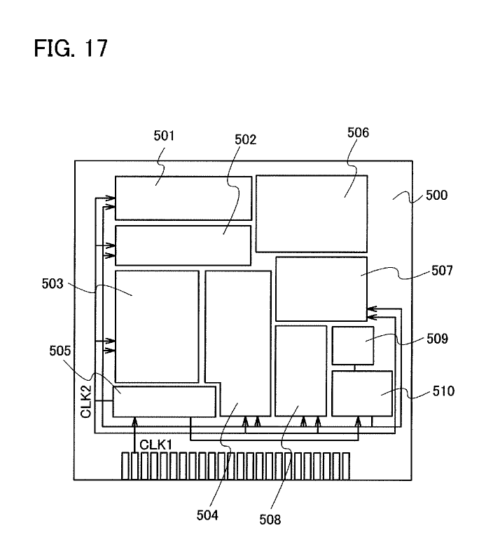

FIG. 17 illustrates a microprocessor 500 as an example of a semiconductor device. As described above, the microprocessor 500 is manufactured using the semiconductor substrate of this embodiment mode. This microprocessor 500 has an arithmetic logic unit (also referred to as an ALU) 501, an ALU controller 502, an instruction decoder 503, an interrupt controller 504, a timing controller 505, a register 506, a register controller 507, a bus interface (bus I/F) 508, a read only memory 509, and a memory interface (ROM I/F) 510.

An instruction input to the microprocessor 500 through the bus interface 508 is input to the instruction decoder 503 and decoded. Then, the instruction is input to the ALU controller 502, the interrupt controller 504, the register controller 507, and the timing controller 505. The ALU controller 502, the interrupt controller 504, the register controller 507, and the timing controller 505 perform various controls based on the decoded instruction. Specifically, the ALU controller 502 generates a signal for controlling the operation of the arithmetic logic unit 501. The interrupt controller 504 judges an interrupt request from an external input/output device or a peripheral circuit based on its priority or a mask state, and processes the request while a program is executed in the microprocessor 500. The register controller 507 generates an address of the register 506, and reads/writes data from/to the register 506 in accordance with the state of the microprocessor 500. The timing controller 505 generates signals for controlling timing of driving of the arithmetic logic unit 501, the ALU controller 502, the instruction decoder 503, the interrupt controller 504, and the register controller 507. For example, the timing controller 505 is provided with an internal clock generator for generating an internal clock signal CLK2 based on a reference clock signal CLK1, and supplies the clock signal CLK2 to each of the above-mentioned circuits. Note that the microprocessor 500 illustrated in FIG. 17 is just an example of the simplified structure, and practical microprocessors have various structures depending on usage.

Since an integrated circuit is formed using a single crystal semiconductor layer whose crystals are oriented in a certain direction and which is bonded to a glass substrate in the microprocessor 500, higher processing speed and lower power consumption can be achieved.

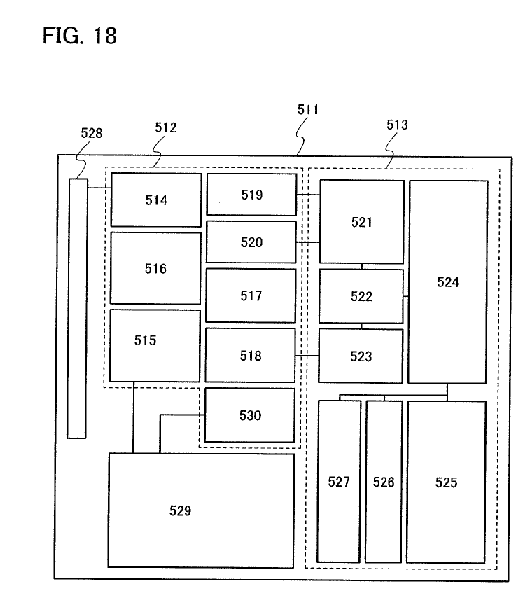

Next, an example of a semiconductor device which has an arithmetic function and can transmit and receive data without contact will be described with reference to FIG. 18. FIG. 18 illustrates an example of a computer (hereinafter also referred to as an RFCPU) which transmits and receives signals to/from an external device by wireless communication. An RFCPU 511 has an analog circuit portion 512 and a digital circuit portion 513. The analog circuit portion 512 includes a resonance circuit 514 having a resonant capacitor, a rectifier circuit 515, a constant voltage circuit 516, a reset circuit 517, an oscillator circuit 518, a demodulation circuit 519, a modulation circuit 520 and a power supply control circuit 530. The digital circuit portion 513 includes an RF interface 521, a control register 522, a clock controller 523, a CPU interface 524, a central processing unit 525, a random access memory 526, and a read only memory 527.

The operation of the RFCPU 511 having such a structure is roughly described below. The resonance circuit 514 generates induced electromotive force based on a signal received at an antenna 528. The induced electromotive force is stored in a capacitor portion 529 via the rectifier circuit 515. The capacitor portion 529 is preferably formed using a capacitor such as a ceramic capacitor or an electric double layer capacitor. The capacitor portion 529 is not necessarily formed over the same substrate as the RFCPU 511 and may be attached as another component to a substrate having an insulating surface that partially constitutes the RFCPU 511.

The reset circuit 517 generates a signal that resets the digital circuit portion 513 to be initialized. For example, the reset circuit 517 generates, as a reset signal, a signal that rises with delay after increase in the power supply voltage. The oscillator circuit 518 changes the frequency and the duty ratio of a clock signal in accordance with a control signal generated by the constant voltage circuit 516. The demodulation circuit 519 having a low pass filter binarizes changes in amplitude of reception signals of an amplitude shift keying (ASK) system, for example. The modulation circuit 520 changes the amplitude of transmission signals of an amplitude shift keying (ASK) system to be transmitted. The modulation circuit 520 changes the resonance point of the resonance circuit 514, thereby changing the amplitude of communication signals. The clock controller 523 generates a control signal for changing the frequency and the duty ratio of the clock signal in accordance with the power supply voltage or current consumption in the central processing unit 525. The power supply voltage is monitored by the power supply control circuit 530.

A signal that is input to the RFCPU 511 from the antenna 528 is demodulated by the demodulation circuit 519, and then divided into a control command, data, and the like by the RF interface 521. The control command is stored in the control register 522. The control command includes reading of data stored in the read only memory 527, writing of data to the random access memory 526, an arithmetic instruction to the central processing unit 525, and the like. The central processing unit 525 accesses the read only memory 527, the random access memory 526, and the control register 522 via the CPU interface 524. The CPU interface 524 has a function of generating an access signal for any one of the read only memory 527, the random access memory 526, and the control register 522 based on an address requested by the central processing unit 525.

As an arithmetic method of the central processing unit 525, a method may be employed in which the read only memory 527 stores an OS (operating system) and a program is read at the time of starting operation and then executed. Alternatively, a method may be employed in which a circuit dedicated to arithmetic is formed as an arithmetic circuit and an arithmetic processing is conducted using hardware. In a method in which both hardware and software are used, a method can be employed in which part of process is conducted in the circuit dedicated to arithmetic and the other part of the arithmetic process is conducted by the central processing unit 525 using a program.

Since an integrated circuit is formed using a single crystal semiconductor layer whose crystals are oriented in a certain direction and which is bonded to a glass substrate in the RFCPU 511, higher processing speed and lower power consumption can be achieved. Accordingly, even when the capacitor portion 529 which supplies electric power is miniaturized, long-term operation can be secured.

### Embodiment Mode 11

This embodiment mode will be described with reference to FIGS. 14A and 14B. This embodiment mode shows an example of a module using a panel including the semiconductor device manufactured in Embodiment Modes 1 to 8. In this embodiment mode, an example of a module including a semiconductor device having high performance and high reliability will be described.

A module of an information terminal illustrated in FIG. 14A includes a printed wiring board 946 on which a controller 901, a central processing unit (CPU) 902, a memory 911, a power supply circuit 903, an audio processing circuit 929, a transmission/reception circuit 904, and other elements such as a resistor, a buffer, a capacitor, and the like are mounted. In addition, a panel 900 is connected to the printed wiring board 946 through a flexible printed circuit (FPC) 908.

The panel 900 is provided with a pixel region 905 having a light-emitting element in each pixel, a first scanning line driver circuit 906a and a second scanning line driver circuit 906b which select a pixel included in the pixel region 905, and a signal line driver circuit 907 which supplies a video signal to the selected pixel.

Various control signals are input and output through an interface (I/F) 909 provided over the printed wiring board 946. An antenna port 910 for transmitting and receiving signals to/from an antenna is provided over the printed wiring board 946.

In this embodiment mode, the printed wiring board 946 is connected to the panel 900 through the FPC 908; however, the present invention is not limited to this structure. The controller 901, the audio processing circuit 929, the memory 911, the CPU 902, or the power supply circuit 903 may be directly mounted on the panel 900 by a COG (chip on glass) method. Moreover, various elements such as a capacitor, a buffer, and the like are provided over the printed wiring board 946, so that a noise in power supply voltage or a signal and delay in signal rising are prevented.

FIG. 14B is a block diagram of the module illustrated in FIG. 14A. A module includes a VRAM 932, a DRAM 925, a flash memory 926, and the like in the memory 911. The VRAM 932 stores image data to be displayed on the panel, the DRAM 925 stores image data or audio data, and the flash memory stores various programs.

The power supply circuit 903 generates power supply voltage applied to the panel 900, the controller 901, the CPU 902, the audio processing circuit 929, the memory 911, and the transmission/reception circuit 931. Moreover, depending on the specifications of the panel, a current source is provided in the power supply circuit 903 in some cases.

The CPU 902 includes a control signal generating circuit 920, a decoder 921, a register 922, an arithmetic circuit 923, a RAM 924, an interface 935 for the CPU, and the like. Various signals input to the CPU 902 through the interface 935 are input to the arithmetic circuit 923, the decoder 921, and the like after once being held in the register 922. The arithmetic circuit 923 carries out an arithmetic operation based on the input signal and specifies an address to which various instructions are sent. On the other hand, the signal input to the decoder 921 is decoded and input to the control signal generating circuit 920. The control signal generating circuit 920 generates a signal including various instructions based on the input signal and sends it to the address specified by the arithmetic circuit 923, specifically, the memory 911, the transmission/reception circuit 931, the audio processing circuit 929, the controller 901, and the like.

The memory 911, the transmission/reception circuit 931, the audio processing circuit 929, and the controller 901 operate in accordance with respective instructions received. The operations will be briefly described below.

The signal input from an input unit 930 is transmitted to the CPU 902 mounted on the printed wiring board 946 through the interface 909. The control signal generating circuit 920 converts the image data stored in the VRAM 932 into a predetermined format in accordance with the signal transmitted from the input unit 930 such as a pointing device and a keyboard, and then transmits it to the controller 901.

The controller 901 processes a signal including image data transmitted from the CPU 902 in accordance with the specifications of the panel and supplies it to the panel 900. The controller 901 generates a Hsync signal, a Vsync signal, a clock signal CLK, alternating voltage (AC Cont), and a switching signal L/R based on the power supply voltage input from the power supply circuit 903 and various signals input from the CPU 902 and supplies them to the panel 900.

In the transmission/reception circuit 904, a signal transmitted and received as an electric wave at an antenna 933 is processed. Specifically, high frequency circuits such as an isolator, a band path filter, a VCO (voltage controlled oscillator), an LPF (low pass filter), a coupler, and a balun are included. Among the signals transmitted and received at the transmission/reception circuit 904, signals including audio data are transmitted to the audio processing circuit 929 in accordance with an instruction transmitted from the CPU 902.

The signals including audio data transmitted in accordance with the instruction from the CPU 902 are demodulated into audio signals in the audio processing circuit 929 and transmitted to a speaker 928. The audio signal transmitted from a microphone 927 is modulated in the audio processing circuit 929 and transmitted to the transmission/reception circuit 904 in accordance with the instruction from the CPU 902.

The controller 901, the CPU 902, the power supply circuit 903, the audio processing circuit 929, and the memory 911 can be incorporated as a package of this embodiment mode. This embodiment mode is applicable to any circuit other than high frequency circuits such as an isolator, a band path filter, a VCO (voltage controlled oscillator), an LPF (low pass filter), a coupler, and a balun.

### Embodiment Mode 12

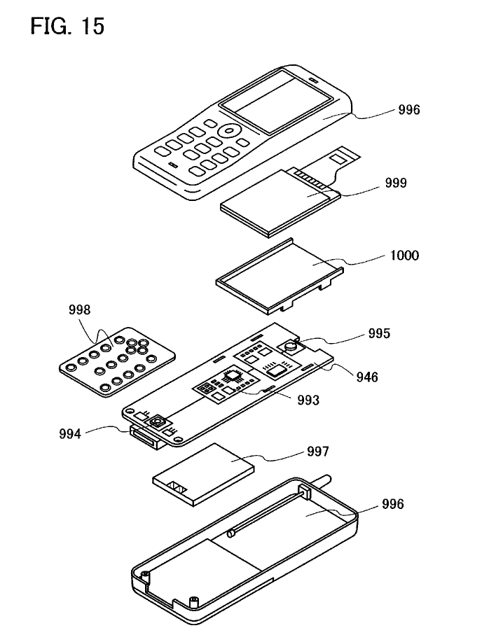

This embodiment mode will be described with reference to FIGS. 14A and 14B and 15. FIG. 15 illustrates one mode of a portable compact phone (mobile phone) which includes the module manufactured in Embodiment Mode 9 and operates wirelessly. The panel 900 is detachably incorporated into a housing 1000 so as to be easily combined with the module 999. The shape and the size of the housing 1000 can be appropriately changed in accordance with an electronic device incorporated therein.

The housing 1000 in which the panel 900 is fixed is fitted to the printed wiring board 946 and set up as a module. A controller, a CPU, a memory, a power supply circuit, and other elements such as a resistor, a buffer, a capacitor, and the like are mounted on the printed wiring board 946. Moreover, an audio processing circuit including a microphone 994 and a speaker 995 and a signal processing circuit 993 such as a transmission/reception circuit or the like are provided. The panel 900 is connected to the printed wiring board 946 through the FPC 908.

The module 999, an input unit 998, and a battery 997 are stored in a housing 996. The pixel region of the panel 900 is arranged so that it can be seen through a window formed in the housing 996.

The housing 996 illustrated in FIG. 15 is an example of an exterior shape of a telephone. However, an electronic device of this embodiment mode can be changed into various modes in accordance with functions and intended purposes. In the following embodiment mode, examples of the modes will be described.

### Embodiment Mode 13

By applying the present invention, various semiconductor devices having a display function can be manufactured. In other words, the present invention is applicable to various electronic devices in which these semiconductor devices having a display function are incorporated into display portions. In this embodiment mode, examples of electronic devices including a high-performance and highly reliable semiconductor device having a display function will be described.

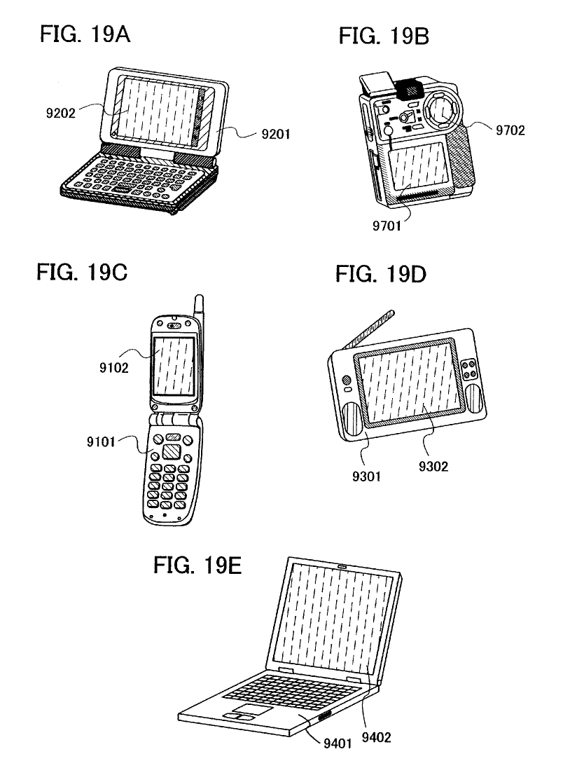

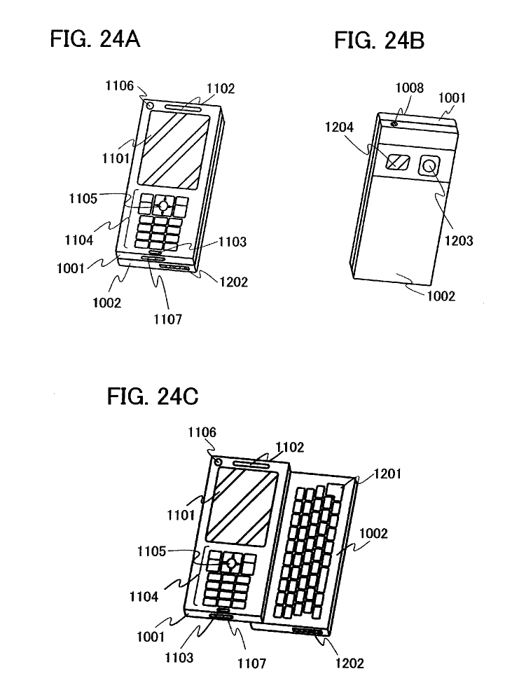

As electronic devices of the present invention, television devices (also simply referred to as televisions or television receivers), cameras such as digital cameras or digital video cameras, mobile phone sets (also simply referred to as mobile phones or cell-phones), portable information terminals such as PDAs, portable game machines, monitors for computers, computers, audio reproducing devices such as car audio systems, image reproducing devices provided with a recording medium such as home game machines (specifically, a digital versatile disc (DVD)), and the like can be given. Specific examples thereof will be described with reference to FIGS. 19A to 19E and FIGS. 24A to 24C.

A portable information terminal device illustrated in FIG. 19A includes a main body 9201, a display portion 9202, and the like. The semiconductor device of the present invention is applicable to the display portion 9202. Accordingly, a portable information terminal device with high performance and high reliability can be provided.

A digital video camera illustrated in FIG. 19B includes a display portion 9701, a display portion 9702, and the like. The semiconductor device of the present invention is applicable to the display portion 9701. Accordingly, a digital video camera with high performance and high reliability can be provided.

A mobile phone illustrated in FIG. 19C includes a main body 9101, a display portion 9102, and the like. The semiconductor device of the present invention is applicable to the display portion 9102. Accordingly, a mobile phone with high performance and high reliability can be provided.

A portable television device illustrated in FIG. 19D includes a main body 9301, a display portion 9302, and the like. The semiconductor device of the present invention is applicable to the display portion 9302. Accordingly, a portable television device with high performance and high reliability can be provided. The semiconductor device of the present invention is applicable to various types of television devices including a small-sized television incorporated in a portable terminal such as a mobile phone or the like, a medium-sized television that is portable, and a large-sized television (e.g., greater than or equal to 40 inches in size).

A portable computer illustrated in FIG. 19E includes a main body 9401, a display portion 9402, and the like. The semiconductor device of the present invention is applicable to the display portion 9402. Accordingly, a portable computer with high performance and high reliability can be provided.

FIGS. 24A to 24C illustrate an example of a cellular phone which is different from the cellular phones illustrated in FIG. 15 and FIG. 19C. FIG. 24A is a front view, FIG. 24B is a rear view, and FIG. 24C is a development view. The cellular phone has both a function of a cellular phone and a function of a portable information terminal, and incorporates a computer provided to conduct a variety of data processing in addition to verbal communication; therefore, it is called a smartphone.

The cellular phone has two housings 1001 and 1002. The housing 1001 includes a display portion 1101, a speaker 1102, a microphone 1103, operation keys 1104, a pointing device 1105, a camera lens 1106, an external connection terminal 1107, an earphone terminal 1108 and the like, while the housing 1002 includes a keyboard 1201, an external memory slot 1202, a camera lens 1203, a light 1204, and the like. In addition, an antenna is incorporated in the housing 1001.

Further, in addition to the above structure, the cellular phone may incorporate a non-contact IC chip, a small size memory device, or the like.

In the display portion 1101 which can incorporate a semiconductor device described in the above embodiment mode, display direction can be changed depending on a use mode. Because the camera lens 1106 is provided in the same plane as the display portion 1101, the cellular phone can be used as a videophone. A still image and a moving image can be taken with the camera lens 1203 and the light 1204 by using the display portion 1101 as a view finder. The speaker 1102 and the microphone 1103 can be used for uses of videophone, recording, playback and the like without being limited to verbal communication. With the use of the operation keys 1104, operation of incoming and outgoing calls, simple information input of electronic mails or the like, scrolling of a screen, cursor movement and the like are possible. Further, the housing 1001 and housing 1002 illustrated in FIG. 24A which are put together to be lapped with each other are developed by sliding as illustrated in FIG. 24C, and the cellular phone can be used as a portable information terminal. In this case, smooth operation can be conducted by using the keyboard 1201 or the pointing device 1105. The external connection terminal 1107 can be connected to an AC adapter and various types of cables such as a USB cable, and charging and data communication with a personal computer are possible. Moreover, a large amount of data can be stored by inserting a storage medium into the external memory slot 1202 and can be moved.

Further, the cellular phone may include an infrared communication function, a function of a television receiver or the like, in addition to the above-described function.

Since the semiconductor device of the present invention can be applied to the display portion 1101, the high-performance and highly reliable cellular phone can be provided.

The semiconductor device of the present invention can also be used as a lighting system. The semiconductor device to which the present invention is applied can also be used as a small desk lamp or a large lighting system in a room. Further, the semiconductor device of the present invention can also be used as a backlight of a liquid crystal display device.

In this manner, by using the semiconductor device of the present invention, high-performance and highly reliable electronic devices can be provided.

### Embodiment 1

This embodiment will describe experimental results of a semiconductor substrate formed by re-single-crystallization using the present invention.

A single crystal silicon layer transferred from a single crystal silicon substrate is formed over a glass substrate with a thickness of 0.7 mm. An embrittlement layer was formed in the single crystal silicon substrate by ion irradiation. The single crystal silicon substrate and the glass substrate are bonded to each other, and heat treatment was performed, so that the single crystal silicon layer was formed over the glass substrate. The bond was performed with insulating layers interposed therebetween. A sample had a stacked layer structure of the glass substrate, a silicon oxide film (with the thickness of 50 nm), a silicon nitride oxide film (with a thickness of 50 nm), a silicon oxynitride film (with a thickness of 50 nm) and the single crystal silicon layer. Note that the silicon oxide film was formed by a chemical vapor deposition method using an organosilane gas.

The single crystal silicon layer was irradiated with pulsed excimer laser light with a wavelength of 308 nm. Note that the energy density was 482 mJ/cm². With the use of a mask, irradiation regions and non-irradiation regions were formed at a space of 2 μm. The sample was placed over a stage which was heated to 500° C.

The effect on crystallinity improvement can be evaluated with Raman shifts, full widths at half maximum (FWHM) of Raman spectra, and electron back scatter diffraction pattern (EBSP) images.

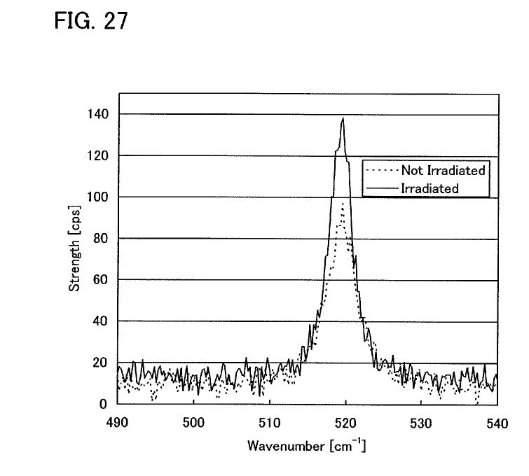

Raman spectroscopy was performed on a single crystal silicon layer before laser light irradiation (described as “not irradiated” and indicated by a dotted line in FIG. 27) and a single crystal silicon layer after laser light irradiation (described as “irradiated” and indicated by a solid line in FIG. 27). FIG. 27 illustrates the results of Raman spectroscopy. Note that in FIG. 27, the horizontal axis represents a wavenumber and the vertical axis represents strength. From the measurement results of FIG. 27, Raman shifts and full widths at half maximum of the single crystal silicon layer which is not irradiated and the irradiated single crystal silicon layer were obtained, as illustrated in Table 1.

TABLE 1

| | Raman | Full Width At Half |
|---|---|---|
| | Shift [cm⁻¹] | Maximum [cm⁻¹] |
| Not Irradiated | 519.414 | 4.68195 |
| Irradiated | 519.243 | 3.41082 |

As illustrated in Table 1, the irradiated single crystal silicon layer has a smaller full width at half maximum than the single crystal silicon layer which is not irradiated, from which it can be confirmed that the irradiated single crystal silicon layer is in a more favorable crystal state.

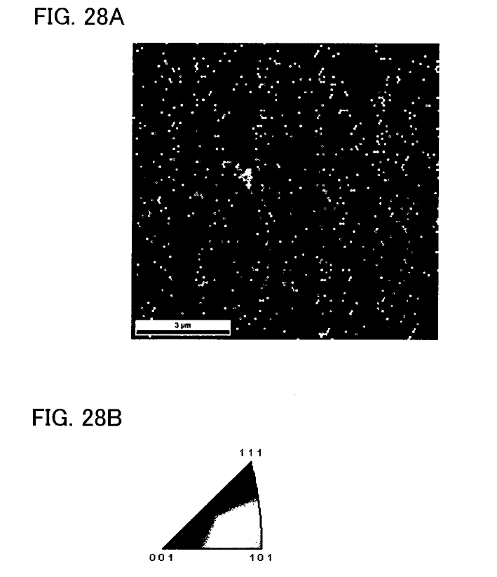

FIG. 28A shows the results obtained from the measurement data of the EBSP of the surface of the single crystal silicon layer after irradiation

FIG. 28A is an inverse pole figure (IPF) map obtained from the measurement data of the EBSP of the surface of the single crystal silicon layer. FIG. 28B is a color code map showing the relationship between colors of the IPF maps and crystal orientation (a crystal axis), in which the orientation of each crystal is color-coded.

It can be seen from the IPF map of FIG. 28A that the surface of the single crystal silicon layer is oriented in (001) plane. The IPF map of FIG. 28A is a monochromatic image of a color (red color in the color code map) which exhibits (001) plane in the color code map of FIG. 28B, from which it can be seen that the crystal orientation is aligned in (100) even after re-single-crystallization.

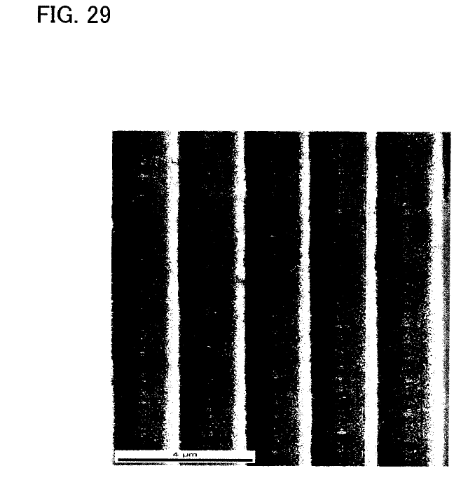

As shown in FIG. 29, the single crystal silicon layer after irradiation was observed with a scanning electron microscope (SEM). FIG. 29 shows a SEM image of the single crystal silicon layer after irradiation. In the SEM image of FIG. 29, white regions are irradiation regions in which re-single-crystallization is caused using peripheral gray single crystal regions as nuclei of crystal growth.

As described above, crystallinity of the single crystal silicon layer transferred to the glass substrate can be improved by the present invention. With the use of such a single crystal semiconductor layer, a semiconductor device that includes various semiconductor elements, memory elements, integrated circuits, or the like which have high performance and high reliability can be manufactured with high yield.

This application is based on Japanese Patent Application serial No. 2007-285180 filed with Japan Patent Office on Nov. 1, 2007, the entire contents of which are hereby incorporated by reference.

What is claimed is:

1. A method for manufacturing an SOI substrate, comprising the steps of:
adding ions into a semiconductor substrate to form an embrittlement layer in the semiconductor substrate;
bonding the semiconductor substrate to a supporting substrate with at least one insulating layer interposed therebetween;
performing heat treatment to separate the semiconductor substrate at the embrittlement layer so that a semiconductor layer is formed over the supporting substrate; and
irradiating the semiconductor layer with pulsed laser light to melt an irradiated region throughout an entire thickness of the semiconductor layer.

2. The method for manufacturing an SOI substrate according to claim 1, further comprising the step of forming the insulating layer over at least one surface of the semiconductor substrate and the supporting substrate so that the semiconductor substrate is bonded to the supporting substrate with the insulating layer interposed therebetween.

3. The method for manufacturing a SOI substrate according to claim 1,
wherein the semiconductor substrate is a single crystal semiconductor substrate, and
wherein the semiconductor layer is recrystallized by irradiation with the pulsed laser light.

4. The method for manufacturing an SOI substrate according to claim 1, wherein a laser light profile of the pulsed laser light in a minor-axis direction of the irradiated region on the semiconductor layer has a rectangular shape and a width of 20 μm or less.

5. The method for manufacturing an SOI substrate according to claim 1, wherein a laser light profile of the pulsed laser light in a minor-axis direction of the irradiated region on the semiconductor layer has Gaussian and a width of 100 μm or less.

6. The method for manufacturing an SOI substrate according to claim 1, wherein the irradiated region on the semiconductor layer has a rectangular shape.

7. The method for manufacturing an SOI substrate according to claim 1, wherein crystal growth of the melted semiconductor layer occurs using non-melted regions of the semiconductor layer which are adjacent to the melted semiconductor layer as crystal nuclei.

8. The method for manufacturing an SOI substrate according to claim 1, wherein the semiconductor layer is recrystallized by irradiation with the pulsed laser light while the semiconductor layer is heated.

9. The method for manufacturing an SOI substrate according to claim 1, wherein an ion doping method is used as a method for adding the ions into the semiconductor substrate.

10. The method for manufacturing an SOI substrate according to claim 1, wherein the supporting substrate is a glass substrate.

11. A method for manufacturing an SOI substrate, comprising the steps of:
adding ions into a single crystal semiconductor substrate to form an embrittlement layer in the single crystal semiconductor substrate;
bonding the single crystal semiconductor substrate to a supporting substrate with at least one insulating layer interposed therebetween;
performing heat treatment to separate the single crystal semiconductor substrate at the embrittlement layer so that a single crystal semiconductor layer is formed over the supporting substrate; and
irradiating the single crystal semiconductor layer with pulsed laser light to melt an irradiated region throughout an entire thickness of the single crystal semiconductor layer,
wherein crystal growth occurs from end portions of a melted region of the single crystal semiconductor layer toward a center of the melted region in a parallel direction to a surface of the supporting substrate and re-single-crystallization is caused.

12. The method for manufacturing an SOI substrate according to claim 11, further comprising the step of forming the insulating layer over at least one surface of the single crystal semiconductor substrate and the supporting substrate so that the single crystal semiconductor substrate is bonded to the supporting substrate with the insulating layer interposed therebetween.

13. The method for manufacturing an SOI substrate according to claim 11, wherein a laser light profile of the pulsed laser light in a minor-axis direction of the irradiated region on the single crystal semiconductor layer has a rectangular shape and a width of 20 μm or less.

14. The method for manufacturing an SOI substrate according to claim 11, wherein a laser light profile of the pulsed laser light in a minor-axis direction of the irradiated region on the single crystal semiconductor layer has Gaussian and a width of 100 μm or less.

15. The method for manufacturing an SOI substrate according to claim 11, wherein the irradiated region on the single crystal semiconductor layer has a rectangular shape.

16. The method for manufacturing an SOI substrate according to claim 11, wherein crystal growth of the melted single crystal semiconductor layer occurs using non-melted regions of the single crystal semiconductor layer which are adjacent to the melted single crystal semiconductor layer as crystal nuclei.

17. The method for manufacturing an SOI substrate according to claim 11, wherein the single crystal semiconductor layer is recrystallized by irradiation with the pulsed laser light while the single crystal semiconductor layer is heated.

18. The method for manufacturing an SOI substrate according to claim 11, wherein an ion doping method is used as a method for adding the ions into the single crystal semiconductor substrate.

19. The method for manufacturing an SOI substrate according to claim 11, wherein the supporting substrate is a glass substrate.

20. A method for manufacturing a semiconductor device, comprising the steps of:
adding ions into a semiconductor substrate to form an embrittlement layer in the semiconductor substrate;
bonding the semiconductor substrate to a supporting substrate with at least one insulating layer interposed therebetween;
performing heat treatment to separate the semiconductor substrate at the embrittlement layer so that a semiconductor layer is formed over the supporting substrate;
irradiating the semiconductor layer with pulsed laser light to melt an irradiated region throughout an entire thickness of the semiconductor layer; and
forming a semiconductor element using the semiconductor layer.

21. The method for manufacturing a semiconductor device according to claim 20, further comprising the step of forming the insulating layer over at least one surface of the semiconductor substrate and the supporting substrate so that the semiconductor substrate is bonded to the supporting substrate with the insulating layer interposed therebetween.

22. The method for manufacturing a semiconductor device according to claim 20,
wherein the semiconductor substrate is a single crystal semiconductor substrate, and
wherein the semiconductor layer is recrystallized by irradiation with the pulsed laser light.

23. The method for manufacturing a semiconductor device according to claim 20, wherein a laser light profile of the pulsed laser light in a minor-axis direction of the irradiated region on the semiconductor layer has a rectangular shape and a width of 20 μm or less.

24. The method for manufacturing a semiconductor device according to claim 20, wherein a laser light profile of the pulsed laser light in a minor-axis direction of the irradiated region on the semiconductor layer has Gaussian and a width of 100 μm or less.

25. The method for manufacturing a semiconductor device according to claim 20, wherein the irradiated region on the semiconductor layer has a rectangular shape.

26. The method for manufacturing a semiconductor device according to claim 20, wherein crystal growth of the melted semiconductor layer occurs using non-melted regions of the semiconductor layer which are adjacent to the melted semiconductor layer as crystal nuclei.

27. The method for manufacturing a semiconductor device according to claim 20, wherein the semiconductor layer is recrystallized by irradiation with the pulsed laser light while the semiconductor layer is heated.

28. The method for manufacturing a semiconductor device according to claim 20, wherein an ion doping method is used as a method for adding the ions into the semiconductor substrate.

29. The method for manufacturing a semiconductor device according to claim 20, wherein the supporting substrate is a glass substrate.

30. The method for manufacturing a semiconductor device according to claim 20, further comprising the step of forming a display element electrically connected to the semiconductor element.
